(19) United States
(12) Patent Application Publication
(10) Pub. No.: US 2012/0279566 A1
(43) Pub. Date: Nov. 8, 2012

(54) PHOTOVOLTAIC ELEMENT WITH INCREASED LONG-TERM STABILITY

(75) Inventors: Ingmar BRUDER, Harthausen (DE); Rüdiger SENS, Ludwigshafen (DE); Markus GROB, Reinach (CH); Ursula SCHULZE TILLING, Muenster (DE)

(73) Assignee: BASF SE, Ludwigshafen (DE)

(21) Appl. No.: 13/446,380

(22) Filed: Apr. 13, 2012

Related U.S. Application Data
(60) Provisional application No. 61/481,275, filed on May 2, 2011.
(60) Provisional application No. 61/567,142, filed on Dec. 6, 2011.

(51) Int. Cl. H01L 31/0232; H01L 31/18; C09D 133/08; H01L 51/46

(52) U.S. Cl. 136/257; 136/263; 438/70; 524/502; 257/E31.127

(57) ABSTRACT

A photovoltaic element for conversion of electromagnetic radiation to electrical energy, having at least one first electrode, at least one n-semiconductive metal oxide, at least one dye for absorption of electromagnetic radiation, at least one organic hole conductor material, and at least one second electrode. The organic hole conductor material has an absorption spectrum which has a maximum in the ultraviolet or blue spectral region and, toward higher wavelengths, an absorption edge declining with wavelength and having a characteristic wavelength λ_{HTL}. A decadic absorbance of the hole conductor material at a wavelength λ_{HTL} within the declining absorption edge is 0.3. The photovoltaic element includes a longpass filter, which has a transmission edge rising with wavelength and having a characteristic wavelength λ_{LP}. A transmission of the longpass filter at λ_{LP} is 50% of a maximum transmission of the longpass filter, where λ_{HTL}−30 nm≦λ_{LP}≦λ_{HTL}+30 nm.

### FIELD OF THE INVENTION

The invention relates to a photovoltaic element for conversion of electromagnetic radiation to electrical energy, to a process for production of a photovoltaic element for conversion of electromagnetic radiation to electrical energy and to a process for selection of a longpass filter for use in a photovoltaic element for conversion of electromagnetic radiation to electrical energy. Such photovoltaic elements and processes are used to convert electromagnetic radiation, especially sunlight, to electrical energy. More particularly, the invention can be applied to dye solar cells.

### PRIOR ART

The direct conversion of solar energy to electrical energy in solar cells is based generally on what is called the “internal photoeffect” of a semiconductor material, i.e. the production of electron-hole pairs by absorption of photons and the separation of the negative and positive charge carriers at a p-n junction or a Schottky contact. In this way, a photovoltage is generated, which, in an external circuit, can cause a photocurrent through which the solar cell releases its power. The semiconductor can generally only absorb those photons which have an energy greater than the bandgap thereof. The size of the semiconductor bandgap thus generally determines the proportion of sunlight which can be converted to electrical energy.

Solar cells based on crystalline silicon were produced as early as the 1950s. The technology at that time was supported by use in space satellites. Even though silicon-based solar cells now dominate the market on Earth, this technology still remains costly. Attempts are therefore being made to develop new approaches which are less expensive. Some of these approaches will be outlined hereinafter, which constitute the basis of the present invention.

An important approach to the development of new solar cells is that of organic solar cells, i.e. solar cells which comprise at least one organic semiconductor material, or solar cells which, instead of solid inorganic semiconductors, comprise other materials, especially organic dyes or even liquid electrolytes and semiconductors. A special case among the innovative solar cells is that of dye solar cells. The dye solar cell (DSC) is one of the most efficient alternative solar cell technologies to date. In a liquid variant of this technology, efficiencies of up to 11% are currently being achieved (see, for example, Grätzel M. et al., J. Photochem. Photobio. C, 2003, 4, 145; Chiba et al., Japanese Journal of Appl. Phys., 2006, 45, L638-L640).

Dye solar cells, of which there are now several variants, generally have two electrodes, at least one of which is transparent. According to their function, the two electrodes are referred to as “working electrode” (also “anode”, generation of electrons) and “counterelectrode” (also “cathode”). On the working electrode or in the vicinity thereof, an n-conductive metal oxide has generally been applied, especially as a porous, for example nanoporous, layer, for example a nanoporous titanium dioxide (TiO₂) layer of thickness approx. 10-20 μm. Between the layer of the n-conductive metal oxide and the working electrode, it is additionally possible for at least one blocking layer to be provided, for example an impervious layer of a metal oxide, for example TiO₂. The n-conductive metal oxide generally has an added light-sensitive dye. For example, on the surface of the n-conductive metal oxide, a monolayer of a light-sensitive dye (for example a ruthenium complex) may be adsorbed, which can be converted to an excited state by absorption of light. At or on the counterelectrode, there is frequently a catalytic layer of a few μm in thickness, for example platinum. The area between the two electrodes in the conventional dye solar cell is generally filled with a redox electrolyte, for example a solution of iodine (I₂) and/or potassium iodide (KI).

The function of the dye solar cell is based on absorption of light by the dye. From the excited dye, electrons are transferred to the n-semiconductive metal oxide semiconductor and migrate thereon to the anode, whereas the electrolyte ensures charge balance via the cathode. The n-semiconductive metal oxide, the dye and the electrolyte are thus the essential constituents of the dye solar cell.

However, the dye solar cell produced with liquid electrolyte in many cases suffers from nonoptimal sealing, which can lead to stability problems. The liquid redox electrolyte can especially be replaced by a solid p-semiconductor. Such solid dye solar cells are also referred to as sDSCs (solid DSCs). The efficiency of the solid variant of the dye solar cell is currently approx. 4.6-4.7% (Snaith, H., Angew. Chem. Int. Ed., 2005, 44, 6413-6417).

Various inorganic p-semiconductors such as Cul, CuBr.3(S(C₄H₉)₂) or CuSCN have been used to date in solid dye solar cells in place of the redox electrolyte. It is also possible, for example, to apply findings from photosynthesis. In nature too, it is the Cu(I) enzyme plastocyanine which, in photosystem I, reduces the oxidized chlorophyll dimer again. Such p-semiconductors can be processed by means of at least three different methods, namely: from a solution, by electrodeposition or by laser deposition.

Organic polymers have also already been used as solid p-semiconductors. Examples thereof include polypyrrole, poly(3,4-ethylenedioxythiophene), carbazole-based polymers, polyaniline, poly(4-undecyl-2,2′-bithiophene), poly(3-octylthiophene), poly(triphenyldiamine) and poly(N-vinylcarbazole). In the case of poly(N-vinylcarbazole), the efficiencies extend up to 2%. PEDOT (poly(3,4-ethylenedioxythiophene) polymerized in situ also showed an efficiency of 0.53%. The polymers described here are typically not used in pure form, but rather with additives.

Inorganic-organic mixed systems have also already been used in place of the redox electrolyte in dye solar cells. For example, Cul was used together with PEDOT:PSS as a hole conductor in sDSC (Zhang J. Photochem: Photobio., 2007, 189, 329).

It is also possible to use low molecular weight organic p-semiconductors, i.e. nonpolymerized, for example monomeric or else oligomeric, organic p-semiconductors. The first use of a low molecular weight p-semiconductor in solid dye solar cells replaced the liquid electrolyte with a vapor-deposited layer of triphenylamine (TPD). The use of the organic compound 2,2′,7,7′-tetrakis(N,N-di-p-methoxyphenylamine)-9,9′-spirobifluorene (spiro-MeOTAD) in dye solar cells was reported in 1998. It can be introduced from a solution and has a relatively high glass transition temperature, which prevents unwanted crystallization and poor contact to the dye. The methoxy groups adjust the oxidation potential of spiro-MeOTAD such that the Ru complex can be regenerated efficiently. In the case of use of spiro-MeOTAD alone as a p-semiconductor, a maximum IPCE (incident photon to current conversion efficiency, external photon conversion efficiency) of 5% was found. When N(PhBr)₃SbCl₆ (as a dopant) and Li[CF₃SO₂)₂N] were also used, the IPCE rose to 33%, and the efficiency was 0.74%. The use of tert-butylpyridine as a solid p-semiconductor increased the efficiency to 2.56%, with an open-circuit voltage (V_{oc}) of approx. 910 mV and a short-circuit current I_{SC} of approx. 5 mA at an active area of approx. 1.07 cm² (see Kruger et al., Appl. Phys. Lett., 2001, 79, 2085). Dyes which achieved better coverage of the TiO₂ layer and which have good wetting on spiro-MeOTAD show efficiencies of more than 4%. Even better efficiencies (approx. 4.6%) were reported when the ruthenium complex was equipped with oxyethylene side chains.

L. Schmidt-Mende et al., Adv. Mater. 17, p. 813-815 (2005) proposed an indoline dye for dye solar cells with spirobifluorenes as the amorphous organic p-conductor. This organic dye, which has an extinction coefficient four times higher than a ruthenium complex, exhibits a high efficiency (4.1% at one sun) in solid dye solar cells. In addition, a concept was presented, in which polymeric p-semiconductors are bonded directly to an Ru dye (Peter, K., Appl. Phys. A. 2004, 79, 65). Durrant et al. Adv. Munc. Mater. 2006, 16, 1832-1838 state that, in many cases, the photocurrent is directly dependent on the yield at the hole transition from the oxidized dye to the solid p-conductor. This depends on two factors: firstly on the degree of penetration of the p-semiconductor into the oxide pores, and secondly on the thermodynamic driving force for the charge transfer (i.e. especially the difference in the free enthalpy ΔG between dye and p-conductor).

One disadvantage of the dye solar cell is that the proportion of light which can be used by the dye is generally limited by the energetic distance between the Fermi energies of the n- and p-conductors used. The photovoltage is generally also limited by this distance. In addition, dye solar cells generally have to be comparatively thin due to the charge transport required (for example 1-2.5 micrometers), and so the exploitation of the incident light is generally not optimal.

A further known technical challenge associated with dye solar cells is that of the long-term stability thereof. Particularly for use in durable products and articles such as motor vehicles or buildings, for example, stability of at least several months, more particularly several years, is required even under adverse ambient conditions. However, dye solar cells known from the prior art in many cases have an efficiency which declines significantly with time. More particularly, this effect can be observed on prolonged illumination of the dye solar cells, which leads to the conclusion that photophysical and chemical processes contribute to degradation of the components. There are thus conflicting aims, since illumination of the dye solar cells is required on the one hand for generation of electrical energy, but, at the same time, specifically this illumination contributes to degradation of the dye solar cells.

### OBJECT OF THE INVENTION

It is therefore an object of the present invention to provide a photovoltaic element and a process for producing a photovoltaic element, which at least substantially avoid the disadvantages of known photovoltaic elements and production processes. More particularly, a photovoltaic element having high long-term stability in operation is to be specified.

### DISCLOSURE OF THE INVENTION

This object is achieved by the invention having the features of the independent claims. Advantageous developments, which can be implemented individually or in any combination, are described in the dependent claims.

In a first aspect of the present invention, a photovoltaic element for conversion of electromagnetic energy to electrical energy is proposed. A photovoltaic element is generally understood to mean any element which is capable of such a conversion. The photovoltaic element may especially be configured fully or partly as a solar cell and/or as a photodiode. Particular preference is given in the context of the present invention to configurations of the photovoltaic element in the form of organic solar cells, i.e. in the form of solar cells which comprise at least one organic material, preferably at least one organic layer, for example at least one organic dye and/or at least one organic conductor material, for example an organic hole conductor material. Accordingly, the photovoltaic element may be configured especially as an organic solar cell and especially as a dye solar cell, especially as a dye solar cell with solid hole conductor material, also referred to hereinafter as SDSC. The electromagnetic radiation may especially be light in the ultraviolet and/or visible and/or infrared spectral region, preferably sunlight.

The photovoltaic element comprises the elements listed hereinafter. Preferably, but not necessarily, these elements are provided in the sequence mentioned. These elements may especially be present in a layer structure. For instance, the photovoltaic element comprises a first electrode and at least one n-semiconductive metal oxide. In addition, the photovoltaic element comprises at least one dye for absorption of at least a portion of the electromagnetic radiation. This dye preferably has an absorption in a visible spectral region of the electromagnetic radiation, preferably in a visible spectral region with a wavelength of at least 500 nm. In addition, the photovoltaic element comprises at least one organic hole conductor material and at least one second electrode. These elements may be applied, for example, in the sequence mentioned or else, for example, in reverse sequence to a substrate which may, for example, likewise be part of the photovoltaic element. This substrate may preferably be transparent, although it is also possible in principle to use nontransparent substrates. The substrate may, for example, comprise a glass substrate and/or a polymer substrate and may have a single-layer or else multilayer structure. More particularly, it is also possible to use multilayer substrates, for example laminated substrates.

The organic hole conductor material in the photovoltaic element has an absorption spectrum for the electromagnetic radiation having at least one absorption maximum in an ultraviolet or blue spectral region. This may be a local or else a global maximum. In general, “light” refers hereinafter to electromagnetic radiation with wavelengths between 100 nm and 1 cm. Visible light or light in the visible spectral region refers to light with a wavelength of 390 to 790 nm. The ultraviolet spectral region refers hereinafter to a spectral region between 100 nm and 390 nm. The infrared spectral region refers to a spectral region between 790 nm and 1 cm. The blue spectral region refers hereinafter to the spectral region between 390 and 480 nm.

The absorption spectrum of the organic hole conductor material then has, i.e. toward higher wavelengths proceeding from the absorption maximum, an absorption edge declining with the wavelength of the electromagnetic radiation and having a characteristic wavelength λ_{HTL}. This characteristic wavelength λ_{HTL} is defined such that the organic hole conductor material at this wavelength λ_{HTL} in the photovoltaic element has a decadic absorbance of 0.3. The decadic absorbance, also called decadic extinction, generally refers in the context of the present invention to the absorbance of the organic hole conductor material within the photovoltaic element based on the decadic system, which can be measured by means of an Ulbricht sphere in diffuse reflection on the photovoltaic element without the dye (see below). For this purpose, for example, the reflector used may be the respective counterelectrode, for example silver or gold. The reference used may be a reference cell without dye and without hole conductor. The absorbance E of the organic hole conductor material, also referred to as extinction or extinction of light, is determined from an absorption A of the organic hole conductor material in the photovoltaic element according to the formula:

A=1-10^{-E}.

For example, the absorbance of the hole conductor material in the photovoltaic element can thus be determined first by obtaining a layer structure including a substrate, the first electrode, the n-semiconductive metal oxide, the organic hole conductor material and the second electrode, i.e. without the dye, which is irradiated in an Ulbricht sphere with light of intensity I₀, where the intensity is I due to the absorption of the organic hole conductor material after passage through the photovoltaic element, where the absorption A is calculated as the quotient A=I/I₀. The reference value determined may be a corresponding absorption for a reference cell having neither dye nor the organic hole conductor material. The absorption A_{Ref} determined in this reference measurement can be subtracted from the total absorption determined beforehand in order to determine the absorption of the organic hole conductor material. From this absorption of the organic hole conductor material in the photovoltaic element, it is then in turn possible to use the formula described above to determine the absorbance of the organic hole conductor material in the photovoltaic element. At the characteristic wavelength λ_{HTL}, the decadic absorbance is by definition exactly 0.3, from which an absorption at this characteristic wavelength of 0.5 is calculated.

The photovoltaic element additionally has at least one longpass filter. A longpass filter is generally understood to mean an optical element which has a high absorption in a low wavelength range and a low absorption in a higher wavelength range, for example a high absorption in a blue and/or ultraviolet spectral region and a lower absorption in a green, red or infrared spectral region. More particularly, the longpass filter may be configured as an edge filter and/or comprise an edge filter. The longpass filter has a transmission edge rising with the wavelength of the electromagnetic radiation and having a characteristic wavelength λ_{LP}. This characteristic wavelength λ_{LP} is defined such that a transmission T of the longpass filter at λ_{LP} is 50% of the maximum transmission of the longpass filter. The transmission is defined as a quotient of an intensity of electromagnetic radiation transmitted by the filter, divided by the starting intensity of electromagnetic radiation incident on the filter, multiplied by 100%. Thus, if the longpass filter, for example in its transmission range, has a maximum transmission of 85%, the characteristic wavelength λ_{LP} for this case is defined as that wavelength at which the longpass filter attains a transmission of 0.5×85%=42.5%, for example when viewing the transmission spectrum with rising wavelengths. This characteristic wavelength λ_{LP} is typically a characteristic wavelength in an absorption edge of the longpass filter. This definition is naturally meaningful only for longpass filters in which transmissions of less than half of the maximum transmission occur in at least one wavelength range, and so such longpass filters are generally preferred in the context of the present invention.

A further provision is configuration of the photovoltaic element such that λ_{LP} is within a spectral range from λ_{HTL}−30 nm to λ_{HTL}+30 nm. In other words, the following relationship shall apply: λ_{HTL}−30 nm≦λ_{LP}≦λ_{HTL}+30 nm. For example, for the commercially available organic hole conductor spiro-MeOTAD, which is described in more detail below, the characteristic wavelength λ_{HTL} is 24 nm. For this organic hole conductor, preference is thus given to using a longpass filter having a characteristic wavelength λ_{LP} within a range from 394 nm to 454 nm. More preferably, the relationship λ_{HTL}−20 nm≦λ_{LP}≦λ_{HTL}±20 nm applies, and more preferably λ_{HTL}−10 nm≦λ_{LP}≦λ_{HTL}+10 nm. Said condition of matching the longpass filter to the absorption of the organic hole conductor material is based on the finding, which is still to be confirmed experimentally below, that degradation of the organic components is attributable essentially to unwanted absorption of the electromagnetic radiation by the organic hole conductor material. Said condition of matching the longpass filter to the spectral properties of the organic hole conductor material can at least substantially compensate for this disadvantage.

At λ_{LP}, the transmission of the longpass filter has fallen to 50%, based on the maximum transmission of the longpass filter. The longpass filter preferably has a maximum transmission which is at least 75%, especially at least 80%, preferably at least 85% or even at least 90% or at least 95%. The wavelength λ_{LP} is specified in many cases by the manufacturers and suppliers of the longpass filters, particularly of the edge filters.

Particular preference is given to using, in the context of the present invention and in the context of the present photovoltaic elements, one or more organic hole conductor materials which have an absorption edge at low wavelengths, preferably in the blue spectral region. It is particularly preferred when λ_{HTL}≦440 nm, especially λ_{HTL}≦430 nm, more preferably λ_{HTL}≦425 nm and especially λ_{HTL}=425 nm. This condition is met for the abovementioned spiro-MeOTAD.

The form of absorption spectrum of the organic hole conductor material may especially be such that, at a wavelength λ_{HTL}+30 nm in the photovoltaic element, it has declined to a decadic absorbance of less than 0.2, preferably to less than 0.1 and more preferably to less than 0.05. More particularly, the organic hole conductor material in the photovoltaic element, for wavelengths of λ_{HTL}+30 nm to 800 nm, may have a decadic absorbance of less than 0.2, preferably of less than 0.1 and more preferably of less than 0.05.

It is particularly preferred when the longpass filter has a steep absorption edge in order that a maximum number of photons can be absorbed on the short-wave side of λ_{LP} and a maximum number of photons can be transmitted on the long-wave side of A_{LP}. The steepness of the longpass filter is typically reported in the unit of electron volts (eV) and is defined typically as:

$${S}_{LP} = h \cdot c \cdot ( \frac{1}{{λ}_{LP , block}} - \frac{1}{{λ}_{LP , trans}} ) .$$

λ_{LP,block} here is that wavelength at which the optical density of the longpass filter attains the value of 2. For example, λ_{LP,block} is that wavelength at which the optical density goes below the value of 2 with rising wavelength. This definition is naturally meaningful only for longpass filters whose optical density in at least one wavelength range, more particularly a blocking range, attains at least the value of 2, preferably at least a value of 3 and more preferably a value of at least 4, and so particular preference is given to such longpass filters in the context of the present invention. The optical density is another way of expressing the above-defined absorbance. At wavelengths below λ_{LP,block}, the longpass filter should preferably have an optical density of ≧2, particularly an optical density of ≧3, and at wavelengths <λ_{LP,block} an optical density of <2. λ_{LP,trans} is defined as that wavelength at which the transmission T attains a value of 95% of the maximum transmission of the longpass filter. At wavelengths of <λ_{LP,trans}, the transmission should thus be <95% of the maximum transmission of the longpass filter, and at wavelengths greater than λ_{LP,trans}≧95% of the maximum transmission of the longpass filter, for example 95% to 100% of the maximum transmission of the longpass filter. If, for example, the longpass filter, more particularly in a transmission region, has a maximum transmission of 85%, λ_{LP,trans} is defined as that wavelength at which, for example with rising wavelength, the transmission attains a value of 0.95×85%=80.75%. In addition, in the abovementioned formula for the steepness of the longpass filter, the parameter h denotes Planck's constant (h≈6.626·10⁻³⁴ Js) and c the speed of light in a vacuum (c≈3.0·10⁸ m/s). With steepness defined in such a way, preferably, the steepness S_{LP}≦1.2 eV, preferably S_{LP}≦1.0 eV and more preferably S_{LP}≦0.8 eV.

As described above, the photovoltaic element may especially have a transparent substrate. For example, a transparent substrate can be used in combination with a transparent first electrode which has been applied directly or indirectly to the transparent substrate. Accordingly, the photovoltaic element may more preferably be configured such that the electromagnetic radiation can enter the photovoltaic element, particularly the above-described layer structure, through the substrate. A transparent substrate is understood to mean a substrate which, in the abovementioned visible spectral region, has a transmission of at least 50%, preferably of at least 70% and more preferably of at least 90%. If a transparent substrate is used, it is particularly preferred when the longpass filter has been applied to the transparent substrate. This can be accomplished in various ways, which can also be combined with one another. For example, the longpass filter may be configured independently of the above-described layer structure, for example by virtue of the longpass filter not being bonded directly to the substrate and the abovementioned layers. Alternatively or additionally, however, the at least one longpass filter may also be applied, for example, on one or more sides of the transparent substrate, for example on a side of the substrate facing the layer structure and/or on a side of the substrate remote from the layer structure. For example, the first electrode or the second electrode may be applied on a first side of the substrate, the longpass filter having been applied on a second side of the substrate remote from the first side. Alternatively or additionally, the longpass filter may, however, also be arranged, for example, between the substrate and the first electrode or the second electrode, for example by virtue of the longpass filter first being applied to the substrate and then the first electrode or the second electrode.

As described above, the longpass filter in at least one transmission region preferably has a maximum transmission of at least 75%, especially at least 80%, at least 85%, at least 90% or even at least 95%. The longpass filter preferably has, in at least one absorption region, i.e., for example, a region below the wavelength λ_{LP,block}, a decadic absorbance of at least 2, preferably of at least 3 and more preferably of at least 4.

In a preferred embodiment of the invention, the longpass filter comprises at least one transparent organic matrix material and at least one absorber material introduced, especially mixed, into the matrix material.

More preferably, this matrix material comprises at least one varnish, said varnish preferably being a clearcoat. Such clearcoats are well known to the person skilled in the art. The varnish, preferably the clearcoat, is preferably selected from the group consisting of polyacrylate-polyester varnishes, polyurethane varnishes, melamine-formaldehyde varnishes and further commercial clearcoats.

The varnish is preferably a polyacrylate-polyester varnish. The term “polyester-polyacrylate varnish” as used in the context of the present invention comprises single- and multicomponent varnishes, said varnish preferably consisting of at least one polyacrylate and at least one polyester. The varnish typically comprises, as well as the at least one polyacrylate and the at least one polyester, copolymers, especially polyacrylate-polyester copolymers. A suitable example is the varnish AF 23-0447 (BASF Coatings).

The varnish is preferably produced by application of a coating composition. This coating composition which comprises the varnish or forms the varnish can be applied, for example, to a substrate of the photovoltaic element, for example by one or more of the operations of spin coating, printing, casting and knife coating. For example, the coating composition can be applied and cured on the substrate to form the varnish.

If the varnish is a polyester-polyacrylate varnish, this coating composition preferably comprises at least one component (A) and a component (B), (A) being a polyester resin and (B) a polyacrylate resin.

Component (A) is preferably obtainable by reaction of polycarboxylic acids or the esterifiable derivatives thereof, optionally together with monocarboxylic acids, polyols and/or monools. Optionally, in this reaction, further modifying components and/or reactive components are also added.

Examples of polycarboxylic acids which can be used include aromatic, aliphatic and cycloaliphatic polycarboxylic acids. Examples of suitable polycarboxylic acids are phthalic acid, isophthalic acid, terephthalic acid, halophthalic acids such as tetrachloro- or tetrabromophthalic acid, adipic acid, glutaric acid, azelaic acid, sebacic acid, fumaric acid, maleic acid, trimellitic acid, pyromellitic acid, tetrahydrophthalic acid, hexahydrophthalic acid, 1,2-, 1,3- and 1,4-cyclohexanedicarboxylic acid, 4-methylhexahydrophthalic acid, endomethylenetetrahydrophthalic acid, tricyclodecanedicarboxylic acid, endoethylene-hexahydrophthalic acid, camphoric acid, cyclohexanetetracarboxylic acid, cyclobutanetetracarboxylic acid and the like. It is optionally possible to use, together with the polycarboxylic acids, also monocarboxylic acids, for example benzoic acid, tert-butylbenzoic acid, lauric acid, isononanoic acid and fatty acids of naturally occurring oils. The monocarboxylic acid used is preferably, for example, isononanoic acid.

Suitable polyol components for preparation of the polyester are polyhydric alcohols such as ethylene glycol, propanediols, butanediols, hexanediols, neopentyl glycol, diethylene glycol, trimethylpentanediol, ethylbutylpropanediol, trimethylolpropane, ditrimethylolpropane, trimethylolethane, glycerol, pentaerythritol, dipentaerythritol, trishydroxyethyl isocyanate, polyethylene glycol, polypropylene glycol, optionally together with monohydric alcohols, for example butanol, octanol, lauryl alcohol, ethoxylated or propoxylated phenols.

Optional further modifying components for preparation of the polyesters include especially compounds which have at least one group reactive toward the functional groups of the polyester, for example polyisocyanates and/or diepoxide compounds, and optionally also monoisocyanates and/or monoepoxide compounds. Suitable components are described, for example, in DE-A-40 24 204 on page 4 lines 4 to 9.

Suitable further components are compounds which, apart from a group reactive toward the functional groups of the polyester, also have a tertiary amino group, for example monoisocyanates having at least one tertiary amino group. For further details, reference is made to DE-A-40 24 204, page 4 lines 10 to 49.

The polyesters are prepared by the methods of esterification known to those skilled in the art (see, for example, Ullmanns Enzyklopädie der technischen Chemie, Volume 14, pages 80 to 106, 1963).

With regard to the polyacrylate resin, there are in principle no restrictions here. The polyacrylate resin is prepared by the methods known to those skilled in the art. The polyacrylate resin (B) is preferably prepared partly in the presence of the polyester resin (A).

Examples of suitable monomers for preparation of the polyacrylate resin include the following: acrylic acid, methacrylic acid, β-carboxyethyl acrylate, and the olefinically unsaturated monomers which comprise sulpho/sulphonate groups and are described in WO-A 00/39181 (page 8 line 13-page 9 line 19), one example of which is 2-acrylamido-2-methylpropanesulphonic acid. Preference is given to using carboxy-functional monomers, more preferably acrylic acid and/or methacrylic acid.

Examples also include hydroxyethyl methacrylate, hydroxypropyl methacrylate, hydroxyethyl acrylate, hydroxypropyl acrylate, hydroxybutyl acrylate, hydroxybutyl methacrylate, or hydroxyl monomers comprising alkylene oxide units, for example addition products of ethylene oxide, propylene oxide or butylene oxide onto (meth)acrylic acid, (meth)acrylic acid hydroxyl esters or (meth)allyl alcohol, and also the mono- and diallyl ethers of trimethylolpropane, glycerol or pentaerythritol. Further examples include (meth)acrylic esters, for example methyl acrylate, ethyl acrylate, n-butyl acrylate, isobutyl acrylate, tert-butyl acrylate, 2-ethylhexyl acrylate, methyl methacrylate, ethyl methacrylate, butyl methacrylate, 2-ethylhexyl methacrylate, hexyl acrylate, lauryl acrylate, monomers comprising cyclic hydrocarbyl radicals, such as cyclohexyl(meth)acrylate, cyclohexyl(meth)acrylates substituted on the ring by alkyl groups, isobornyl(meth)acrylate or norbornyl(meth)acrylate, condensation products of (meth)acrylic acid with oligoalkylene oxide monoalkyl ethers, and monomers having further functional groups, for example epoxy groups, alkoxysilyl groups, urea groups, urethane groups, amide groups or nitrile groups. It is also possible to use difunctional or higher-functionality (meth)acrylate monomers and/or vinyl monomers, for example hexanediol di(meth)acrylate, ethylene glycol diacrylate.

Polymerization processes for preparation of polyacrylate resins are common knowledge and have been described many times (see, for example: Houben-Weyl, Methoden der organischen Chemie [Methods of Organic Chemistry], 4th edition, volume 14/1, pages 24 to 255 (1961)).

The coating composition preferably comprises at least one crosslinking agent (C). Useful crosslinking agents (hardeners) include all substances known to those skilled in the art for this purpose. The crosslinker is preferably selected from the group consisting of polyisocyanates, amide- and amine-formaldehyde resins, phenol resins, aldehyde resins and ketone resins. The crosslinker is preferably a polyisocyanate.

Accordingly, the present invention also relates to a photovoltaic element as described above, wherein the varnish is applied by applying at least one coating composition, and wherein the coating composition comprises at least one polyester resin (A), at least one polyacrylate resin (B), optionally copolymers, and preferably at least one crosslinking agent, said crosslinking agent preferably being selected from the group consisting of polyisocyanates, amide- and amine-formaldehyde resins, phenol resins, aldehyde resins and ketone resins, said crosslinking agent further preferably being a polyisocyanate.

When the at least one crosslinking agent is a polyisocyanate, it may comprise any organic polyisocyanates with aliphatically, cycloaliphatically and/or aromatically bonded, free isocyanate groups. Preference is given to using polyisocyanates having 2 to 5 isocyanate groups per molecule. Optionally, small amounts of organic solvent can be added to the polyisocyanates in the coating composition, preferably, for example, up to 10% by weight based on pure polyisocyanate, in order thus to improve the incorporability of the isocyanate. Solvents suitable as additives for the polyisocyanates are, for example, ethoxyethyl propionate, butyl acetate and the like.

Examples of suitable isocyanates are described, for example, in “Methoden der organischen Chemie”, Houben-Weyl, Volume 14/2, 4th Edition, Georg Thieme Verlag, Stuttgart 1963, pages 61 to 70, and by W. Siefken, Liebigs Ann. Chem. 562, 75 to 136. Suitable examples include ethylene 1,2-diisocyanate, tetramethylene 1,4-diisocyanate, hexamethylene 1,6-diisocyanate, 2,2,4- or 2,4,4-trimethylhexamethylene 1,6-diisocyanate, dodecane 1,12-diisocyanate, omega,omega′-diisocyanatodipropyl ether, cyclobutane 1,3-diisocyanate, cyclohexane 1,3- and 1,4-diisocyanate, 2,2- and 2,6-diisocyanato-1-methylcyclohexane, 3-isocyanatomethyl-3,5,5-trimethylcyclohexyl isocyanate, 2,5- and 3,5-bis(isocyanatomethyl)-8-methyl-1,4-methanodecahydronaphthalene, 1,5-, 2,5-, 1,6- and 2,6-bis(isocyanatomethyl)-4,7-methanohexahydroindane, 1,5-, 2,5-, 1,6- and 2,6-bis(isocyanato)-4,7-methanohexahydroindane, dicyclohexyl 2,4′- and 4,4′-diisocyanate, hexahydrotolylene 2,4- and 2,6-diisocyanate, perhydro(diphenylmethane 2,4′- and 4,4′-diisocyanate), ω,ω′-diisocyanato-1,4-diethylbenzene, phenylene 1,3- and 1,4-diisocyanate, 4,4′-diisocyanatodiphenyl, 4,4′-diisocyanato-3,3′-dichlorodiphenyl, 4,4′-diisocyanato-3,3′-dimethoxydiphenyl, 4,4′-diisocyanato-3,3′-dimethyldiphenyl, 4,4′-diisocyanato-3,3′-diphenyl-diphenyl, 2,4′- and 4,4′-diisocyanatodiphenylmethane, naphthylene 1,5-diisocyanate, tolylene diisocyanates such as tolylene 2,4- or 2,6-diisocyanate, N,N′-(4,4′-dimethyl-3,3′-diisocyanatodiphenyl)uretdione, m-xylylene diisocyanate, dicyclohexylmethane diisocyanate, tetramethylxylylene diisocyanate, but also triisocyanates such as 2,4,4′-triisocyanatodiphenyl ether, 4,4′,4″-triisocyanatotriphenyl-methane.

Preference is given to using, optionally in combination with the abovementioned polyisocyanates, polyisocyanates having isocyanurate groups and/or biurethane groups and/or allophanate groups and/or urethane groups and/or urea groups. Polyisocyanates having urethane groups are obtained, for example, by reacting some of the isocyanate groups with polyols, for example trimethylolpropane and glycerol.

Preference is given to using aliphatic or cycloaliphatic polyisocyanates, especially hexamethylene diisocyanate, dimerized and trimerized hexamethylene diisocyanate, isophorone diisocyanate, dicyclohexylmethane 2,4′-diisocyanate or dicyclohexylmethane 4,4′-diisocyanate, or mixtures of these polyisocyanates. Very particular preference is given to using mixtures of polyisocyanates which have uretdione and/or isocyanurate groups and/or allophanate groups and are based on hexamethylene diisocyanate, as formed through catalytic oligomerization of hexamethylene diisocyanate using suitable catalysts. The polyisocyanate component (C) may otherwise also consist of any desired mixtures of the polyisocyanates mentioned by way of example.

Examples include the following commercially available crosslinking agents: SC29-0035, SC29-0031, SC29-0034 (BASF Coatings).

As well the abovementioned components, the coating composition may further comprise at least one diluent. The term “diluent” as used in the context of the present invention comprises solvents and solvent mixtures which are selected according to the drying requirements on the varnish. The solvents used here are especially organic solvents selected from the group consisting of solvents comprising acetate groups, aromatic solvents and gasoline. Examples include the following commercially available diluents: SV42-0150, SV41-0391, SV41-0316 (BASF Coatings).

In a further preferred configuration of the invention, the matrix material, preferably the above-described varnish, comprises at least one organic absorber material, for example 1, 2, 3, 4 or 5 organic absorber materials.

The term “absorber material” as used in the context of the present invention is understood to mean UV stabilizers, i.e. chemical compounds which are introduced into the matrix material as additives as protection against ageing of the matrix material by UV radiation.

This absorber material is preferably an organic absorber material, further preferably an organic absorber material selected from compounds comprising a benzotriazole group or a triazine group.

In a preferred embodiment of the invention, the longpass filter comprises at least two different absorber materials introduced, especially mixed, into the matrix material.

When the longpass filter comprises at least two different absorber materials, preferably at least one of these absorber materials is a compound which comprises a triazine group. In this context, the scope of the invention comprises, for example, embodiments in which one of the absorber materials is a compound comprising triazine groups and the at least one second absorber material is likewise a compound comprising triazine groups different than the first absorber material. The term “different” in this case means that the two organic compounds differ in at least one substituent or functional group. Also encompassed are embodiments in which one of the absorber materials is a compound comprising triazine groups and the at least one second absorber material is an inorganic or organic absorber material which does not comprise a triazine group, for example a compound comprising a benzotriazole group.

With regard to absorber materials comprising a triazine group, this absorber material preferably has the structure of the formula

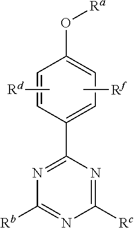

where R^{a} is selected from the group consisting of H, -alkyl, O-alkyl-O-alkyl*, cycloalkyl, alkenyl, aryl and —SO₃H,

and where R^{b} and R^{c} are each independently selected from the group consisting of H, halides, alkyl, cycloalkyl, aryl, heteroaryl, O-alkyl and —S-alkyl,

and where R^{d} and R^{f} are each independently selected from the group consisting of H, —OH; O-alkyl, —NR′R″, —S-alkyl, —SO₃H and COOalkyl,

and where R′ and R″ are each independently H or alkyl.

The term “alkyl” or “alkyl radical” or “alkyl*” as used in the context of the present invention is generally understood to mean substituted or unsubstituted C₁-C₂₅-alkyl radicals. Preference is given to C₁- to C₁₀-alkyl radicals, particular preference to C₁- to C₈-alkyl radicals. The alkyl radicals may be either unbranched or branched. In addition, the alkyl radicals may be substituted or unsubstituted. Preferred alkyl radicals are methyl, ethyl, propyl, butyl, pentyl, hexyl, heptyl and octyl, and also isopropyl, isobutyl, isopentyl, sec-butyl, tert-butyl, neopentyl, 3,3-dimethylbutyl and 2-ethylhexyl.

The term “aryl” or “aryl group” or “aryl radical” as used in the context of the present invention is understood to mean optionally substituted C₆-C₃₀-aryl radicals derived from monocyclic, bicyclic, tricyclic and polycyclic aromatic rings, and wherein the aromatic rings do not comprise any ring heteroatoms. The aryl radical preferably comprises 5- and/or 6-membered aromatic rings. When the systems are not monocyclic systems, in the case of the term “aryl”, the saturated form (perhydro form) or the partially unsaturated form (for example the dihydro form or tetrahydro form) is also possible for the second ring, provided that the respective forms are known and stable. Thus, the term “aryl” in the context of the present invention also comprises, for example, bicyclic or tricyclic radicals in which either both or all three radicals are aromatic, and bicyclic or tricyclic radicals in which only one ring is aromatic, and tricyclic radicals in which two rings are aromatic.

The term “heteroaryl” or “heteroaryl group” or “heteroaryl radical” as used in the context of the present invention is understood to mean optionally substituted 5- and 6-membered aromatic rings and polycyclic rings, for example bicyclic or tricyclic compounds, which have at least one heteroatom in at least one ring. The heteroaryls in the context of the invention comprise preferably 5 to 30 ring atoms. They may be monocyclic, bicyclic or tricyclic, and some can be derived from the aforementioned aryl in which at least one carbon atom in the aryl base skeleton has been replaced by a heteroatom. Preferred heteroatoms are N, O and S. More preferably, the heteroaryl radicals have 5 to 13 ring atoms.

The term “optionally substituted” in the context of the invention relates to radicals in which at least one hydrogen radical of an alkyl group, aryl group or heteroaryl group has been replaced by a substituent. With regard to the nature of this substituent, preferential mention is made of alkyl radicals, especially methyl, halogen, carboxyl groups, ester groups and hydroxyl radicals.

In a preferred embodiment of the invention, at least one of the R^{b} and R^{c} radicals is an aryl radical or heteroaryl radical, for example an optionally substituted radical selected from the group consisting of phenyl, biphenyl, naphthyl, pyrrolyl and pyridyl. Preferably, at least one of the R^{b} and R^{c} radicals is an aryl radical, further preferably a phenyl radical, and further preferably a phenyl radical substituted by at least one methyl group, preferably by at least two methyl groups.

In a preferred embodiment of the invention, the R^{b} and R^{c} radicals are each aryl radicals, further preferably phenyl radicals, and further preferably phenyl radicals substituted by at least two methyl groups.

When at least one of the R^{b} and R^{c} radicals is an aryl radical, it preferably has the structure

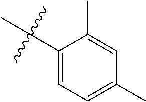

Accordingly, the present invention also describes a longpass filter comprising at least two different absorber materials introduced, especially mixed, into the matrix material, at least one absorber material being a compound with the following structure:

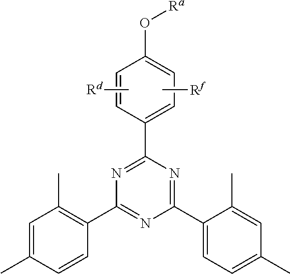

In a further preferred embodiment, the absorber material has the following structure:

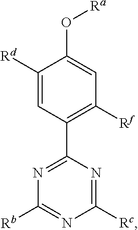

especially the following structure:

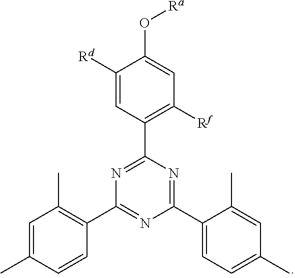

With regard to the R^{d} and R^{f} radicals, these are, as described above, each independently selected from the group consisting of H, —OH; O-alkyl, —NR′R″, —S-alkyl, —SO₃H and —COOalkyl; more preferably, R^{f} is —OH and R^{d} is alkyl or H, preferably H.

With regard to the R^{a} radical, it is preferably —OH, -alkyl or —O-alkyl-O-alkyl, especially —OH or O-alkyl-O-alkyl where the two alkyl groups may be different than one another. The O-alkyl-O-alkyl radical preferably has the structure —CH2C(H)(OH)—CH2-O-alkyl, in which case alkyl is preferably a linear alkyl group, especially a linear alkyl group having 12 or 13 carbon atoms.

Examples include the following absorber materials:

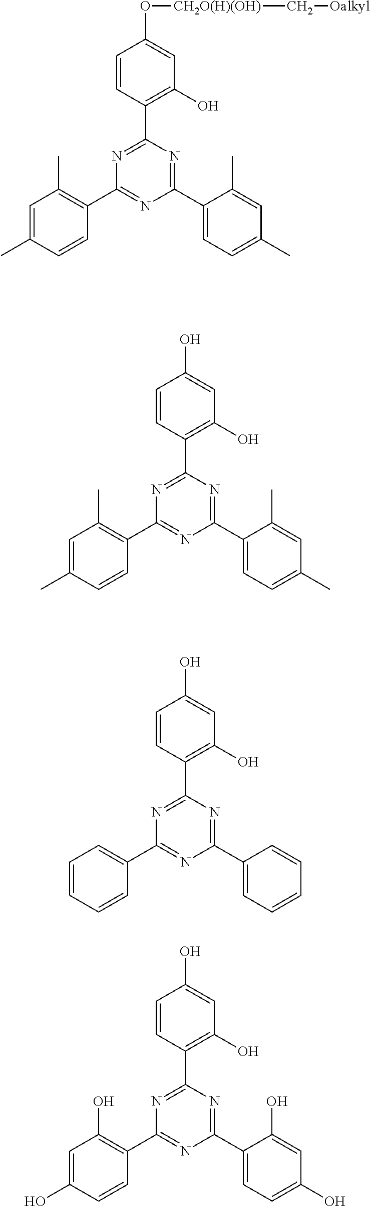

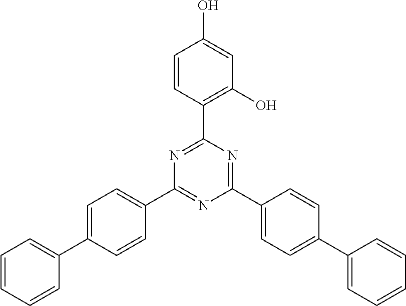

In a particularly preferred embodiment of the invention, the at least one absorber material has a structure of the following formula:

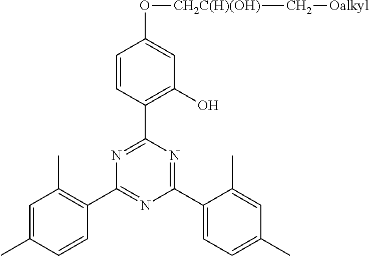

where alkyl is preferably a linear alkyl group, especially a linear alkyl group having 12 or 13 carbon atoms. More particularly, the absorber material is Tinuvin® 400.

In a preferred embodiment, the longpass filter comprises, as at least one absorber material, a compound comprising benzotriazole groups, preferably a compound of the following formula:

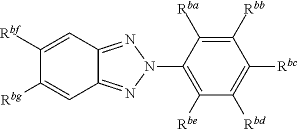

where R^{ba}, R^{bb}, R^{bc}, R^{bd} and R^{be} are each independently selected from the group consisting of H, -alkyl, —OH, -alkylaryl, -alkylheteroaryl, -cycloalkyl, cycloheteroalkyl, alkenyl, aryl and —SO₃H,

and where R^{bf} and R^{bg} are each independently selected from the group consisting of H, halides, alkyl, cycloalkyl, aryl, heteroaryl and radicals in which R^{bf} and R^{bg} form an optionally substituted cycloalkyl or cycloheteroalkyl preferably a 5- or 6-membered cycloalkyl or cycloheteroalkyl ring. The term “cycloheteroalkyl ring” or ““cycloheteroalkyl” within the meaning of the present invention is denoted to mean a non-aromatic monocyclic or polycyclic alkyl ring comprising at least one heteroatom and may, also be referred to as heterocycloalkyl ring.

The term “alkylaryl” as used in the context of the present invention relates to radicals with the -alkyl-aryl structure which are attached via the alkyl group. Both the alkyl group and the aryl group include substituted radicals in this context. With regard to the term “substituted”, reference is made to the above remarks.

The term “alkylheteroaryl” as used in the context of the present invention relates to radicals with the -alkyl-heteroaryl structure which are attached via the alkyl group. Both the alkyl group and the heteroaryl group include substituted radicals in this context. With regard to the term “substituted”, reference is made to the above remarks.

Preferably, R^{bf} and R^{bg} form an optionally substituted cycloalkyl or cycloheteroalkyl ring. Such benzotriazole-comprising compounds are disclosed, for example in WO 2008/000646.

More preferably, the longpass filter comprises, as at least one absorber material, a compound which comprises benzotriazole groups and is selected from the compounds of the following formulae:

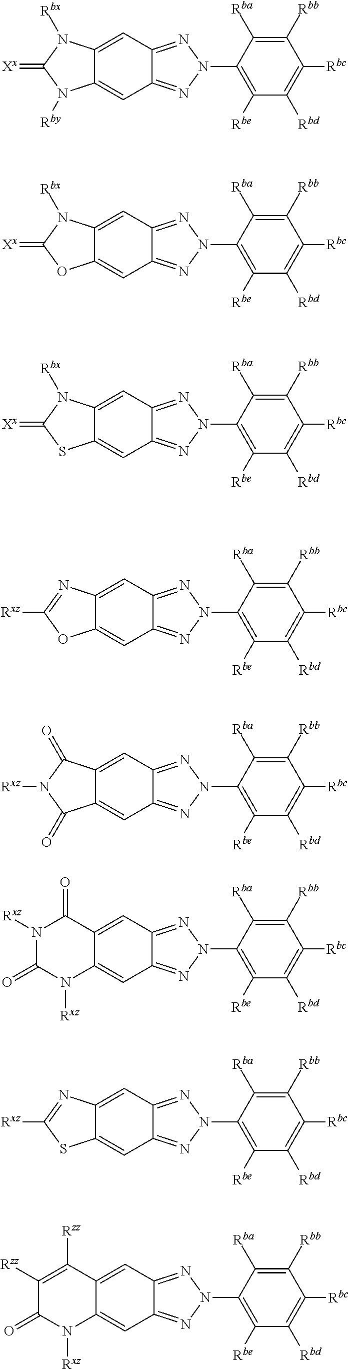

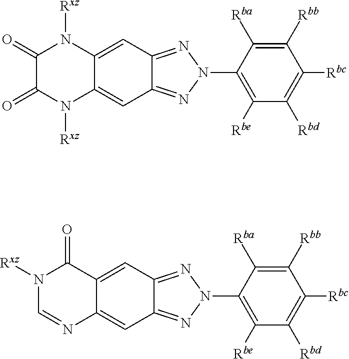

where R^{bx}, R^{by} and R^{xz} are each independently radicals selected from the group consisting of H, alkyl, aryl, heteroaryl, alkylaryl, alkylheteroaryl, alkenyl and alkynyl,

X^{x} is O or S,

and R^{zz} is selected from the group consisting of H, —C(═O)R^{xz}, alkyl, alkenyl, alkynyl, aryl, cycloalkyl, heteroaryl and cycloheteroalkyl.

In a preferred embodiment, at least one of the R^{ba}, R^{bb}, R^{bc}, R^{ba} and R^{be} radicals is —OH; preferably, R^{ba} is —OH. Accordingly, the benzotriazole-comprising compound is preferably a compound of the following formula:

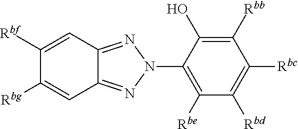

further preferably a compound selected from the compounds of the following formulae:

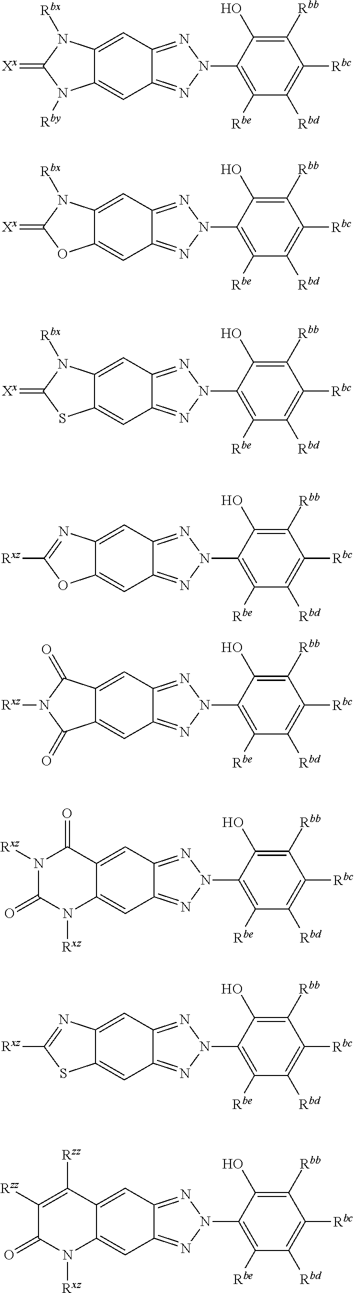

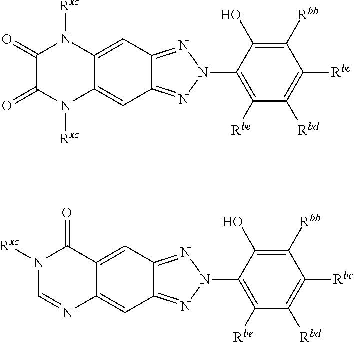

In a preferred embodiment, R^{bc} and R^{be} are both H.

More preferably, the benzotriazole-comprising compound is a compound of the following formula:

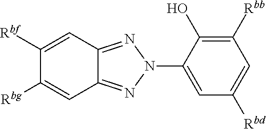

further preferably a compound selected from the compounds of the following formulae:

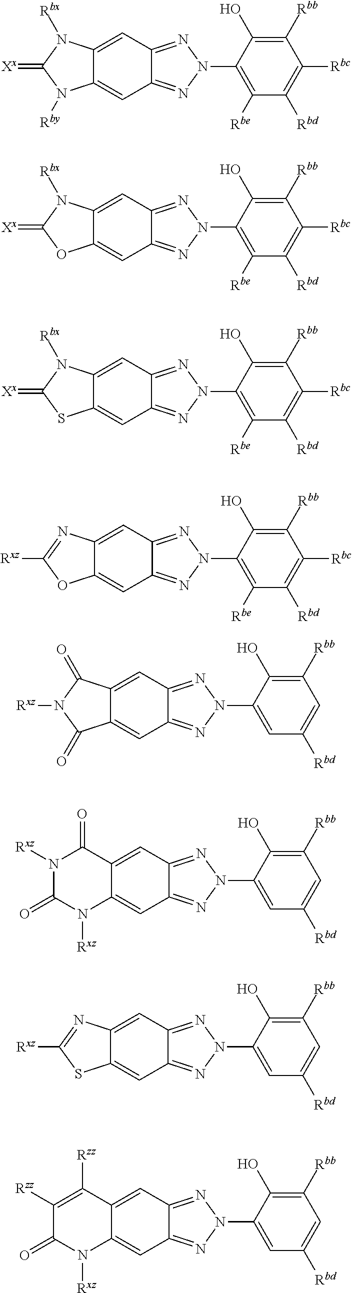

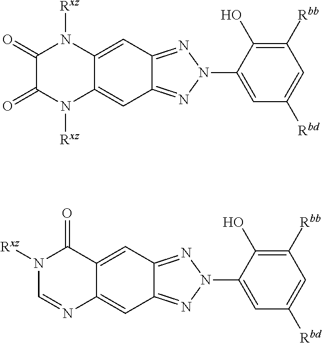

More preferably, the benzotriazole-comprising compound is a compound of the following formula:

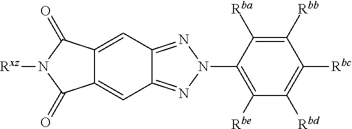

especially of the following formula:

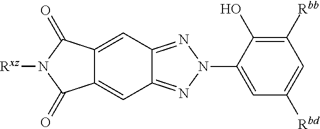

where R^{xz} is preferably alkyl, especially a C2-C20 alkyl radical. R^{bb} and R^{bd} are preferably each independently alkylaryl groups, especially alkylphenyl groups, or alkyl groups, especially alkyl groups having 5 to 15 carbon atoms.

Examples include the brand names of the following commercially available absorbers comprising a benzotriazole group: TINUVIN 384, TINUVIN 928, TINUVIN 900, TINUVIN 328 and TINUVIN 1130, and Xymara® Carboprotect (BASF).

When the longpass filter comprises at least two different absorber materials introduced, especially mixed, into the matrix material, one absorber material is preferably a compound comprising a triazine as described above, especially a compound of the formula:

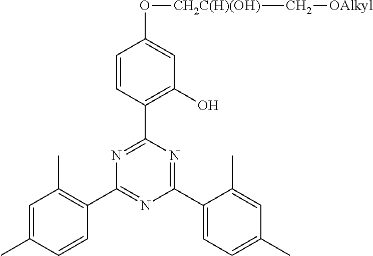

where alkyl is preferably a linear alkyl group, especially a linear alkyl group having 12 or 13 carbon atoms, and the second absorber material is preferably a benzotriazole-comprising compound, especially a compound of the following formula:

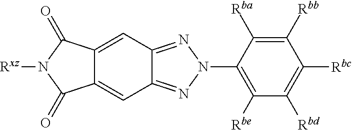

further preferably of the following formula:

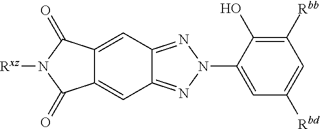

In a particularly preferred embodiment, the matrix material comprises Xymara® Carboprotect, especially Tinuvin 400 and Xymara® Carboprotect.

When the longpass filter comprises a triazine-comprising compound, the matrix material comprises this compound preferably in an amount in the range from 0.05 to 3% by weight, preferably in an amount in the range from 0.1 to 2.5% by weight, and further preferably in an amount in the range from 0.2 to 2% by weight, based on the total weight of the matrix material.

When the longpass filter comprises a benzotriazole-comprising compound, the matrix material comprises this compound preferably in an amount in the range from 0.05 to 3% by weight, preferably in an amount in the range from 0.1 to 2.5% by weight, and further preferably in an amount in the range from 0.2 to 2% by weight, based on the total weight of the matrix material.

When the longpass filter comprises a triazine-comprising compound and a benzotriazole-comprising compound, the matrix material comprises the benzotriazole-comprising compound preferably in an amount in the range from 0.05 to 3% by weight, preferably in an amount in the range from 0.1 to 2.5% by weight and further preferably in an amount in the range from 0.2 to 2% by weight, and the compound comprising a triazine group preferably in the range from 0.05 to 3% by weight, preferably in an amount in the range from 0.1 to 2.5% by weight, and further preferably in an amount in the range from 0.2 to 2% by weight, based in each case on the total weight of the matrix material.

Further preferred configurations of the invention relate to the organic hole conductor material. This may especially be a solid organic hole conductor material or comprise at least one solid organic hole conductor material. The organic hole conductor material more preferably comprises an arylamine compound and/or a spiro compound, or is configured as such an arylamine compound and/or as a Spiro compound. More particularly, it may be a spiro compound. Examples are cited in more detail below. Particular preference is given to the use of spiro-MeOTAD, further details of which are likewise given below. Alternatively or additionally, the organic hole conductor material may comprise a compound having the structural formula (I) elucidated in detail below. Such hole conductor materials, especially Spiro compounds, have a short-wave absorption spectrum which generally has a characteristic wavelength λ_{HTL} in a region below typically 440 nm and especially below 430 nm, such that this characteristic wavelength is generally at a clear distance in the spectrum from the absorption of the dye of the photovoltaic element, which typically has an absorption maximum within a spectral range from 500 to 800 nm, preferably within a spectral range from 550 to 700 nm. In this way, use of a sufficiently steep longpass filter can effectively prevent or at least suppress the absorption by the organic hole conductor material, whereas the absorption by the dye, which is desired in the context of the function of the photovoltaic element, is influenced only insignificantly, if at all.

Further preferred configurations relate to the at least one longpass filter. Usable longpass filters are in principle any filter materials and/or filter structures which have the abovementioned properties. Useful filter materials here are in principle organic and/or inorganic filter materials. Thus, in a preferred configuration, the longpass filter may especially comprise at least one inorganic filter material, especially a metal oxide and more preferably an inorganic filter material selected from the group consisting of: SiO₂; TiO₂; ZrO₂ and Ta₂O₅. The longpass filter may especially have at least one layer structure with one or more layers, for example with one or more layers of the inorganic and/or organic filter material. For application of the at least one filter material, it is possible to use different processes. For example, physical vapor phase deposition processes such as sputtering, vapor deposition or similar processes can be used, and/or chemical vapor phase deposition processes. Alternatively or additionally, it is also possible to use one or more wet-chemical processes, for example what are called sol-gel processes. In a sol-gel process, one or more dispersions, especially colloidal dispersions, of the at least one filter material and/or of at least one starting material of the at least one filter material, for example of at least one precursor, are used. For example, these may comprise one or more alkoxides of one or more metals. These dispersions are generally referred to as sols. Sol particles are deposited on the substrate and gelate there, with conversion of the sol to an at least nearly solid or gelated state, which is referred to as a gel and may generally still comprise solvent components. The substrate coated in this way can be dried and optionally then subjected to a thermal treatment, for example to one or more sintering steps. In sol-gel processes, it is generally possible to use wet-chemical processes to apply the sol to the substrate, for example dip coating, spin coating, knife coating or spraying. Sol-gel coatings are known, for example, from the field of production of interference filters for optical applications and/or for antireflection coating and/or for generation of color effects in the lighting industry. In general, the at least one longpass filter may thus especially have at least one interference filter. Longpass filters produced by sol-gel coating are commercially available. As described above, it is possible by means of the sol-gel process, for example, to directly coat the substrate of the photovoltaic element on the side facing the layer structure and/or on the side remote from the layer structure. Alternatively or additionally, the longpass filter, however, may also be configured as a separate element.

Alternatively or additionally to the use of inorganic filter materials, the longpass filter may also comprise at least one organic filter dye. For this purpose, it is possible to use, for example, filter dyes known from the prior art. Suitable examples are in principle all photochemically stable UV absorbers, which preferably additionally have absorptions in the blue spectral range in order to be able to be used in accordance with the invention. It is alternatively or additionally also possible to use rylene dyes, especially naphthalenedicarboxylic monoimides or else naphthalenetetracarboxylic diimides, as longpass filters, and/or parts thereof. According to this embodiment, preference is given to using naphthalenedicarboxylic monoimides or naphthalenetetracarboxylic diimides selected from the following structures:

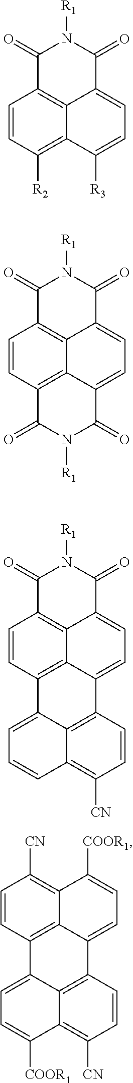

where R₁ is preferably selected from the group consisting of alkyl, aryl and heteroaryl, and where R₂ and R₃ are preferably each independently selected from the group consisting of H, alkyl, cyano (—CN) and alkoxy.

The term “alkoxy” is understood to mean a functional group based on an alkyl group bonded to an oxygen atom. Examples include methoxy and ethoxy.

R₁ is more preferably an akyl radical or aryl radical, especially an alkyl radical or an optionally substituted phenyl radical.

The longpass filter may, as described above, be producible especially by a wet-chemical process. More particularly, the longpass filter may be producible by applying a solution comprising at least one filter material and at least one solvent to a substrate, and the solvent is then removed. The term “solution” here, apart from a solution in the actual sense, should be interpreted such that it can in principle also comprise a dispersion and/or emulsion. The at least one filter material may be organic and/or inorganic in nature. The at least one substrate may be completely or partially identical to the substrate of the photovoltaic element to which the abovementioned layer structure is also applied, but may in principle also be configured as a separate substrate. The solvent can be removed from the substrate, for example, by drying and/or spinning off, optionally also supported by heating.

The n-conductive metal oxide may especially comprise titanium dioxide (TiO₂). Such materials have been found to be particularly suitable in solid dye solar cells.

The dye may especially have an absorption with a decadic absorbance of at least 0.1, especially of at least 0.3 and more preferably of at least 0.5 or even at least 1.0 at a wavelength in a spectral region above λ_{HTL}. More particularly, the absorbances mentioned may be at one or more wavelengths within a spectral range from 480 to 700 nm and more preferably within a spectral range from 550 to 750 nm. The absorbances can be defined and determined in an analogous manner to the above-described absorbance of the organic hold conductor material.

The photovoltaic element may also have at least one encapsulation. This encapsulation may be designed to keep air humidity and/or oxygen away from the organic hole conductor material and preferably the dye. The encapsulation may be applied, for example, as a solid capsule and/or may comprise one or more encapsulation layers.

In a further aspect of the present invention, a process is proposed for producing a photovoltaic element for conversion of electromagnetic radiation to electrical energy. The photovoltaic element may especially be a photovoltaic element according to one or more of the configurations described in detail above or still to be described below. Accordingly, for preferred configurations, reference may be made to the description above or below. In the process, at least one first electrode, at least one n-semiconductive metal oxide, at least one dye for absorption of at least a portion of the electromagnetic radiation, at least one organic hole conductor material and at least one second electrode are provided, more particularly by application to a substrate and preferably in the sequence mentioned. For example, this application may produce a layer structure. The organic hole conductor material is selected such that, in the photovoltaic element, it has an absorption spectrum for the electromagnetic radiation which has an absorption maximum in an ultraviolet or blue spectral region and then, toward higher wavelengths, has an absorption edge declining with the wavelength of the electromagnetic radiation and having a characteristic wavelength λ_{HTL}. A decadic absorbance of the hole conductor material at the wavelength λ_{HTL} within the declining absorption edge is 0.3. In addition, at least one longpass filter is provided, especially likewise by application to the substrate, said longpass filter having a transmission edge rising with the wavelength of the electromagnetic radiation and having a characteristic wavelength λ_{LP}. At λ_{LP}, a transmission of the longpass filter is 50% of the maximum transmission. λ_{LP} and λ_{HTL} are selected such that the following relationship applies: λ_{HTL}−30 nm≦λ_{LP}≦λ_{HTL}+30 nm.

In a further aspect of the present invention, a process is proposed for selection of a longpass filter for use in a photovoltaic element for conversion of electromagnetic radiation to electrical energy. More particularly, this may be a photovoltaic element according to one of the configurations described above or still to be described below, and so reference may be made to the description above or below with regard to preferred embodiments. The photovoltaic element has at least one first electrode, at least one n-semiconductive metal oxide, at least one dye for absorption of at least a portion of the electromagnetic radiation, at least one organic hole conductor material and at least one second electrode. The process comprises the following steps:
determining an absorption spectrum of the organic hole conductor material in the photovoltaic element,
evaluating the absorption spectrum and determining a characteristic wavelength λ_{HTL}, the characteristic wavelength being within a declining absorption edge in which an absorption of the organic hole conductor material in the photovoltaic element declines proceeding from an absorption maximum in an ultraviolet or blue spectral range, a decadic absorbance of the hole conductor material at the characteristic wavelength λ_{HTL} being 0.3,
selecting the longpass filter such that the longpass filter has a transmission edge rising with the wavelength of the electromagnetic radiation and having a characteristic wavelength λ_{LP}, a transmission of the longpass filter at λ_{LP} being 50% of a maximum transmission of the longpass filter, where λ_{HTL}−30 nm≦λ_{LP}≦λ_{HTL}+30 nm.

Preferred configurations of individual elements of the photovoltaic element, especially of the dye solar cell, are described by way of example hereinafter, and these configurations can be used in any desired combination. However, numerous other configurations are also possible in principle, and reference may be made, for example, to the abovementioned US 2007/0176165 A1, U.S. Pat. No. 6,995,445 B2, DE 2501124 A1, DE 3225372 A1 and WO 2009/013282 A1.

First Electrode and n-Semiconductive Metal Oxide

The n-semiconductive metal oxide used in the photovoltaic element may be a single metal oxide or a mixture of different oxides. It is also possible to use mixed oxides. The n-semiconductive metal oxide may especially be porous and/or be used in the form of a nanoparticulate oxide, nanoparticles in this context being understood to mean particles which have an average particle size of less than 0.1 micrometer. A nanoparticulate oxide is typically applied to a conductive substrate (i.e. a carrier with a conductive layer as the first electrode) by a sintering process as a thin porous film with large surface area.

The substrate may be rigid or else flexible. Suitable substrates (also referred to hereinafter as carriers) are, as well as metal foils, in particular plastic sheets or films and especially glass sheets or glass films. Particularly suitable electrode materials, especially for the first electrode according to the above-described, preferred structure, are conductive materials, for example transparent conductive oxides (TCOs), for example fluorine- and/or indium-doped tin oxide (FTO or ITO) and/or aluminum-doped zinc oxide (AZO), carbon nanotubes or metal films. Alternatively or additionally, it would, however, also be possible to use thin metal films which still have a sufficient transparency. The substrate can be covered or coated with these conductive materials. Since generally only a single substrate is required in the structure proposed, the formation of flexible cells is also possible. This enables a multitude of end uses which would be achievable only with difficulty, if at all, with rigid substrates, for example use in bank cards, garments, etc.

The first electrode, especially the TCO layer, may additionally be covered or coated with a solid metal oxide buffer layer (for example of thickness 10 to 200 nm), in order to prevent direct contact of the p-semiconductor with the TCO layer (see Peng et al, Coord. Chem. Rev. 248, 1479 (2004)). The inventive use of solid p-semiconductive electrolytes, in the case of which contact of the electrolyte with the first electrode is greatly reduced compared to liquid or gel-form electrolytes, however, makes this buffer layer unnecessary in many cases, such that it is possible in many cases to dispense with this layer, which also has a current-limiting effect and can also worsen the contact of the n-semiconductive metal oxide with the first electrode. This enhances the efficiency of the components. On the other hand, such a buffer layer can in turn be utilized in a controlled manner in order to match the current component of the dye solar cell to the current component of the organic solar cell. In addition, in the case of cells in which the buffer layer has been dispensed with, especially in solid cells, problems frequently occur with unwanted recombinations of charge carriers. In this respect, buffer layers are advantageous in many cases specifically in solid cells.

As is well known, thin layers or films of metal oxides are generally inexpensive solid semiconductor materials (n-semiconductors), but the absorption thereof, due to large bandgaps, is typically not within the visible region of the electromagnetic spectrum, but rather usually in the ultraviolet spectral region. For use in solar cells, the metal oxides therefore generally, as is the case in the dye solar cells, have to be combined with a dye as a photosensitizer, which absorbs in the wavelength range of sunlight, i.e. at 300 to 2000 nm, and, in the electronically excited state, injects electrons into the conduction band of the semiconductor. With the aid of a solid p-semiconductor used additionally in the cell as an electrolyte, which is in turn reduced at the counterelectrode, electrons can be recycled to the sensitizer, such that it is regenerated.

Of particular interest for use in organic solar cells are the semiconductors zinc oxide, tin dioxide, titanium dioxide or mixtures of these metal oxides. The metal oxides can be used in the form of nanocrystalline porous layers. These layers have a large surface area which is coated with the dye as a sensitizer, such that a high absorption of sunlight is achieved. Metal oxide layers which are structured, for example nanorods, give advantages such as higher electron mobilities or improved pore filling by the dye.

The metal oxide semiconductors can be used alone or in the form of mixtures. It is also possible to coat a metal oxide with one or more other metal oxides. In addition, the metal oxides may also be applied as a coating to another semiconductor, for example GaP, ZnP or ZnS.

Particularly preferred semiconductors are zinc oxide and titanium dioxide in the anatase polymorph, which is preferably used in nanocrystalline form.

In addition, the sensitizers can advantageously be combined with all n-semiconductors which typically find use in these solar cells. Preferred examples include metal oxides used in ceramics, such as titanium dioxide, zinc oxide, tin(IV) oxide, tungsten(VI) oxide, tantalum(V) oxide, niobium(V) oxide, cesium oxide, strontium titanate, zinc stannate, complex oxides of the perovskite type, for example barium titanate, and binary and ternary iron oxides, which may also be present in nanocrystalline or amorphous form.

Due to the strong absorption that customary organic dyes and phthalocyanines and porphyrins have, even thin layers or films of the n-semiconductive metal oxide are sufficient to absorb the required amount of dye. Thin metal oxide films in turn have the advantage that the probability of unwanted recombination processes falls and that the inner resistance of the dye subcell is reduced. For the n-semiconductive metal oxide, it is possible with preference to use layer thicknesses of 100 nm up to 20 micrometers, more preferably in the range between 500 nm and approx. 3 micrometers.

Dye

In the context of the present invention, as usual for DSCs in particular, the terms “dye”, “sensitizer dye” and “sensitizer” are used essentially synonymously without any restriction of possible configurations. Numerous dyes which are usable in the context of the present invention are known from the prior art, and so, for possible material examples, reference may also be made to the above description of the prior art regarding dye solar cells. All dyes listed and claimed may in principle also be present as pigments. Dye-sensitized solar cells based on titanium dioxide as a semiconductor material are described, for example, in U.S. Pat. No. 4,927,721, Nature 353, p. 737-740 (1991) and U.S. Pat. No. 5,350,644, and also Nature 395, p. 583-585 (1998) and EP-A-1 176 646. The dyes described in these documents can in principle also be used advantageously in the context of the present invention. These dye solar cells preferably comprise monomolecular films of transition metal complexes, especially ruthenium complexes, which are bonded to the titanium dioxide layer via acid groups as sensitizers.

Not least for reasons of cost, sensitizers which have been proposed repeatedly include metal-free organic dyes, which are likewise also usable in the context of the present invention. High efficiencies of more than 4%, especially in solid dye solar cells, can be achieved, for example, with indoline dyes (see, for example, Schmidt-Mende et al, Adv. Mater. 2005, 17, 813). U.S. Pat. No. 6,359,211 describes the use, also implementable in the context of the present invention, of cyanine, oxazine, thiazine and acridine dyes which have carboxyl groups bonded via an alkylene radical for fixing to the titanium dioxide semiconductor.

Organic dyes now achieve efficiencies of almost 12.1% in liquid cells (see, for example, Wang et al., ACS. Nano 2010). Pyridinium-containing dyes have also been reported, can be used in the context of the present invention and exhibit promising efficiencies.

Particularly preferred sensitizer dyes in the photovoltaic element are the perylene derivatives, terrylene derivatives and quaterrylene derivatives described in DE 10 2005 053 995 A1 or WO 2007/054470 A1. The use of these dyes, which is also possible in the context of the present invention, leads to photovoltaic elements with high efficiencies and simultaneously high stabilities.

The rylenes exhibit strong absorption in the wavelength range of sunlight and can, depending on the length of the conjugated system, cover a range from about 400 nm (perylene derivatives I from DE 10 2005 053 995 A1) up to about 900 nm (quaterrylene derivatives I from DE 10 2005 053 995 A1). Rylene derivatives I based on terrylene absorb, according to the composition thereof, in the solid state adsorbed onto titanium dioxide, within a range from about 400 to 800 nm. In order to achieve very substantial utilization of the incident sunlight from the visible into the near infrared region, it is advantageous to use mixtures of different rylene derivatives I. Occasionally, it may also be advisable also to use different rylene homologs.

The rylene derivatives I can be fixed easily and in a permanent manner to the n-semiconductive metal oxide film. The bonding is effected via the anhydride function (x1) or the carboxyl groups —COOH or —COO— formed in situ, or via the acid groups A present in the imide or condensate radicals ((x2) or (x3)). The rylene derivatives I described in DE 10 2005 053 995 A1 have good suitability for use in dye-sensitized solar cells in the context of the present invention.

It is particularly preferred when the dyes, at one end of the molecule, have an anchor group which enables the fixing thereof to the n-semiconductor film. At the other end of the molecule, the dyes preferably comprise electron donors Y which facilitate the regeneration of the dye after the electron has been released to the n-semiconductor, and also prevent recombination with electrons already released to the semiconductor.

For further details regarding the possible selection of a suitable dye, it is possible, for example, again to refer to DE 10 2005 053 995 A1. For example, it is possible especially to use ruthenium complexes, porphyrins, other organic sensitizers, and preferably rylenes.

The dyes can be fixed onto or into the n-semiconductive metal oxide films in a simple manner. For example, the n-semiconductive metal oxide films can be contacted in the freshly sintered (still warm) state over a sufficient period (for example about 0.5 to 24 h) with a solution or suspension of the dye in a suitable organic solvent. This can be accomplished, for example, by immersing the metal oxide-coated substrate into the solution of the dye.

If combinations of different dyes are to be used, they may, for example, be applied successively from one or more solutions or suspensions which comprise one or more of the dyes. It is also possible to use two dyes which are separated by a layer of, for example, CuSCN (on this subject see, for example, Tennakone, K. J., Phys. Chem. B. 2003, 107, 13758). The most convenient method can be determined comparatively easily in the individual case.

In the selection of the dye and of the size of the oxide particles of the n-semiconductive metal oxide, the organic solar cell should be configured such that a maximum amount of light is absorbed. The oxide layers should be structured such that the solid p-semiconductor can efficiently fill the pores. For instance, smaller particles have greater surface areas and are therefore capable of adsorbing a greater amount of dyes. On the other hand, larger particles generally have larger pores which enable better penetration through the p-conductor.

Organic Hole Conductor Material

As described above, the photovoltaic element has at least one organic hole conductor material. More particularly, this may be a solid organic hole conductor material. As usual in the context of organic electronics and photovoltaics, the terms “hole conductor material”, “p-semiconductive material”, “p-conductor” and “p-semiconductor” are used synonymously, since the transitions between insulators, semiconductors and conductors in this field of industry are generally fluid, and since a distinction between intrinsically conductive materials and materials which become conductive only after doping or an injection of external charge carriers is possible only with difficulty in practice.

A series of preferred examples of such organic p-semiconductors are described hereinafter, and these can be used individually or else in any combination, for example in a combination of a plurality of layers with a p-semiconductor in each case, and/or in a combination of several p-semiconductors in one layer.

In order to prevent recombination of the electrons in the n-semiconductive metal oxide with the solid p-conductor, it is possible to use, between the n-semiconductive metal oxide and the p-semiconductor, at least one passivating layer which has a passivating material. This layer should be very thin and should as far as possible cover only the as yet uncovered sites of the n-semiconductive metal oxide. The passivation material may, under some circumstances, also be applied to the metal oxide before the dye. Preferred passivation materials are especially one or more of the following substances: Al₂O₃; silanes, for example CH₃SiCl₃; Al³⁺; 4-tert-butylpyridine (TBP); MgO; GBA (4-guanidinobutyric acid) and similar derivatives; alkyl acids; hexadecylmalonic acid (HDMA).

As described above, in the context of the organic solar cell, preference is given to using one or more solid organic p-semiconductors—alone or else in combination with one or more further p-semiconductors which are organic or inorganic in nature. In the context of the present invention, an organic hole conductor material or p-semiconductor is generally understood to mean a material, especially an organic material, which is capable of conducting holes, i.e. positive charge carriers. More particularly, it may be an organic material with an extensive π-electron system which can be oxidized stably at least once, for example to form what is called a free-radical cation. For example, the p-semiconductor may comprise at least one organic matrix material which has the properties mentioned. In addition, the p-semiconductor may optionally have one or more dopants which enhance the p-semiconductive properties. A significant parameter influencing the selection of the p-semiconductor is the hole mobility, since this partly determines the hole diffusion length (cf. Kumara, G., Langmuir, 2002, 18, 10493-10495). A comparison of charge carrier mobilities in different Spiro compounds can be found, for example, in T. Saragi, Adv. Funct. Mater. 2006, 16, 966-974.

Preferably, in the context of the present invention, organic semiconductors are used (i.e. low molecular weight, oligomeric or polymeric semiconductors or mixtures of such semiconductors). Particular preference is given to p-semiconductors which can be processed from a liquid phase. Examples here are p-semiconductors based on polymers such as polythiophene and polyarylamines, or on amorphous, reversibly oxidizable, nonpolymeric organic compounds, such as the spirobifluorenes mentioned at the outset (cf., for example, US 2006/0049397 and the Spiro compounds disclosed therein as p-semiconductors, which are also usable in the context of the present invention). Preference is given to using low molecular weight organic semiconductors. In addition, reference may also be made to the remarks regarding the p-semiconductive materials and dopants from the above description of the prior art.

The p-semiconductor is preferably producible or produced by applying at least one p-conductive organic material to at least one carrier element, the application being effected, for example, by deposition from a liquid phase which comprises the at least one p-conductive organic material. The deposition can in turn in principle be effected by any deposition process, for example by spin coating, knife coating, printing or combinations of these and/or other deposition processes.

The organic p-semiconductor may especially comprise at least one spiro compound and/or especially be selected from: a spiro compound, especially spiro-MeOTAD; a compound with the structural formula:

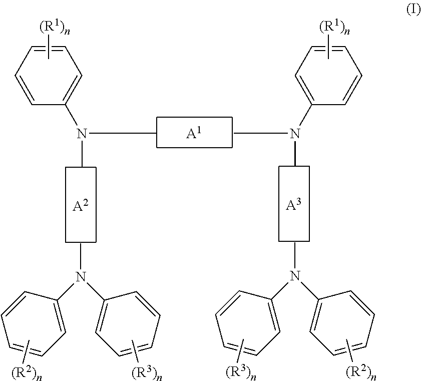

where
A¹, A² A³ are each independently optionally substituted aryl groups or heteroaryl groups,
R¹, R², R³ are each independently selected from the group consisting of the substituents —R, —OR, —NR₂, -A⁴-OR and -A⁴-NR₂,
where R is selected from the group consisting of alkyl, aryl and heteroaryl,
and
where A⁴ is an aryl group or heteroaryl group, and
where n at each instance in formula I is independently a value of 0, 1, 2 or 3,
with the proviso that the sum of the individual values n is at least 2 and at least two of the R¹, R² and R³ radicals are —OR and/or —NR₂.

Preferably, A² and A³ are the same; accordingly, the compound of the formula (I) preferably has the following structure (Ia)

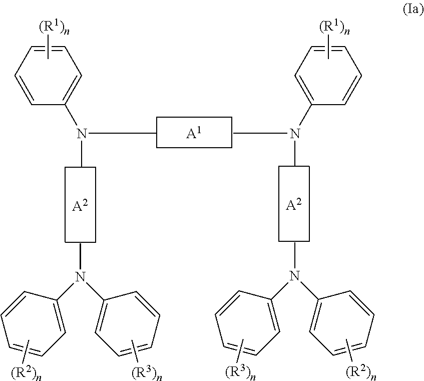

The p-semiconductor may thus especially, as stated above, have at least one low molecular weight organic p-semiconductor. A low molecular weight material is generally understood to mean a material which is present in monomeric, unpolymerized or unoligomerized form. The term “low molecular weight” as used in the present context preferably means that the p-semiconductor has molecular weights in the range from 100 to 25 000 g/mol. The low molecular weight substances preferably have molecular weights of 500-2000 g/mol.

In general, in the context of the present invention, p-semiconductive properties are understood to mean the property of materials, especially of organic molecules, to form holes and to transport these holes and/or to pass them on to adjacent molecules. More particularly, stable oxidation of these molecules should be possible. In addition, the low molecular weight organic p-semiconductors mentioned may especially have an extensive π-electron system. More particularly, the at least one low molecular weight p-semiconductor may be processible from a solution. The low molecular weight p-semiconductor may especially comprise at least one triphenylamine. It is particularly preferred when the low molecular weight organic p-semiconductor comprises at least one spiro compound. A spiro compound is understood to mean polycyclic organic compounds whose rings are joined only at one atom, which is also referred to as the spiro atom. More particularly, the spiro atom may be sp³-hybridized, such that the constituents of the spiro compound connected to one another via the spiro atom are, for example, arranged in different planes with respect to one another.

More preferably, the spiro compound has a structure of the following formula:

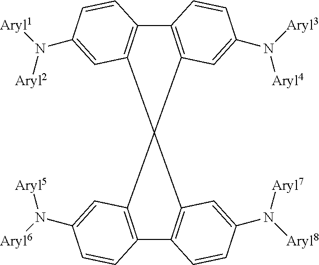

where the Aryl¹, Aryl², Aryl³, Aryl⁴, Aryl⁵, Aryl⁶, Aryl⁷ and Aryl⁸ radicals are each independently selected from substituted aryl radicals and heteroaryl radicals, especially from substituted phenyl radicals, where the aryl radicals and heteroaryl radicals, preferably the phenyl radicals, are each independently substituted, preferably in each case by one or more substituents selected from the group consisting of —O-alkyl, —OH, —F, —Cl, —Br and —I, where alkyl is preferably methyl, ethyl, propyl or isopropyl. More preferably, the phenyl radicals are each independently substituted, in each case by one or more substituents selected from the group consisting of —O-Me, —OH, —F, —Cl, —Br and —I.

Further preferably, the spiro compound is a compound of the following formula:

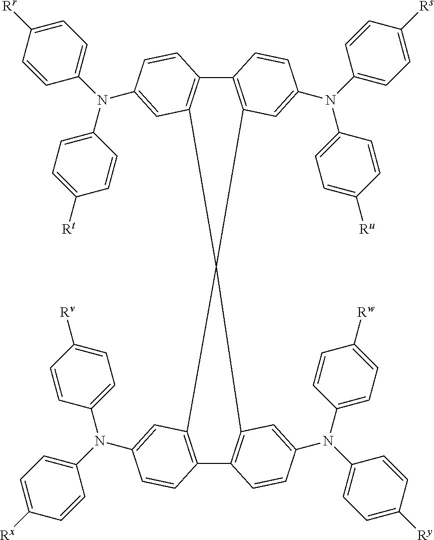

where R^{r}, R^{s}, R^{t}, R^{u}, R^{w}, R^{x} and R^{y} are each independently selected from the group consisting of —O-alkyl, —OH, —F, —Cl, —Br and —I, where alkyl is preferably methyl, ethyl, propyl or isopropyl. More preferably, R^{r}, R^{s}, R^{t}, R^{u}, R^{v}, R^{w}, R^{x} and R^{y} are each independently selected from the group consisting of —O-Me, —OH, —F, —Cl, —Br and —I.

More particularly, the p-semiconductor may comprise spiro-MeOTAD or consist of spiro-MeOTAD, i.e. a compound commercially available, for example, from Merck KGaA, Darmstadt, Germany, and of the formula:

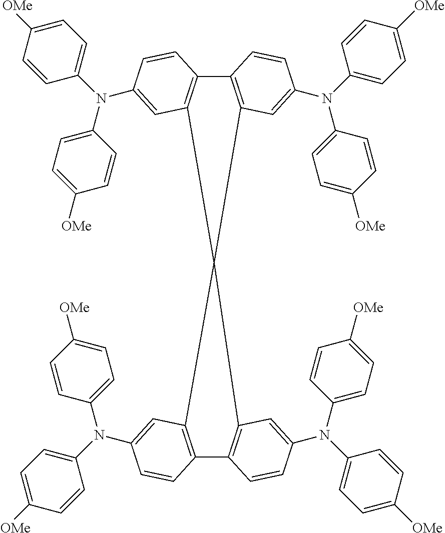

Alternatively or additionally, it is also possible to use other p-semiconductive compounds, especially low molecular weight and/or oligomeric and/or polymeric p-semiconductive compounds.

In an alternative embodiment, the low molecular weight organic p-semiconductor comprises one or more compounds of the abovementioned general formula I, for which reference may be made, for example, to PCT application number PCT/EP2010/051826, which will be published after the priority date of the present application. The p-semiconductor may comprise the at least one compound of the abovementioned general formula I additionally or alternatively to the spiro compound described above.

The term “alkyl” or “alkyl group” or “alkyl radical” as used in the context of the present invention is understood to mean substituted or unsubstituted C₁-C₂₀-alkyl radicals in general. Preference is given to C₁- to C₁₀-alkyl radicals, particular preference to C₁- to C₈-alkyl radicals. The alkyl radicals may be either straight-chain or branched. In addition, the alkyl radicals may be substituted by one or more substituents selected from the group consisting of C₁-C₂₀-alkoxy, halogen, preferably F, and C₆-C₃₀-aryl which may in turn be substituted or unsubstituted. Examples of suitable alkyl groups are methyl, ethyl, propyl, butyl, pentyl, hexyl, heptyl and octyl, and also isopropyl, isobutyl, isopentyl, sec-butyl, tert-butyl, neopentyl, 3,3-dimethylbutyl, 2-ethylhexyl, and also derivatives of the alkyl groups mentioned substituted by C₆-C₃₀-aryl, C₁-C₂₀-alkoxy and/or halogen, especially F, for example —CF₃.

The term “aryl” or “aryl group” or “aryl radical” as used in the context of the present invention is understood to mean optionally substituted C₆-C₃₀-aryl radicals which are derived from monocyclic, bicyclic, tricyclic or else multicyclic aromatic rings, where the aromatic rings do not comprise any ring heteroatoms. The aryl radical preferably comprises 5- and/or 6-membered aromatic rings. When the aryls are not monocyclic systems, in the case of the term “aryl” for the second ring, the saturated form (perhydro form) or the partly unsaturated form (for example the dihydro form or tetrahydro form), provided the particular forms are known and stable, is also possible. The term “aryl” in the context of the present invention thus comprises, for example, also bicyclic or tricyclic radicals in which either both or all three radicals are aromatic, and also bicyclic or tricyclic radicals in which only one ring is aromatic, and also tricyclic radicals in which two rings are aromatic. Examples of aryl are: phenyl, naphthyl, indanyl, 1,2-dihydronaphthenyl, 1,4-dihydronaphthenyl, fluorenyl, indenyl, anthracenyl, phenanthrenyl or 1,2,3,4-tetrahydronaphthyl. Particular preference is given to C₆-C₁₀-aryl radicals, for example phenyl or naphthyl, very particular preference to C₆-aryl radicals, for example phenyl. In addition, the term “aryl” also comprises ring systems comprising at least two monocyclic, bicyclic or multicyclic aromatic rings joined to one another via single or double bonds. One example is that of biphenyl groups.

The term “heteroaryl” or “heteroaryl group” or “heteroaryl radical” as used in the context of the present invention is understood to mean optionally substituted 5- or 6-membered aromatic rings and multicyclic rings, for example bicyclic and tricyclic compounds having at least one heteroatom in at least one ring. The heteroaryls in the context of the invention preferably comprise 5 to 30 ring atoms. They may be monocyclic, bicyclic or tricyclic, and some can be derived from the aforementioned aryl by replacing at least one carbon atom in the aryl base skeleton with a heteroatom. Preferred heteroatoms are N, O and S. The hetaryl radicals more preferably have 5 to 13 ring atoms. The base skeleton of the heteroaryl radicals is especially preferably selected from systems such as pyridine and five-membered heteroaromatics such as thiophene, pyrrole, imidazole or furan. These base skeletons may optionally be fused to one or two six-membered aromatic radicals. In addition, the term “heteroaryl” also comprises ring systems comprising at least two monocyclic, bicyclic or multicyclic aromatic rings joined to one another via single or double bonds, where at least one ring comprises a heteroatom. When the heteroaryls are not monocyclic systems, in the case of the term “heteroaryl” for at least one ring, the saturated form (perhydro form) or the partly unsaturated form (for example the dihydro form or tetrahydro form), provided the particular forms are known and stable, is also possible. The term “heteroaryl” in the context of the present invention thus comprises, for example, also bicyclic or tricyclic radicals in which either both or all three radicals are aromatic, and also bicyclic or tricyclic radicals in which only one ring is aromatic, and also tricyclic radicals in which two rings are aromatic, where at least one of the rings, i.e. one aromatic or one nonaromatic ring has a heteroatom. Suitable fused heteroaromatics are, for example, carbazolyl, benzimidazolyl, benzofuryl, dibenzofuryl or dibenzothiophenyl. The base skeleton may be substituted at one, more than one or all substitutable positions, suitable substituents being the same as have already been specified under the definition of C₆-C₃₀-aryl. However, the hetaryl radicals are preferably unsubstituted. Suitable hetaryl radicals are, for example, pyridin-2-yl, pyridin-3-yl, pyridin-4-yl, thiophen-2-yl, thiophen-3-yl, pyrrol-2-yl, pyrrol-3-yl, furan-2-yl, furan-3-yl and imidazol-2-yl and the corresponding benzofused radicals, especially carbazolyl, benzimidazolyl, benzofuryl, dibenzofuryl or dibenzothiophenyl.

In the context of the invention the term “optionally substituted” refers to radicals in which at least one hydrogen radical of an alkyl group, aryl group or heteroaryl group has been replaced by a substituent. With regard to the type of this substituent, preference is given to alkyl radicals, for example methyl, ethyl, propyl, butyl, pentyl, hexyl, heptyl and octyl, and also isopropyl, isobutyl, isopentyl, sec-butyl, tert-butyl, neopentyl, 3,3-dimethylbutyl and 2-ethylhexyl, aryl radicals, for example C₆-C₁₀-aryl radicals, especially phenyl or naphthyl, most preferably C₆-aryl radicals, for example phenyl, and hetaryl radicals, for example pyridin-2-yl, pyridin-3-yl, pyridin-4-yl, thiophen-2-yl, thiophen-3-yl, pyrrol-2-yl, pyrrol-3-yl, furan-2-yl, furan-3-yl and imidazol-2-yl, and also the corresponding benzofused radicals, especially carbazolyl, benzimidazolyl, benzofuryl, dibenzofuryl or dibenzothiophenyl. Further examples include the following substituents: alkenyl, alkynyl, halogen, hydroxyl.

The degree of substitution here may vary from monosubstitution up to the maximum number of possible substituents.

Preferred compounds of the formula I for use in accordance with the invention are notable in that at least two of the R¹, R² and R³ radicals are para-OR and/or —NR₂ substituents. The at least two radicals here may be only —OR radicals, only —NR₂ radicals, or at least one —OR and at least one —NR₂ radical.

Particularly preferred compounds of the formula I for use in accordance with the invention are notable in that at least four of the R¹, R² and R³ radicals are para-OR and/or —NR₂ substituents. The at least four radicals here may be only —OR radicals, only —NR₂ radicals or a mixture of —OR and —NR₂ radicals.

Very particularly preferred compounds of the formula I for use in accordance with the invention are notable in that all of the R¹, R² and R³ radicals are para-OR and/or —NR₂ substituents. They may be only —OR radicals, only —NR₂ radicals or a mixture of —OR and —NR₂ radicals.

In all cases, the two R in the —NR₂ radicals may be different from one another, but they are preferably the same.

Preferably, A¹, A² and A³ are each independently selected from the group consisting of

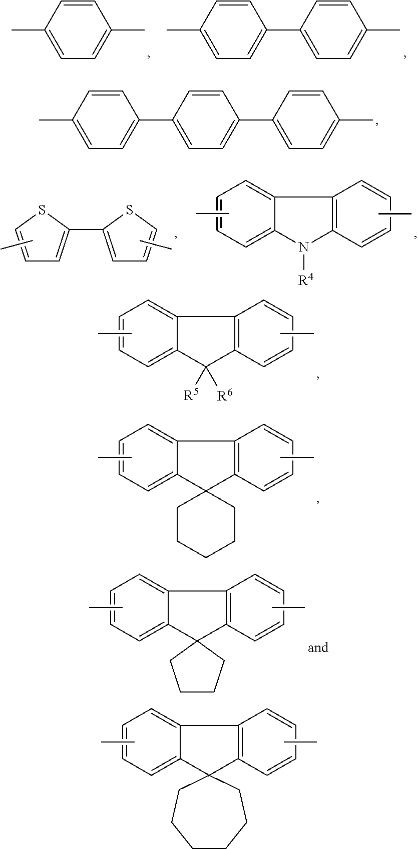

in which
m is an integer from 1 to 18,
R⁴ is alkyl, aryl or heteroaryl, where R⁴ is preferably an aryl radical, more preferably a phenyl radical,
R⁵, R⁶ are each independently H, alkyl, aryl or heteroaryl,

where the aromatic and heteroaromatic rings of the structures shown may optionally have further substitution. The degree of substitution of the aromatic and heteroaromatic rings here may vary from monosubstitution up to the maximum number of possible substituents.

Preferred substituents in the case of further substitution of the aromatic and heteroaromatic rings include the substituents already mentioned above for the one, two or three optionally substituted aromatic or heteroaromatic groups.

Preferably, the aromatic and heteroaromatic rings of the structures shown do not have further substitution.

More preferably, A¹, A² and A³ are each independently

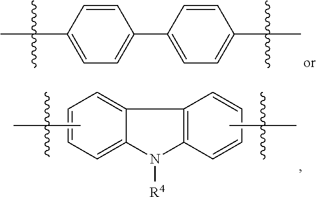

more preferably

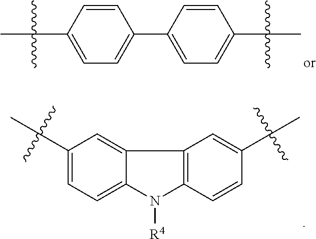

More preferably, the at least one compound of the formula (I) has one of the following structures:

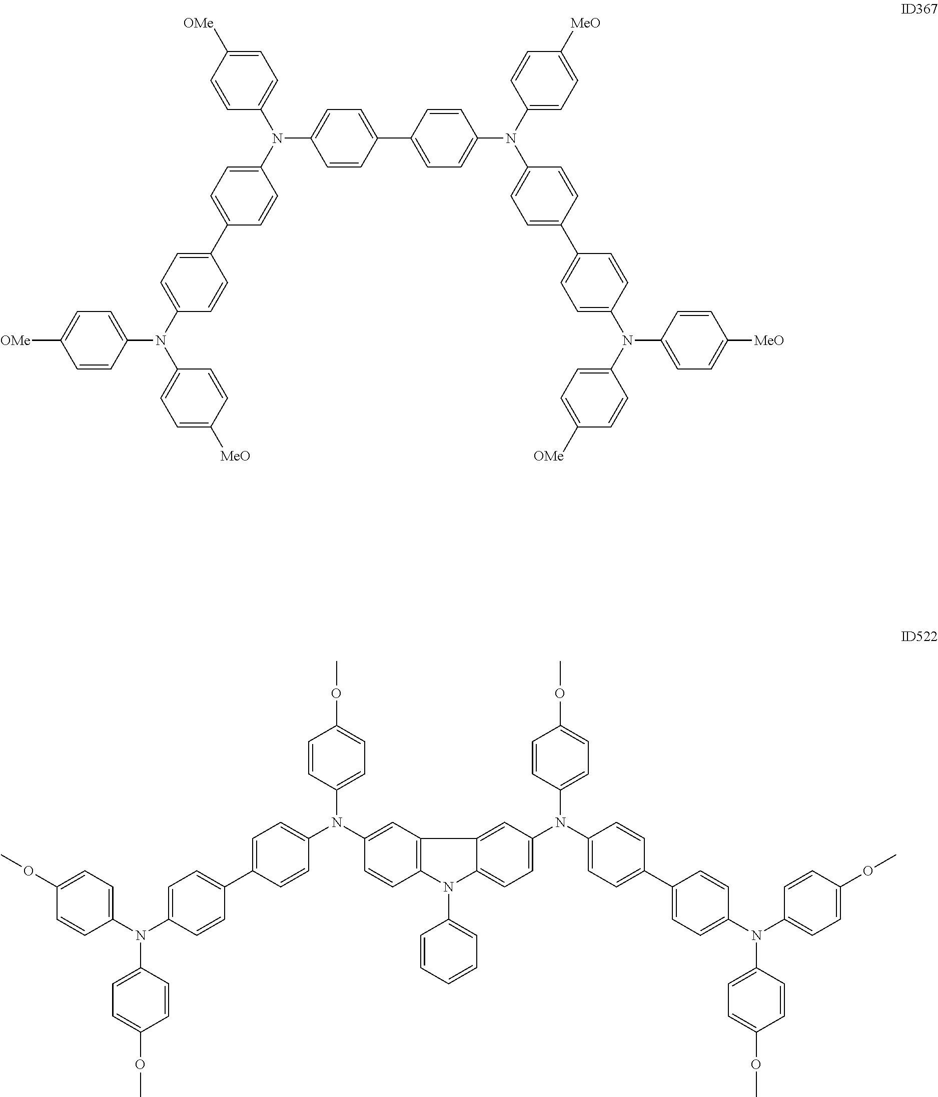

In an alternative embodiment, the organic p-semiconductor comprises a compound of the ID322 type with the following structure:

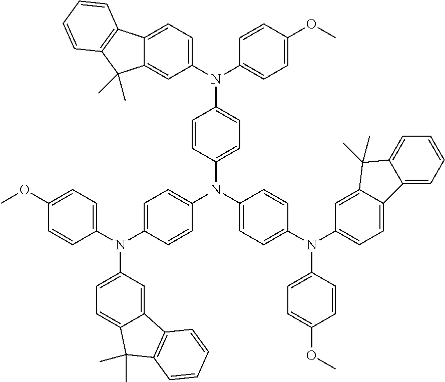

The compounds for use in accordance with the invention can be prepared by customary methods of organic synthesis known to those skilled in the art. References to relevant (patent) literature can additionally be found in the synthesis examples adduced below.

Second Electrode

The second electrode may especially be a bottom electrode facing the substrate or else a top electrode facing away from the substrate. The second electrodes which can be used are especially metal electrodes which may have one or more metals in pure form or as a mixture/alloy, such as especially aluminum or silver. The use of inorganic/organic mixed electrodes or multilayer electrodes is also possible, for example the use of LiF/Al electrodes.

In addition, it is also possible to use electrode designs in which the quantum efficiency of the components is increased by virtue of the photons being forced, by means of appropriate reflections, to pass through the absorbing layers at least twice. Such layered structures are also referred to as “concentrators” and are likewise described, for example, in WO 02/101838 (particularly p. 23-24).

The organic solar cell may further comprise at least one encapsulation, the encapsulation being designed to shield the organic solar cell, more particularly the electrodes and/or the p-semiconductor, from an ambient atmosphere.

Overall, in the context of the present invention, the following embodiments are considered to be particularly preferred:

Embodiment 1: A photovoltaic element for conversion of electromagnetic radiation to electrical energy, comprising at least one first electrode, at least one n-semiconductive metal oxide, further comprising at least one dye for absorption of at least a portion of the electromagnetic radiation, further comprising at least one organic hole conductor material and at least one second electrode, said organic hole conductor material in said photovoltaic element having an absorption spectrum for the electromagnetic radiation having an absorption maximum in an ultraviolet or blue spectral region and then, toward higher wavelengths, an absorption edge declining with the wavelength of the electromagnetic radiation and having a characteristic wavelength λ_{HTL}, a decadic absorbance of the hole conductor material at a wavelength λ_{HTL} within the declining absorption edge being 0.3, said photovoltaic element further having at least one longpass filter, said longpass filter having a transmission edge rising with the wavelength of the electromagnetic radiation and having a characteristic wavelength λ_{LP}, a transmission of the longpass filter at λ_{LP} being 50% of a maximum transmission of the longpass filter, where λ_{HTL}−30 nm≦λ_{LP}≦λ_{HTL}+30 nm.

Embodiment 2: The photovoltaic element according to the preceding embodiment, wherein λ_{HTL}≦440 nm, especially λ_{HTL}≦430 nm, preferably λ_{HTL}≦425 nm and more preferably λ_{HTL}=425 nm.

Embodiment 3: The photovoltaic element according to either of the preceding embodiments, wherein the absorption spectrum of the organic hole conductor material at a wavelength of λ_{HTL}+30 nm has declined to a decadic absorbance of less than 0.2, preferably to less than 0.1 and more preferably to less than 0.05, and for wavelengths of λ_{HTL}+30 nm to 800 nm has a decadic absorbance of less than 0.2, preferably of less than 0.1 and more preferably of less than 0.05.

Embodiment 4: The photovoltaic element according to any of the preceding embodiments, wherein the longpass filter has an edge steepness S_{LP} of the rising transmission edge, where S_{LP} is ≦1.2 eV, preferably S_{LP}≦1.0 eV and more preferably S_{LP}≦0.8 eV.

Embodiment 5: The photovoltaic element according to any of the preceding embodiments, wherein the photovoltaic element has a transparent substrate, the longpass filter having been applied to the transparent substrate.

Embodiment 6: The photovoltaic element according to the preceding embodiment, wherein the first electrode or the second electrode have been applied to a first side of the substrate, the longpass filter having been applied to a second side of the substrate opposing the first side.

Embodiment 7: The photovoltaic element according to any of the preceding embodiments, wherein the longpass filter in at least one transmission region takes up a transmission of at least 75%, especially of at least 80% and more preferably of at least 85%.

Embodiment 8: The photovoltaic element according to any of the preceding embodiments, wherein the longpass filter in at least one absorption region takes up a decadic absorbance of at least 3 and more preferably of at least 4.

Embodiment 9: The photovoltaic element according to any of the preceding embodiments, wherein the organic hole conductor material is a solid organic hole conductor material.

Embodiment 10: The photovoltaic element according to any of the preceding embodiments, wherein the organic hole conductor material is or comprises an arylamine compound and/or a spiro compound,

especially a spiro compound with a structure of the following formula:

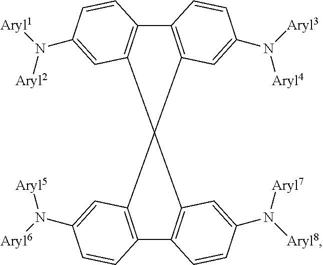

where the Aryl¹, Aryl², Aryl³, Aryl⁴, Aryl⁵, Aryl⁶, Aryl⁷ and Aryl⁸ radicals are each independently selected from substituted aryl radicals and heteroaryl radicals, especially from substituted phenyl radicals, where the aryl radicals and heteroaryl radicals, preferably the phenyl radicals, are preferably each independently substituted by one or more substituents selected from the group consisting of —O-alkyl, —OH, —F, —Cl, —Br and —I, where alkyl is preferably methyl, ethyl, propyl or isopropyl, where the phenyl radicals are more preferably each independently substituted by one or more substituents selected from the group consisting of —O-Me, —OH, —F, —Cl, —Br and —I,

preferably a spiro compound of the following formula:

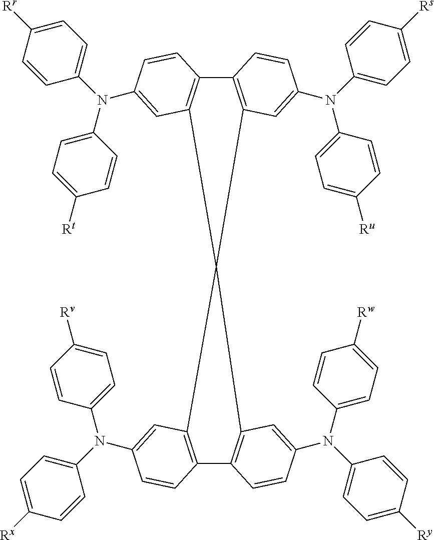

where R^{r}, R^{s}, R^{t}, R^{u}, R^{v}, R^{w}, R^{x} and R^{y} are each independently selected from the group consisting of —O-alkyl, —OH, —F, —Cl, —Br and —I, where alkyl is preferably methyl, ethyl, propyl or isopropyl, where R^{r}, R^{s}, R^{t}, R^{u}, R^{v}, R^{w}, R^{x} and R^{y} are preferably each independently selected from the group consisting of —O-Me, —OH, —F, —Cl, —Br and —I,

and more preferably spiro-MeOTAD:

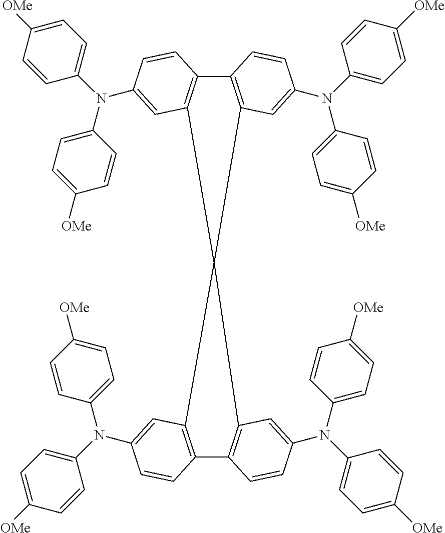

Embodiment 11: The photovoltaic element according to any of the preceding embodiments, wherein the organic hole conductor material is or comprises a compound with the following structural formula:

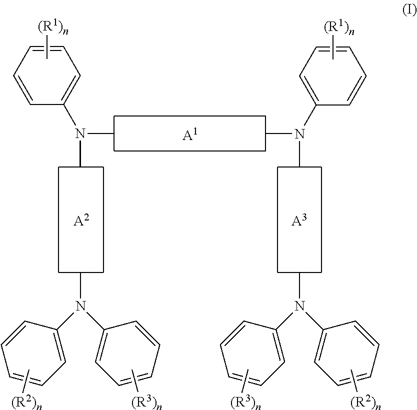

where

A¹, A², A³ are each independently optionally substituted aryl groups or heteroaryl groups,

R¹, R², R³ are each independently selected from the group consisting of the substituents —R, —OR, —NR₂, -A⁴-OR and -A⁴-NR₂,

where R is selected from the group consisting of alkyl, aryl and heteroaryl,

and

where A⁴ is an aryl group or heteroaryl group, and

where n at each instance in formula I is independently a value of 0, 1, 2 or 3,

with the proviso that the sum of the individual values n is at least 2 and at least two of the R¹, R² and R³ radicals are —OR and/or —NR₂.

Embodiment 12: The photovoltaic element according to any of the preceding embodiments, wherein the longpass filter comprises at least one inorganic filter material, especially a metal oxide and more preferably an inorganic filter material selected from the group consisting of SiO₂, TiO₂, ZrO₂ and Ta₂O₅.

Embodiment 13: The photovoltaic element according to any of the preceding embodiments, wherein the longpass filter is producible by means of a sol-gel process.

Embodiment 14: The photovoltaic element according to any of the preceding embodiments, wherein the longpass filter comprises at least one organic filter dye, especially at least one rylene dye.

Embodiment 15: The photovoltaic element according to any of the preceding embodiments, wherein the longpass filter is producible by applying a solution comprising at least one filter material and at least one solvent to a substrate, and then the solvent is removed.

Embodiment 16: The photovoltaic element according to any of the preceding embodiments, wherein the n-semiconductive metal oxide comprises TiO₂.

Embodiment 17: The photovoltaic element according to any of the preceding embodiments, wherein the dye has an absorption with a decadic absorbance of at least 0.1, especially of at least 0.3 and more preferably of at least 0.5 or even at least 1.0 at at least one wavelength in a spectral range above λ_{HTL}.

Embodiment 18: The photovoltaic element according to any of the preceding embodiments, wherein the photovoltaic element further comprises at least one encapsulation, said encapsulation being designed to keep air humidity and oxygen away from the organic hole conductor material and preferably the dye.

Embodiment 19: The photovoltaic element according to any of the preceding embodiments, wherein the longpass filter comprises at least one transparent organic matrix material and at least one absorber material introduced, especially mixed, into the matrix material.

Embodiment 20: The photovoltaic element according to the preceding embodiment, wherein the matrix material comprises at least one varnish.

Embodiment 21: The photovoltaic element according to the preceding embodiment, wherein the varnish is a polyacrylate-polyester varnish.

Embodiment 22: The photovoltaic element according to any of the two preceding embodiments, wherein the varnish is applied by applying a coating composition, and wherein the coating composition comprises at least one polyester resin (A), at least one polyacrylate resin (B) and preferably at least one crosslinking agent, said crosslinking agent being selected from the group consisting of polyisocyanates, amide- and amine-formaldehyde resins, phenol resins, aldehyde resins and ketone resins, said crosslinking agent preferably being a polyisocyanate.

Embodiment 23: The photovoltaic element according to any of the four preceding embodiments, wherein the absorber material comprises at least one organic absorber material.

Embodiment 24: The photovoltaic element (110) according to any of the five preceding embodiments, wherein the organic absorber material is selected from compounds comprising a benzotriazole group or a triazine group.

Embodiment 25: The photovoltaic element according to any of the preceding embodiments, wherein the longpass filter comprises at least two absorber materials introduced, especially mixed, into the matrix material, one absorber material being an absorber material comprising a triazine group, preferably an absorber material having the following structure

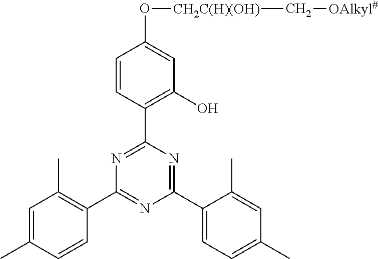

where alkyl^{#} is preferably a linear alkyl group, especially a linear alkyl group having 12 or 13 carbon atoms, and the other absorber material being preferably a compound of the following structure:

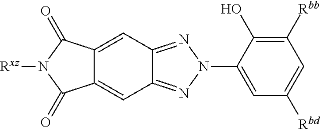

where R^{bb} and R^{bd} are each independently selected from the group consisting of H, -alkyl, —OH, -alkylaryl, -alkylheteryl, -cycloalkyl, cycloheteroalkyl, alkenyl, aryl and —SO₃H,

and where R^{xz} is selected from the group consisting of H, alkyl, aryl, heteroaryl, alkylaryl, alkylheteroryl, alkenyl and alkynyl.

Embodiment 26: A process for producing a photovoltaic element for conversion of electromagnetic radiation to electrical energy, especially a photovoltaic element according to any of the preceding embodiments, by providing at least one first electrode, at least one n-semiconductive metal oxide, at least one dye for absorption of at least a portion of the electromagnetic radiation, at least one organic hole conductor material and at least one second electrode, especially by application to a substrate, the organic hole conductor material being selected such that it, in the photovoltaic element, has an absorption spectrum for the electromagnetic radiation having an absorption maximum in an ultraviolet or blue spectral region and then, toward higher wavelengths, having an absorption edge declining with the wavelength of the electromagnetic radiation and having a characteristic wavelength λ_{HTL}, a decadic absorbance of the hole conductor material at the wavelength λ_{HTL} within the declining absorption edge being 0.3, and by further providing at least one longpass filter, especially likewise by application to the substrate, said longpass filter having a transmission edge rising with the wavelength of the electromagnetic radiation and having a characteristic wavelength λ_{LP}, a transmission of the longpass filter at λ_{LP} being 50% of a maximum transmission of the longpass filter, where λ_{HTL}−30 nm≦λ_{LP}≦λ_{HTL}+30 nm.

Embodiment 27: A process for selecting a longpass filter for use in a photovoltaic element for conversion of electromagnetic radiation to electrical energy, said photovoltaic element having at least one first electrode, at least one n-semiconductive metal oxide, at least one dye for absorption of at least a portion of the electromagnetic radiation, at least one organic hole conductor material and at least one second electrode, said process comprising the following steps:
determining an absorption spectrum of the organic hole conductor material in the photovoltaic element,
evaluating the absorption spectrum and determining a characteristic wavelength λ_{HTL}, the characteristic wavelength being within a declining absorption edge in which an absorption of the organic hole conductor material in the photovoltaic element declines proceeding from an absorption maximum in an ultraviolet or blue spectral range, a decadic absorbance of the hole conductor material at the characteristic wavelength λ_{HTL} being 0.3,
selecting the longpass filter such that the longpass filter has a transmission edge rising with the wavelength of the electromagnetic radiation and having a characteristic wavelength λ_{LP}, a transmission of the longpass filter at λ_{LP} being 50% of a maximum transmission of the longpass filter, where λ_{HTL}−30 nm≦λ_{LP}≦λ_{HTL}+30 nm.

### BRIEF DESCRIPTION OF THE FIGURES

Further optional details and features of the invention are evident from the description of preferred working examples which follows, in conjunction with the dependent claims. In this context, the particular features may each be implemented alone, or several may be implemented in combination with one another. The invention is not restricted to the working examples. The working examples are shown schematically in the figures. Identical reference numerals in the individual figures denote identical elements or elements with identical function, or elements which correspond to one another in terms of their functions.

The individual figures show:

FIG. 1 a layer structure of a preferred photovoltaic element;

FIG. 2 an energy level scheme of a preferred photovoltaic element;

FIG. 3 a schematic profile of an absorption edge of a typical hole conductor material;

FIG. 4 a schematic profile of a transmission curve of a typical longpass filter;

FIG. 5 an absorbance spectrum of the spiro-MeOTAD hole conductor material;

FIG. 6 an absorbance spectrum of the ID 504 dye;

FIG. 7 transmission spectra of several longpass filters used;

FIG. 8 lifetime curves of various photovoltaic elements;

FIG. 9 absorbance curves of substrates with various coatings; and

FIG. 10 lifetime curves of photovoltaic elements with various UV longpass filters.

### SAMPLE PRODUCTION

Various examples of photovoltaic elements with organic hole conductor materials and with various filters are described hereinafter.

### EXAMPLE 1

### Photovoltaic Element with Spiro-MeOTAD as Organic p-Semiconductor (Without Longpass Filter, Comparative Example)

As the base material and substrate, glass plates which had been coated with fluorine-doped tin oxide (FTO) as the first electrode (working electrode) and were of dimensions 25 mm×25 mm×3 mm (Hartford Glass) were used, which were treated successively in an ultrasound bath with glass cleaner (RBS 35), demineralized water and acetone, for 5 min in each case, then boiled in isopropanol for 10 minutes and dried in a nitrogen stream.

To produce an optional solid TiO₂ buffer layer, a spray pyrolysis process was used. Thereon, as an n-semiconductive metal oxide, a TiO₂ paste (Dyesol) which comprises TiO₂ particles with a diameter of 25 nm in a terpineol/ethylcellulose dispersion was spun on with a spin-coater at 4500 rpm and dried at 90° C. for 30 min. After heating to 450° C. for 45 min and a sintering step at 450° C. for 30 minutes, a TiO₂ layer thickness of approximately 1.8 μm was obtained.

After removal from the drying cabinet, the sample was cooled to 80° C. and immersed into an optional 5 mM solution of an additive ID662 (obtainable, for example, according to example H below) for 12 h and subsequently into a 0.5 mM solution of a dye in dichloromethane for 1 h. The dye used was the dye ID504 (obtainable, for example, according to example G below), although a multitude of other dyes are usable. More particularly, the dye can be matched to the particular end use and the wavelengths of electromagnetic radiation used.

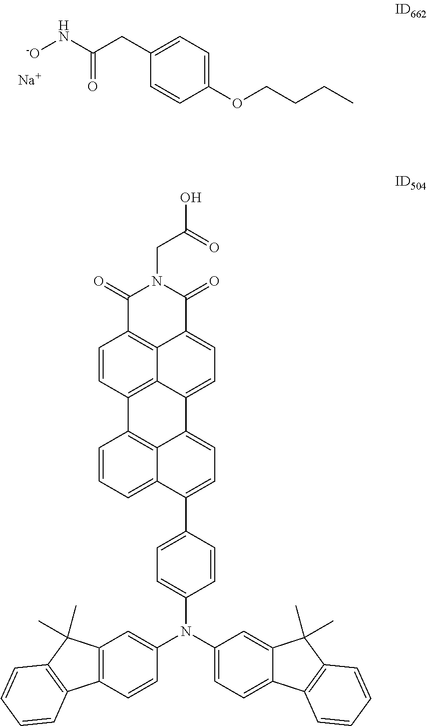

After removal from the solution, the sample was subsequently rinsed with the same solvent and dried in a nitrogen stream. The samples obtained in this way were subsequently dried at 40° C. under reduced pressure.

Next, a solution of an organic p-semiconductor was spun on. For this purpose, a solution of 0.163 M spiro-MeOTAD (Merck) and 20 mM LiN(SO₂CF₃)₂ (Aldrich) in chlorobenzene was made up. 125 μl of this solution were applied to the sample and allowed to act for 60 s. Thereafter, the supernatant solution was spun off at 2000 rpm for 30 s.

Finally, a metal back electrode was applied as a second electrode by thermal metal vaporization under reduced pressure. The metal used was Ag, which was vaporized at a rate of 3 Å/s at a pressure of approx. 2*10⁻⁶ mbar, so as to give a layer thickness of about 200 nm.

### EXAMPLES 2 TO 5

### Photovoltaic Elements with Spiro-MeOTAD as Organic p-Semiconductor and Various Longpass Filters

As inventive working examples (examples 2 to 5), four photovoltaic elements were first produced according to the above-described example 1. In addition, these photovoltaic elements, however, were each provided with a longpass filter on the non-FTO-coated side of the glass substrate.

The longpass filters used in this case were commercially available glass longpass filters of the LCGG-X-2X2 type from LASER COMPONENTS GmbH in 82140 Olching, Germany, X designating the characteristic edge wavelength λ_{LP}, namely:
Example 2: LCGG-385-2X2, λ_{LP}=385 nm
Example 3: LCGG-420-2X2, λ_{LP}=420 nm
Example 4: LCGG-435-2X2, λ_{LP}=435 nm
Example 5: LCGG-450-2X2, λ_{LP}=450 nm

These filter types are UV filters with their own glass substrate, which has been placed directly onto the glass substrate of the photovoltaic element. However, another structure which is possible in principle is one in which the longpass filter is integrated into the glass substrate, applied to the glass substrate as a coating or arranged at a distance from the glass substrate.

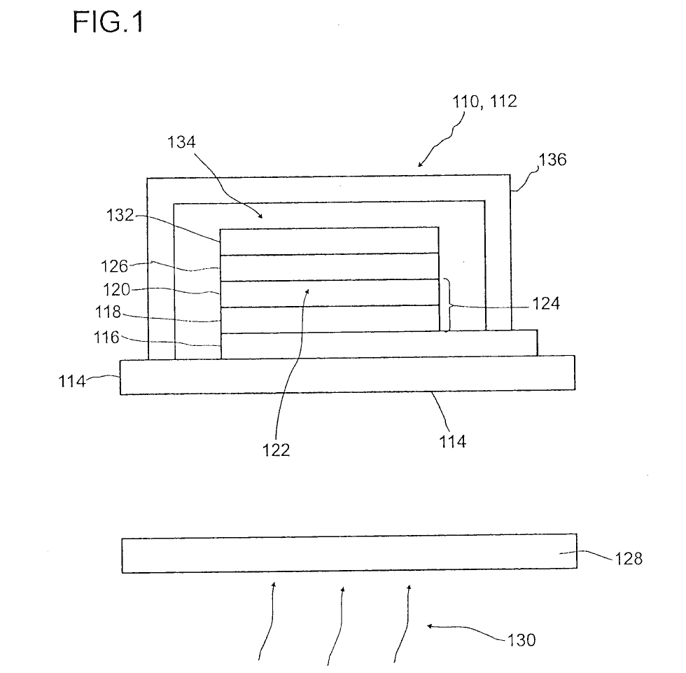

FIG. 1 shows, in a highly schematic section view, a photovoltaic element 110 in the form of a dye solar cell 112, which corresponds to the above-described inventive examples 2 to 5. The photovoltaic element 110 comprises a substrate 114, for example a glass substrate.

Other substrates are also usable, as described above. Applied to this substrate 114 has been a first electrode 116, which is also referred to as a working electrode and which is preferably transparent, as described above. Applied to this first electrode 116 in turn has been an optical blocking layer 118 of at least one metal oxide, which is preferably nonporous and/or nonparticulate. Applied to this in turn has been an n-semiconductive metal oxide 120 which has been sensitized with a dye 122.

The substrate 114 and the layers 116 to 120 applied thereto form, for example, a carrier element 124 for at least one layer of a solid organic p-semiconductor 126 applied thereto. Applied to this p-semiconductor 126 has been a second electrode 132, which is also referred to as the counterelectrode. The layers shown in FIG. 1 together form a layer structure 134 which may optionally be shielded from an ambient atmosphere by an encapsulation 136, for example in order to fully or partly protect the layer structure 134 from oxygen and/or moisture. One or both of the electrodes 116, 132 may, as indicated in FIG. 1 by the first electrode 116, be conducted out of the encapsulation 136 in order to be able to provide one or more contact areas outside the encapsulation 136.

In this respect, the layer structure 134 described corresponds, for example, to example 1 described above. In addition, the photovoltaic element 110 according to FIG. 1, however, as detailed above in the context of examples 2 to 5, on a side of the substrate 114 remote from the first electrode 116, has at least one longpass filter 128 through which electromagnetic radiation 130 has to pass before it can enter the layer structure 134 through the substrate 114.

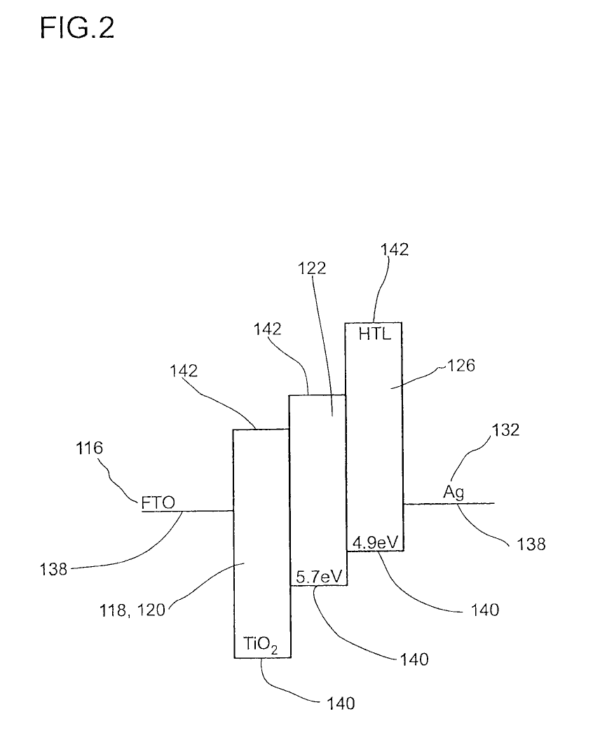

FIG. 2 shows, by way of example, in highly schematic form, an energy level diagram of the photovoltaic element 110, for example according to FIG. 1. This shows the Fermi levels 138 of the first electrode 116 and of the second electrode 132, and the HOMOs (Highest Occupied Molecular Orbitals) 140 and the LUMOs (Lowest Unoccupied Molecular Orbitals) of layers 118/120 (which may comprise the same material, for example TiO₂) of the dye 122 (shown by way of example with a HOMO level of 5.7 eV) and of the p-semiconductor 126 (also referred to as HTL, Hole Transport Layer). The materials specified by way of example for the first electrode 116 and the second electrode 132 are FTO (fluorine-doped tin oxide) and silver.

Measurement of the Spectral Properties and Lifetimes

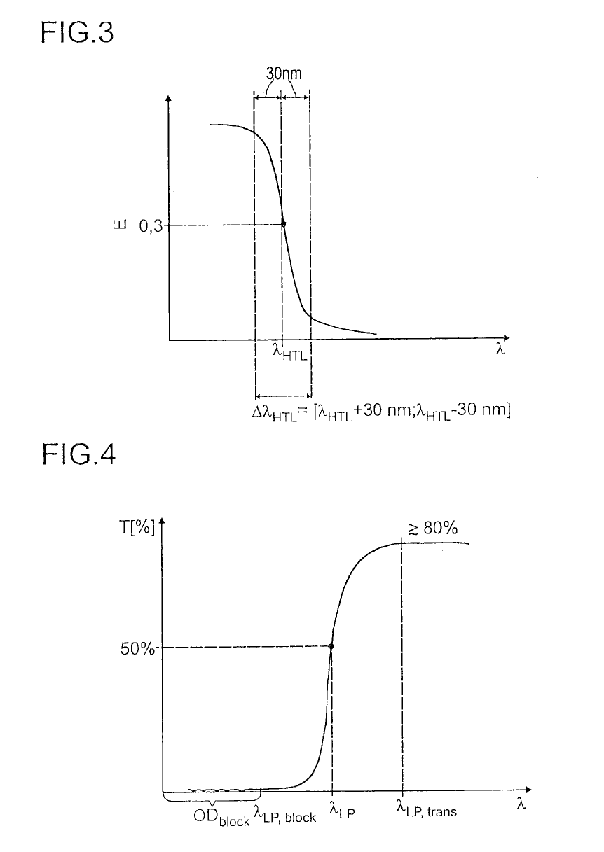

FIGS. 3 and 4 explain the above-described definitions of the characteristic wavelengths λ_{HTL} and λ_{LP}. For instance, FIG. 3 shows, in schematic form, an absorbance curve measured according to the description above for the hole conductor material, as a function of wavelength λ. FIG. 4 shows a transmission T of the longpass filter, likewise as a function of wavelength λ. As is evident from FIG. 3, the characteristic wavelength λ_{HTL} is that wavelength within a declining absorption edge at which the absorbance is exactly 0.3. The range Δλ_{HTL} refers to the range of λ_{HTL}±30 nm.

FIG. 4, in contrast, shows the edge of a typical longpass filter. With regard to the test method, reference may again be made to the above description. As is evident from this schematic diagram, the characteristic wavelength λ_{LP} of the longpass filter is that wavelength at which the transmission is 50% of a maximum transmission of the longpass filter. For example, in FIG. 4, a maximum transmission may be 80%, and so λ_{LP} is defined as that wavelength at which the transmission attains 0.5×80%=40%. Preference is given to longpass filters with a particularly steep absorption edge, in order that a maximum number of photons can be blocked on the short-wave side and transmitted to the long-wave side. The steepness of these longpass filters is calculated from the two wavelengths λ_{LP,block} and λ_{LP,trans}. λ_{LP,block} here is that wavelength at which, according to the specification, the optical density for the blocking effect (blocking OD) ends, more particularly goes below the value of 2 with rising wavelength. λ_{LP,trans} is that wavelength at which, according to the specification of the longpass filter, the transmission of the longpass filter begins and at which the transmission, for example, exceeds 95% of a maximum transmission of the longpass filter. If, for example, the minimum transmission is 0.5% and the maximum transmission 85%, λ_{LP,block} can be defined as that wavelength at which the transmission exceeds 2×0.5%=1.0%, and λ_{LP,trans} as that wavelength at which the transmission exceeds 0.95×85%=80.75%.

From these two wavelengths, the steepness S_{LP} is calculated by the formula specified above. Particular preference is given to inorganic longpass filters for which S_{LP} does not exceed the value of 1 eV. More preferably, S_{LP}≦0.8 eV. However, it is also generally possible to use specific organic UV and blue absorbers in organic binders within the mass concentration range from 0.1% to 15%. The steepness of these absorbers is calculated analogously. The steepness of these organic absorbers should preferably not be less than the value of 0.3 eV.

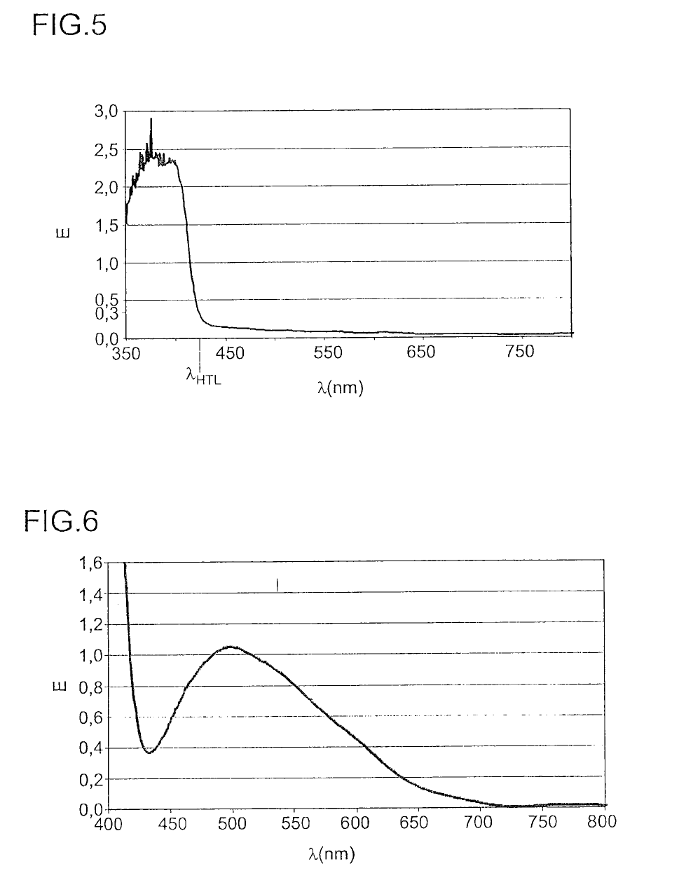

FIGS. 5 and 6 show absorbance spectra for the spiro-MeOTAD hole conductor material (FIG. 5) and for the ID 504 dye (FIG. 6). The plot in each case is of the absorbance as defined above, which is measured according to the above-described test method as a function of wavelength λ in nm. FIG. 5 shows that the characteristic wavelength λ_{HTL} of the spiro-MeOTAD hole conductor is approximately 420 nm.

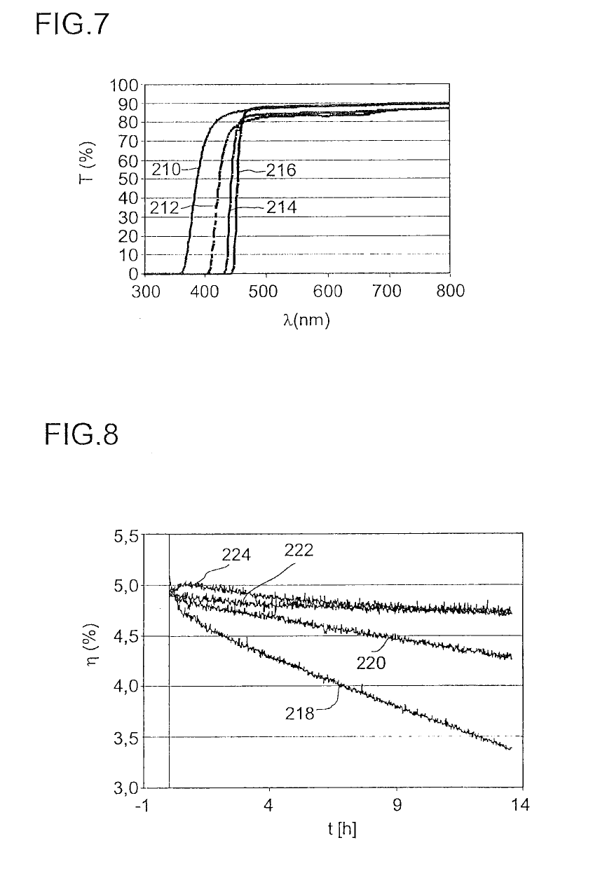

FIG. 7 shows transmission curves of the above-described longpass filters of working examples 2 to 5. In this figure, reference numeral 210 denotes the transmission spectrum of the longpass filter with the characteristic wavelength λ_{LP}=350 nm, reference numeral 212 denotes the transmission spectrum of the longpass filter with the characteristic wavelength λ_{LP}=420 nm, reference numeral 214 denotes the transmission spectrum of the longpass filter with the characteristic wavelength λ_{LP}=435 nm, and reference numeral 216 denotes the transmission spectrum of the longpass filter with characteristic wavelength λ_{LP}=450 nm.

It is clear from the curves according to FIG. 7 that the abovementioned examples 3, 4 and 5 are configured in accordance with the invention, since the wavelength λ_{LP} is within a range of λ_{HTL}±30 nm. Components according to example 2, in contrast, are not within the inventive range.

FIG. 8 shows various lifetimes of the components. The plot is of efficiency η, reported in %, as a function of irradiation hours at irradiation with one sun. Characteristic 218 denotes the lifetime measurement for components according to the abovementioned example 1, i.e. of a photovoltaic element without longpass filter. Characteristic 220 denotes a lifetime measurement of a photovoltaic element according to the abovementioned example 2, i.e. with a longpass filter with λ_{LP}=385 nm. Reference numeral 222 denotes a lifetime measurement for an inventive photovoltaic element according to the above-described example 3, i.e. with a longpass filter with a characteristic wavelength λ_{LP}=420 nm. Reference numeral 224 denotes a lifetime measurement for a photovoltaic element likewise configured in accordance with the invention according to the abovementioned example 5, i.e. for a photovoltaic element with a longpass filter with characteristic wavelength λ_{LP}=450 nm.

The lifetime measurements show clearly that the photovoltaic elements configured in accordance with the invention have a distinct increase in lifetime compared to photovoltaic elements not configured in accordance with the invention. At the same time, the starting efficiency of the inventive photovoltaic elements is comparable to conventional photovoltaic elements without longpass filters, since the lifetime curves 218-222 at t=0 h all have an efficiency of approx. 5%. This fact shows that the conditions specified, for the wavelength λ_{LP}, are still configured such that the longpass filters or edge filters transmit enough photons in the long-wave range to cover the absorbance spectrum of the dye according to FIG. 6. At the same time, however, it has been recognized in accordance with the invention that the characteristic wavelength λ_{LP} should be selected such that the absorbance spectrum of the hole conductor shown in FIG. 5 is well below the characteristic wavelength λ_{LP} in order to at least substantially avoid absorption leading to degradation by the hole conductor.

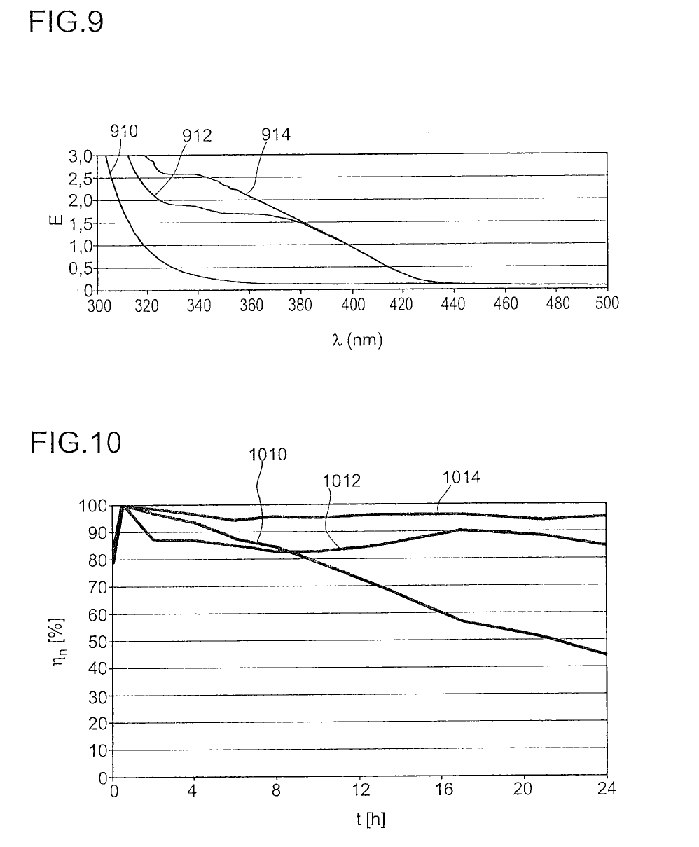

Hereinafter, FIGS. 9 and 10 are used to describe working examples in which the longpass filter 128 used was a varnish comprising one or two UV absorber materials.

### EXAMPLE 6

### Method for Production of the UV/VIS Protective Varnish Layers

In order to test the optical efficacy of varnishes as a longpass filter 128, UV protection layers were first produced in the form of varnish layers on glass substrates. To produce the protective layers, the commercially available HS (high solids) clearcoat, scratch-resistant VOC from Glasurit was used. It likewise comprises the diluent and hardener components. To produce varnish layers on the glass substrates, the varnish was applied by means of a spin coater at 1000 rpm to 25 mm×25 mm front-side cell cover glasses for 30 sec. Subsequently, the cells were heat-treated at 60° C. for 2 h.

### EXAMPLE 6.1

### UV Protection Varnish Comprising the UV Absorbers Carboprotect and Tinuvin 400 (Full UV)

In addition, samples were produced analogously to example 6, in which commercial UV absorbers were added to the varnish as the matrix material. Stirred into a mixture of: 2.5 g of clearcoat, 0.41 g of diluent and 1.25 g of hardener were in each case 78 mg or 39 mg of commercial UV absorber Carboprotect Xymara or Tinuvin 400.

300 microliters of this solution was applied with a spin coater at 1000 rpm to 25 mm×25 mm front-side cell cover glasses for 30 sec. Subsequently, the cells were heat-treated at 60° C. for 2 h.

### EXAMPLE 6.2

### UV Protection Varnish Comprising the UV Absorber Carboprotect Xymara

The procedure was as in 6.1, except that the UV absorber Tinuvin 400 was omitted.

FIG. 9 shows absorbance curves of the samples produced as above, which were recorded analogously to the curves in FIGS. 5 and 6. Curve 910 denotes an absorbance measurement on cell glass without protection varnish. Curve 912 denotes an absorbance measurement on a sample according to working example 6.2 above, i.e. a sample comprising a varnish matrix and Carboprotect Xymara. Curve 914 denotes an absorbance measurement on a sample according to working example 6.1 above, i.e. a sample comprising a varnish matrix and the UV absorber materials Carboprotect Xymara and Tinuvin 400.

FIG. 10 shows lifetime measurements on photovoltaic elements 110, with the above-described varnishes and UV absorber materials as the longpass filter 128. The basis used was a photovoltaic element 110 according to the above-described example 1. According to the above-described production thereof, as per examples 6.1 and 6.2 above, varnishes were applied as the longpass filter 128 to the side of the substrate 114 facing away from the organic layer structure in two of the photovoltaic elements 110, specifically a UV protection varnish comprising the UV absorbers Carboprotect and Tinuvin 400 (full UV) in one case (example 7.1, analogously to 6.1 above), and a UV protection varnish only comprising the UV absorber Carboprotect Xymara in another case (example 7.2, analogously to example 6.2 above).

These components were used to record lifetime measurements, analogously to the measurements above in FIG. 8. The results of these measurements are shown in FIG. 10. Plotted on the horizontal axis is the exposure time for exposure with 1 sun in hours. Plotted on the vertical axis is, analogously to FIG. 8, the efficiency η in percent, which has been normalized here arbitrarily to the maximum value of the curve as 100 percent. The curve 1010 denotes the course against time of the lifetime of a photovoltaic element 110 without longpass filter, i.e. entirely without protective varnish. Curve 1012 denotes the course against time of the efficiency in a photovoltaic element 110 according to working example 7.2 above, i.e. of a sample comprising a varnish matrix and Carboprotect Xymara. Curve 1014 denotes a lifetime measurement on a sample according to working example 7.1 above, i.e. a photovoltaic element 110 comprising a varnish matrix and the UV absorber materials Carboprotect Xymara and Tinuvin 400. It is clearly evident from these curves that the use of the UV protection varnish comprising one UV absorber component (curve 1012) or even comprising two absorber components (curve 1014) can distinctly enhance the lifetime of the photovoltaic elements 110.

### SYNTHESIS EXAMPLES

Specified hereinafter by way of example are syntheses of various compounds which can be used in photovoltaic elements in the context of the present invention, especially as organic hole conductor materials. For example, possible syntheses of compounds of the formula (I) are described:

### (A) GENERAL SYNTHESIS SCHEMES FOR PREPARATION OF COMPOUNDS OF THE FORMULA I

(a) Synthesis Route I:

(a1) Synthesis Step I-R1:

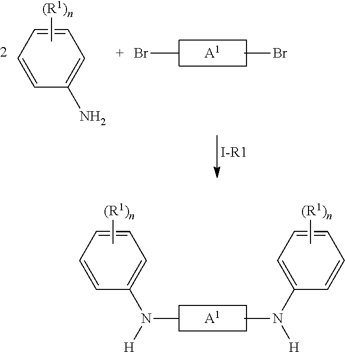

The synthesis in synthesis step I-R1 was based on the references cited below:

a) Liu, Yunqi; Ma, Hong; Jen, Alex K-Y.; CHCOFS; Chem. Commun.; 24; 1998; 2747-2748,

b) Goodson, Felix E.; Hauck, Sheila; Hartwig, John F.; J. Am. Chem. Soc.; 121; 33; 1999; 7527-7539,

c) Shen, Jiun Yi; Lee, Chung Ying; Huang, Tai-Hsiang; Lin, Jiann T.; Tao, Yu-Tai; Chien, Chin-Hsiung; Tsai, Chiitang; J. Mater. Chem.; 15; 25; 2005; 2455-2463,

d) Huang, Ping-Hsin; Shen, Jiun-Yi; Pu, Shin-Chien; Wen, Yuh-Sheng; Lin, Jiann T.; Chou, Pi-Tai; Yeh, Ming-Chang P.; J. Mater. Chem.; 16; 9; 2006; 850-857,

e) Hirata, Narukuni; Kroeze, Jessica E.; Park, Taiho; Jones, David; Haque, Saif A.; Holmes, Andrew B.; Durrant, James R.; Chem. Commun.; 5; 2006; 535-537.

(a2) Synthesis Step I-R2:

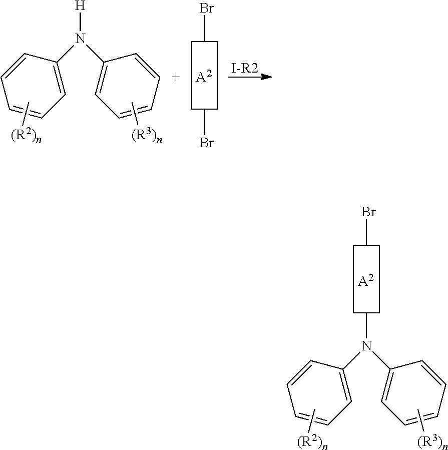

The synthesis in synthesis step I-R2 was based on the references cited below:

a) Huang, Qinglan; Evmenenko, Guennadi; Dutta, Pulak; Marks, Tobin J.; J. Am. Chem. Soc.; 125; 48; 2003; 14704-14705,

b) Bacher, Erwin; Bayerl, Michael; Rudati, Paula; Reckefuss, Nina; Mueller, C. David; Meerholz, Klaus; Nuyken, Oskar; Macromolecules; E N; 38; 5; 2005; 1640-1647,

c) Li, Zhong Hui; Wong, Man Shing; Tao, Ye; D'lorio, Marie; J. Org. Chem.; EN; 69; 3; 2004; 921-927.

(a3) Synthesis Step I-R3:

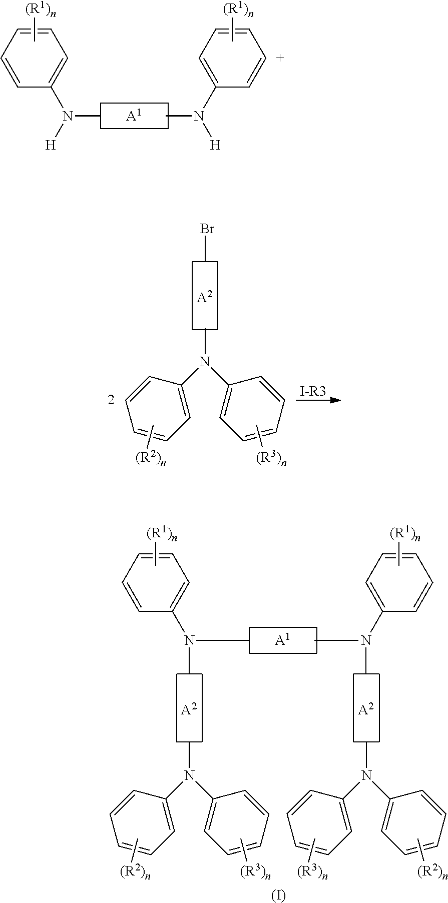

The synthesis in synthesis step I-R3 was based on the reference cited below:

J. Grazulevicius; J. of Photochem. and Photobio., A: Chemistry 2004 162(2-3), 249-252.

The compounds of the formula I can be prepared via the sequence of synthesis steps shown above in synthesis route I. In steps (I-R1) to (I-R3), the reactants can be coupled, for example, by Ullmann reaction with copper as a catalyst or under palladium catalysis.

(b) Synthesis Route II:

(b1) Synthesis Step II-R1:

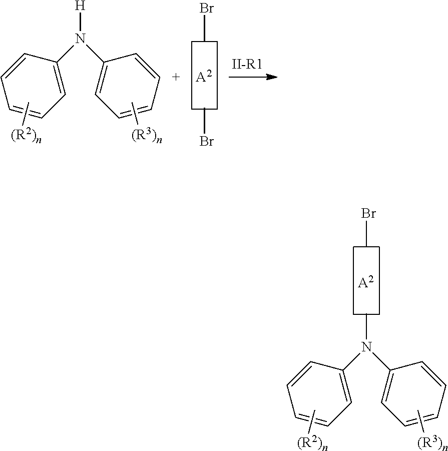

The synthesis in synthesis step II-R1 was based on the references cited under I-R2.

(b2) Synthesis Step II-R2:

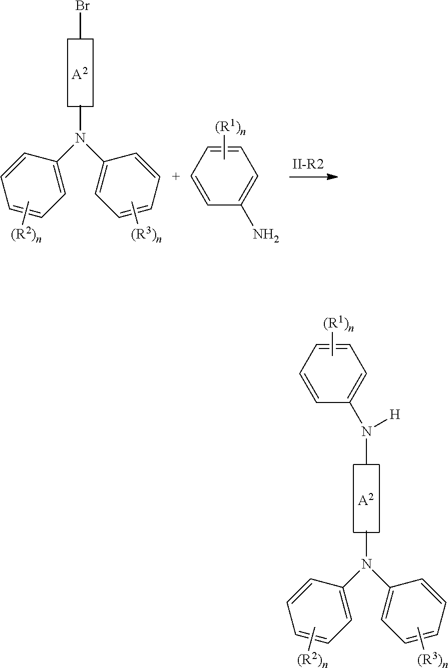

The synthesis in synthesis step II-R2 was based on the references cited below:

a) Bacher, Erwin; Bayerl, Michael; Rudati, Paula; Reckefuss, Nina; Müller, C. David; Meerholz, Klaus; Nuyken, Oskar; Macromolecules; 38; 5; 2005; 1640-1647,

b) Goodson, Felix E.; Hauck, Sheila; Hartwig, John F.; J. Am. Chem. Soc.; 121; 33; 1999; 7527-7539; Hauck, Sheila I.; Lakshmi, K. V.; Hartwig, John F.; Org. Lett.; 1; 13; 1999; 2057-2060.

(b3) Synthesis Step II-R3:

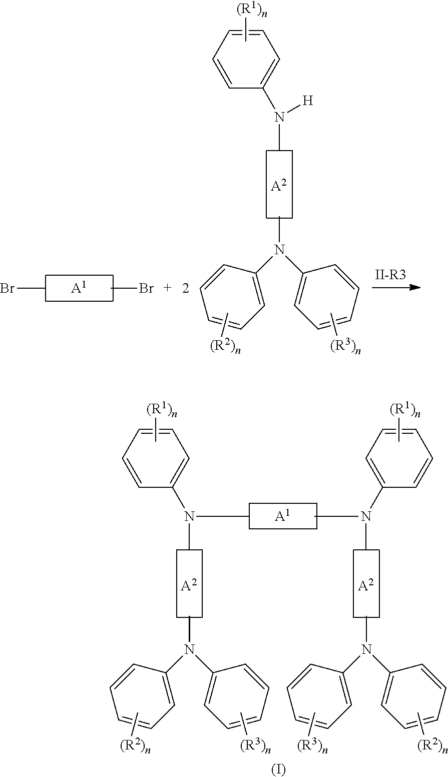

The compounds of the formula I can be prepared via the sequence of synthesis steps shown above in synthesis route II. In steps (II-R1) to (II-R3), the reactants can be coupled, as also in synthesis route I, for example, by Ullmann reaction with copper as a catalyst or under palladium catalysis.

(c) Preparation of the Starting Amines:

When the diarylamines in synthesis steps I-R2 and II-R1 of synthesis routes I and II are not commercially available, they can be prepared, for example, by Ullmann reaction with copper as a catalyst or under palladium catalysis, according to the following reaction:

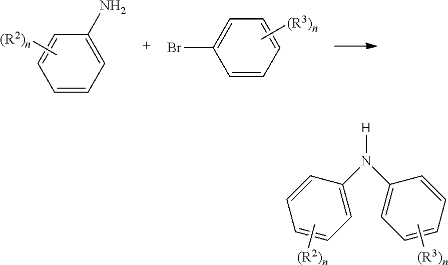

The synthesis was based on the review articles listed below:

Palladium-Catalyzed C—N Coupling Reactions:

a) Yang, Buchwald; J. Organomet. Chem. 1999, 576 (1-2), 125-146,

b) Wolfe, Marcoux, Buchwald; Acc. Chem. Res. 1998, 31, 805-818,

c) Hartwig; Angew. Chem. Int. Ed. Engl. 1998, 37, 2046-2067.

Copper-Catalyzed C—N Coupling Reactions:

a) Goodbrand, Hu; Org. Chem. 1999, 64, 670-674,

b) Lindley; Tetrahedron 1984, 40, 1433-1456.

### (B) SYNTHESIS EXAMPLE 1

### Synthesis of the Compound ID367 (Synthesis Route I)

### (B1): SYNTHESIS STEP ACCORDING TO GENERAL SYNTHESIS SCHEME I-R1

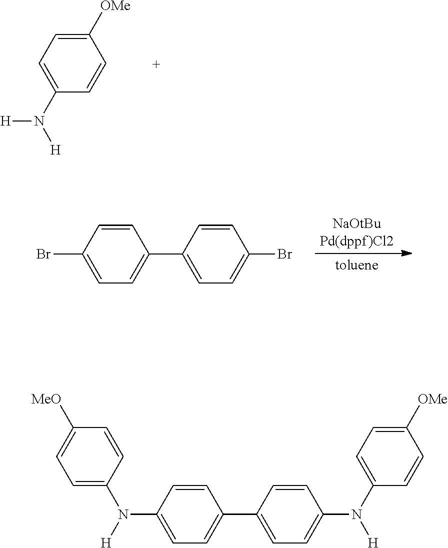

A mixture of 4,4′-dibromobiphenyl (93.6 g; 300 mmol), 4-methoxyaniline (133 g; 1.08 mol), Pd(dppf)Cl₂ (Pd(1,1′-bis(diphenylphosphino)ferrocene)Cl₂; 21.93 g; 30 mmol) and t-BuONa (sodium tert-butoxide; 109.06 g; 1.136 mol) in toluene (1500 ml) was stirred under a nitrogen atmosphere at 110° C. for 24 hours. After cooling, the mixture was diluted with diethyl ether and filtered through a Celite® pad (from Carl Roth). The filter bed was washed with 1500 ml each of ethyl acetate, methanol and methylene chloride. The product was obtained as a light brown solid (36 g; yield: 30%).

¹H NMR (400 MHz, DMSO): δ 7.81 (s, 2H), 7.34-7.32 (m, 4H), 6.99-6.97 (m, 4H), 6.90-6.88 (m, 4H), 6.81-6.79 (m, 4H), 3.64 (s, 6H).

### (B2): SYNTHESIS STEP ACCORDING TO GENERAL SYNTHESIS SCHEME I-R2

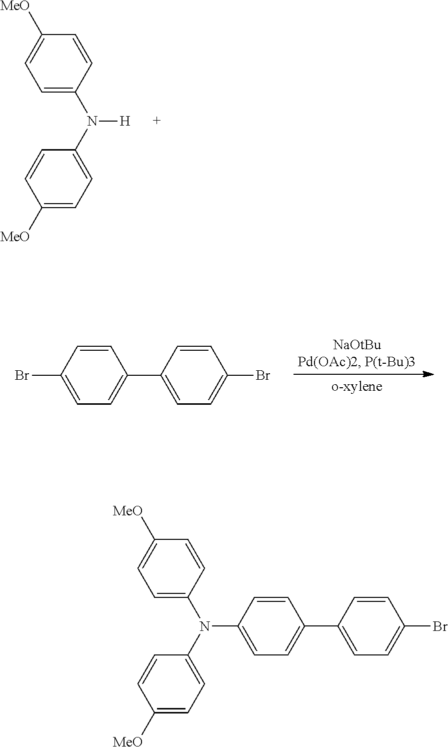

Nitrogen was passed for a period of 10 minutes through a solution of dppf (1,1′-bis(diphenylphosphino)ferrocene; 0.19 g; 0.34 mmol) and Pd₂(dba)₃ (tris(dibenzylideneacetone)dipalladium(0); 0.15 g; 0.17 mmol) in toluene (220 ml). Subsequently, t-BuONa (2.8 g; 29 mmol) was added and the reaction mixture was stirred for a further 15 minutes. 4,4′-Dibromobiphenyl (25 g; 80 mmol) and 4,4′-dimethoxydiphenylamine (5.52 g; 20 mmol) were then added successively. The reaction mixture was heated at a temperature of 100° C. under a nitrogen atmosphere for 7 hours. After cooling to room temperature, the reaction mixture was quenched with ice-water, and the precipitated solid was filtered off and dissolved in ethyl acetate. The organic layer was washed with water, dried over sodium sulfate and purified by column chromatography (eluent: 5% ethyl acetate/hexane). A pale yellow solid was obtained (7.58 g, yield: 82%).

¹H NMR (300 MHz, DMSO-d₆): 7.60-7.49 (m, 6H), 7.07-7.04 (m, 4H), 6.94-6.91 (m, 4H), 6.83-6.80 (d, 2H), 3.75 (s, 6H).

### (B3): SYNTHESIS STEP ACCORDING TO GENERAL SYNTHESIS SCHEME I-R3

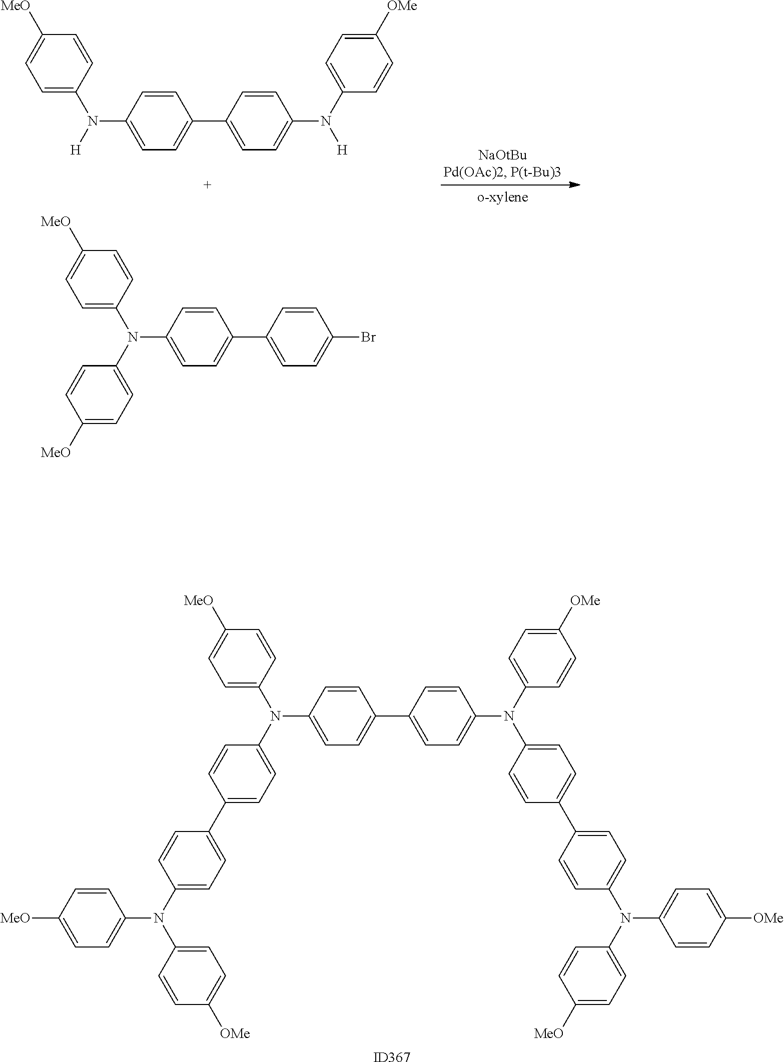

N⁴,N⁴′-Bis(4-methoxyphenyl)biphenyl-4,4′-diamine (product from synthesis step I-R1; 0.4 g; 1.0 mmol) and product from synthesis step I-R2 (1.0 g; 2.2 mmol) were added under a nitrogen atmosphere to a solution of t-BuONa (0.32 g; 3.3 mmol) in o-xylene (25 ml). Subsequently, palladium acetate (0.03 g; 0.14 mmol) and a solution of 10% by weight of P(t-Bu)₃ (tris-t-butylphosphine) in hexane (0.3 ml; 0.1 mmol) were added to the reaction mixture which was stirred at 125° C. for 7 hours. Thereafter, the reaction mixture was diluted with 150 ml of toluene and filtered through Celite®, and the organic layer was dried over Na₂SO₄. The solvent was removed and the crude product was reprecipitated three times from a mixture of tetrahydrofuran (THF)/methanol. The solid was purified by column chromatography (eluent: 20% ethyl acetate/hexane), followed by a precipitation with THF/methanol and an activated carbon purification. After removing the solvent, the product was obtained as a pale yellow solid (1.0 g, yield: 86%).

¹H NMR (400 MHz, DMSO-d₆): 7.52-7.40 (m, 8H), 6.88-7.10 (m, 32H), 6.79-6.81 (d, 4H), 3.75 (s, 6H), 3.73 (s, 12H).

### (C) SYNTHESIS EXAMPLE 2

### Synthesis of the Compound ID447 (Synthesis Route II)

### (C1) SYNTHESIS STEP ACCORDING TO GENERAL SYNTHESIS SCHEME II-R2

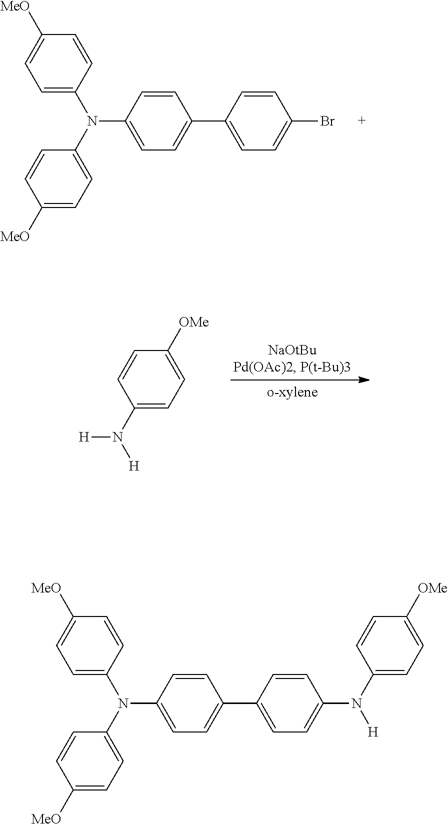

p-Anisidine (5.7 g, 46.1 mmol), t-BuONa (5.5 g, 57.7 mol) and P(t-Bu)₃ (0.62 ml, 0.31 mmol) were added to a solution of the product from synthesis step I-R2 (17.7 g, 38.4 mmol) in toluene (150 ml). After nitrogen had been passed through the reaction mixture for 20 minutes, Pd₂(dba)₃ (0.35 g, 0.38 mmol) was added. The resulting reaction mixture was left to stir under a nitrogen atmosphere at room temperature for 16 hours. Subsequently, it was diluted with ethyl acetate and filtered through Celite®. The filtrate was washed twice with 150 ml each of water and saturated sodium chloride solution. After the organic phase had been dried over Na₂SO₄ and the solvent had been removed, a black solid was obtained. This solid was purified by column chromatography (eluent: 0-25% ethyl acetate/hexane). This afforded an orange solid (14 g, yield: 75%).

¹H NMR (300 MHz, DMSO): 7.91 (s, 1H), 7.43-7.40 (d, 4H), 7.08-6.81 (m, 16H), 3.74 (s, 6H), 3.72 (s, 3H).

### (C1) SYNTHESIS STEP ACCORDING TO GENERAL SYNTHESIS SCHEME II-R3

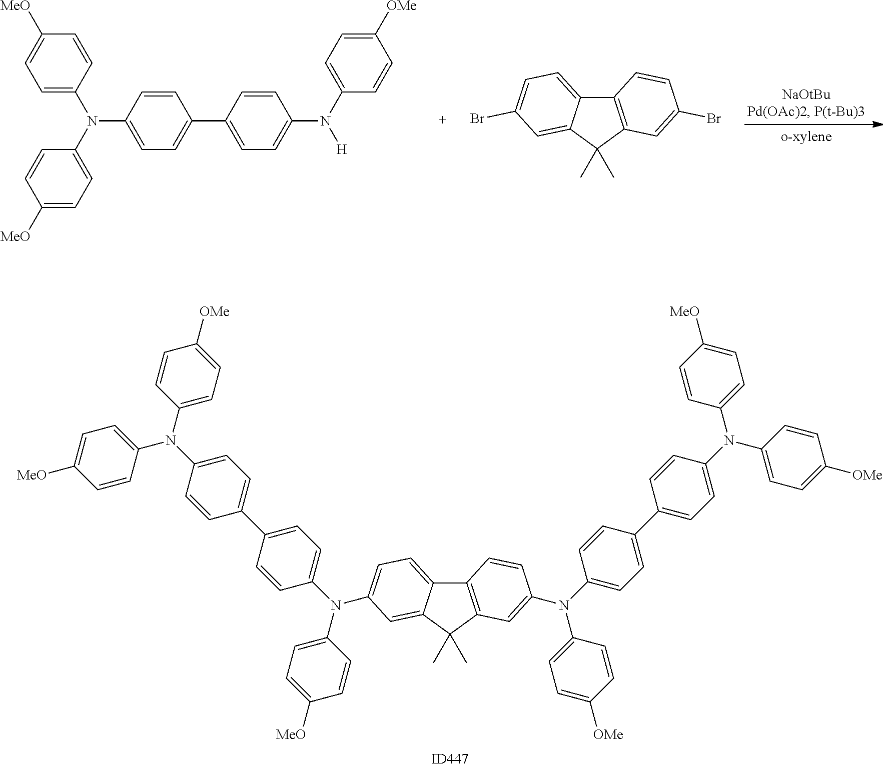

t-BuONa (686 mg; 7.14 mmol) was heated at 100° C. under reduced pressure, then the reaction flask was purged with nitrogen and allowed to cool to room temperature. 2,7-Dibromo-9,9-dimethylfluorene (420 mg; 1.19 mmol), toluene (40 ml) and Pd[P(^{t}Bu)₃]₂ (20 mg; 0.0714 mmol) were then added, and the reaction mixture was stirred at room temperature for 15 minutes. Subsequently, N,N,N′-p-trimethoxytriphenylbenzidine (1.5 g; 1.27 mmol) was added to the reaction mixture which was stirred at 120° C. for 5 hours. The mixture was filtered through a Celite®/MgSO₄ mixture and washed with toluene. The crude product was purified twice by column chromatography (eluent: 30% ethyl acetate/hexane) and, after twice reprecipitating from THF/methanol, a pale yellow solid was obtained (200 mg, yield: 13%).

¹H NMR: (400 MHz, DMSO-d₆): 7.60-7.37 (m, 8H), 7.02-6.99 (m, 16H), 6.92-6.87 (m, 20H), 6.80-6.77 (d, 2H), 3.73 (s, 6H), 3.71 (s, 12H), 1.25 (s, 6H)

### (D) SYNTHESIS EXAMPLE 3

### Synthesis of the Compound ID453 (Synthesis Route I)

### (D1) PREPARATION OF THE STARTING AMINE

Step 1:

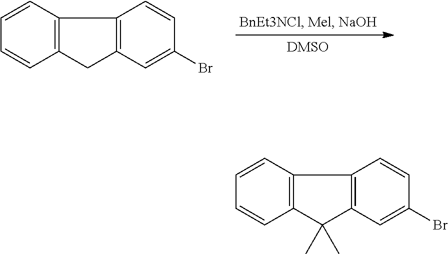

NaOH (78 g; 4 eq) was added to a mixture of 2-bromo-9H-fluorene (120 g; 1 eq) and BnEt₃NCl (benzyltriethylammonium chloride; 5.9 g; 0.06 eq) in 580 ml of DMSO (dimethyl-sulfoxide). The mixture was cooled with ice-water, and methyl iodide (Mel) (160 g; 2.3 eq) was slowly added dropwise. The reaction mixture was left to stir overnight, then poured into water and subsequently extracted three times with ethyl acetate. The combined organic phases were washed with a saturated sodium chloride solution and dried over Na₂SO₄, and the solvent was removed. The crude product was purified by column chromatography using silica gel (eluent: petroleum ether). After washing with methanol, the product (2-bromo-9,9′-dimethyl-9H-fluorene) was obtained as a white solid (102 g).

¹H NMR (400 MHz, CDCl3): δ 1.46 (s, 6H), 7.32 (m, 2H), 7.43 (m, 2H), 7.55 (m, 2H), 7.68 (m, 1H)

Step 2:

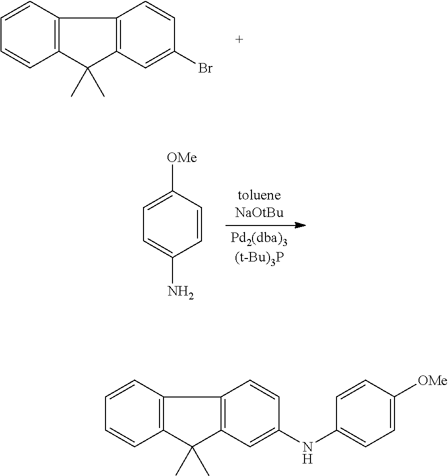

p-Anisidine (1.23 g; 10.0 mmol) and 2-bromo-9,9′-dimethyl-9H-fluorene (3.0 g; 11.0 mmol) were added under a nitrogen atmosphere to a solution of t-BuONa (1.44 g; 15.0 mmol) in 15 ml of toluene (15 ml). Pd₂(dba)₃ (92 mg; 0.1 mmol) and a 10% by weight solution of P(t-Bu)₃ in hexane (0.24 ml; 0.08 mmol) were added, and the reaction mixture was stirred at room temperature for 5 hours. Subsequently, the mixture was quenched with ice-water, and the precipitated solid was filtered off and dissolved in ethyl acetate. The organic phase was washed with water and dried over Na₂SO₄. After purifying the crude product by column chromatography (eluent: 10% ethyl acetate/hexane), a pale yellow solid was obtained (1.5 g, yield: 48%).

¹H NMR (300 MHz, C₆D₆): 7.59-7.55 (d, 1H), 7.53-7.50 (d, 1H), 7.27-7.22 (t, 2H), 7.19 (s, 1H), 6.99-6.95 (d, 2H), 6.84-6.77 (m, 4H), 4.99 (s, 1H), 3.35 (s, 3H), 1.37 (s, 6H).

### (D2) PREPARATION OF THE COMPOUND ID453 FOR USE IN ACCORDANCE WITH THE INVENTION

(D2.1): Synthesis Step According to General Synthesis Scheme I-R2:

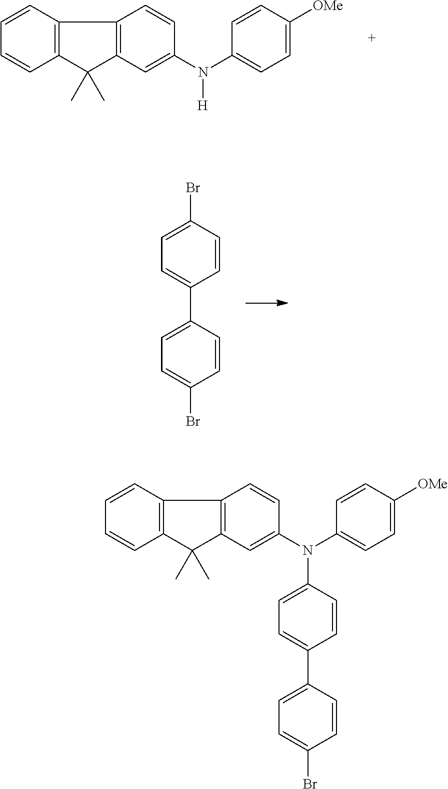

Product from a) (4.70 g; 10.0 mmol) and 4,4′-dibromobiphenyl (7.8 g; 25 mmol) were added to a solution of t-BuONa (1.15 g; 12 mmol) in 50 ml of toluene under nitrogen. Pd₂(dba)₃ (0.64 g; 0.7 mmol) and DPPF (0.78 g; 1.4 mmol) were added, and the reaction mixture was left to stir at 100° C. for 7 hours. After the reaction mixture had been quenched with ice-water, the precipitated solid was filtered off and it was dissolved in ethyl acetate. The organic phase was washed with water and dried over Na₂SO₄. After purifying the crude product by column chromatography (eluent: 1% ethyl acetate/hexane), a pale yellow solid was obtained (4.5 g, yield: 82%).

¹H NMR (400 MHz, DMSO-d6): 7.70-7.72 (d, 2H), 7.54-7.58 (m, 6H), 7.47-7.48 (d, 1H), 7.21-7.32 (m, 3H), 7.09-7.12 (m, 2H), 6.94-6.99 (m, 4H), 3.76 (s, 3H), 1.36 (s, 6H).

(D2.2) Synthesis Step According to General Synthesis Scheme I-R3:

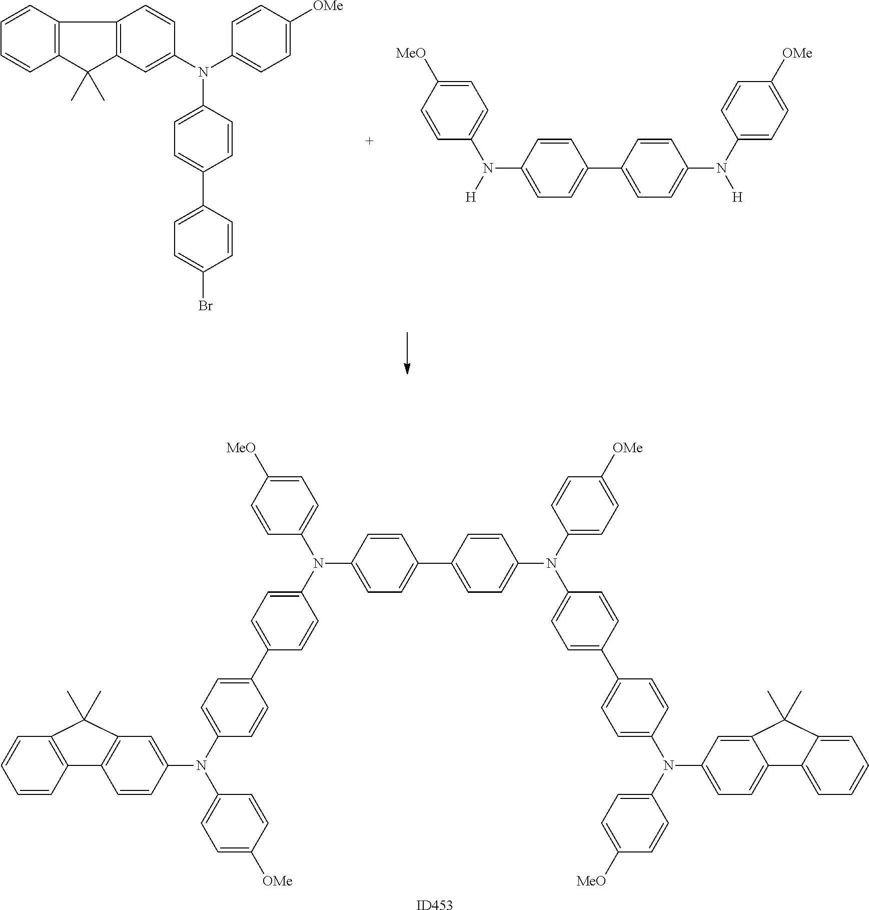

N⁴,N⁴′-Bis(4-methoxyphenyl)biphenyl-4,4′-diamine (0.60 g; 1.5 mmol) and product from the preceding synthesis step I-R2 (1.89 g; 3.5 mmol) were added under nitrogen to a solution of t-BuONa (0.48 g; 5.0 mmol) in 30 ml of o-xylene. Palladium acetate (0.04 g; 0.18 mmol) and P(t-Bu)₃ in a 10% by weight solution in hexane (0.62 ml; 0.21 mmol) were added, and the reaction mixture was stirred at 125° C. for 6 hours. Subsequently, the mixture was diluted with 100 ml of toluene and filtered through Celite®. The organic phase was dried over Na₂SO₄ and the resulting solid was purified by column chromatography (eluent: 10% ethyl acetate/hexane). This was followed by reprecipitation from THF/methanol to obtain a pale yellow solid (1.6 g, yield: 80%).

¹H NMR (400 MHz, DMSO-d₆): 7.67-7.70 (d, 4H), 7.46-7.53 (m, 14H), 7.21-7.31 (m, 4H), 7.17-7.18 (d, 2H), 7.06-7.11 (m, 8H), 6.91-7.01 (m, 22H), 3.75 (s, 12H), 1.35 (s, 12H).

### (E) FURTHER COMPOUNDS OF THE FORMULA I FOR USE IN ACCORDANCE WITH THE INVENTION

The compounds listed below were obtained analogously to the syntheses described above:

### (E1) SYNTHESIS EXAMPLE 4

### Compound ID320

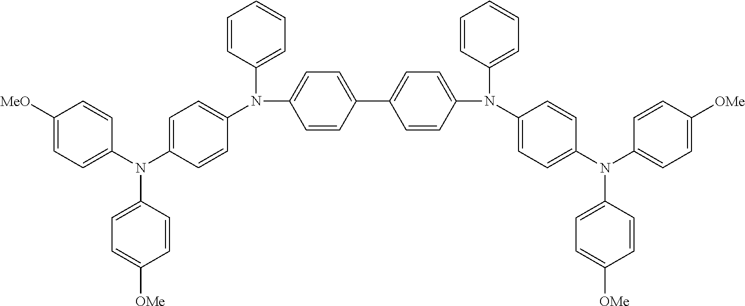

¹H NMR (300 MHz, THF-d₈): δ 7.43-7.46 (d, 4H), 7.18-7.23 (t, 4H), 7.00-7.08 (m, 16H), 6.81-6.96 (m, 18H), 3.74 (s, 12H)

### (E2) SYNTHESIS EXAMPLE 5

### Compound ID321

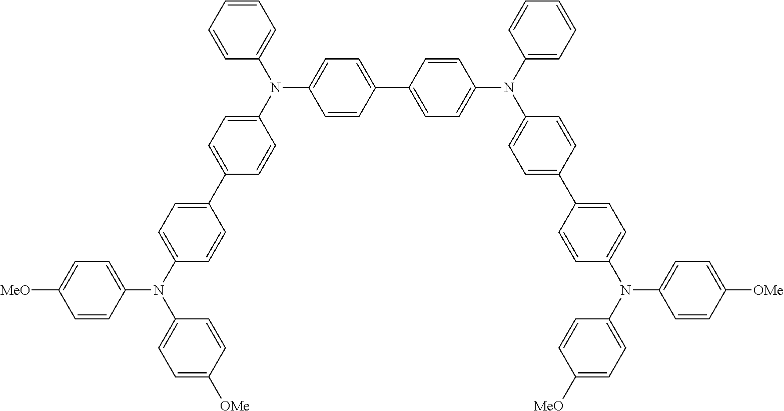

¹H NMR (300 MHz, THF-d₈): δ 7.37-7.50 (t, 8H), 7.37-7.40 (d, 4H), 7.21-7.26 (d, 4H), 6.96-7.12 (m, 22H), 6.90-6.93 (d, 4H), 6.81-6.84 (d, 8H), 3.74 (s, 12H)

### (E3) SYNTHESIS EXAMPLE 6

### Compound ID366

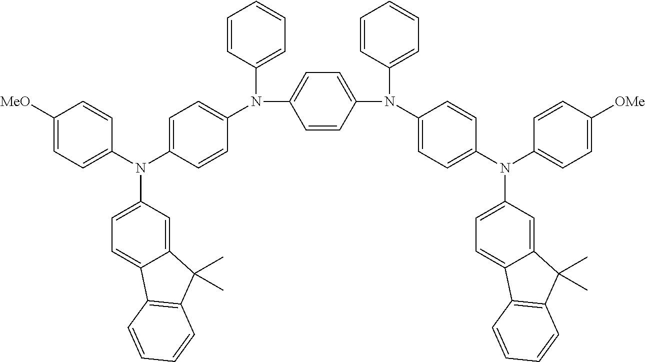

¹H NMR (400 MHz, DMSO-d6): δ 7.60-7.70 (t, 4H), 7.40-7.55 (d, 2H), 7.17-7.29 (m, 8H), 7.07-7.09 (t, 4H), 7.06 (s, 2H), 6.86-7.00 (m, 24H), 3.73 (s, 6H), 1.31 (s, 12H)

### (E4) SYNTHESIS EXAMPLE 7

### Compound ID368

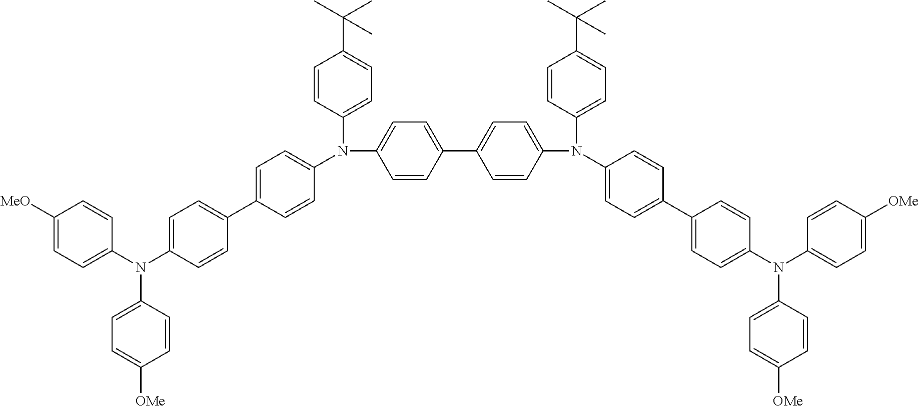

¹H NMR (400 MHz, DMSO-d6): δ 7.48-7.55 (m, 8H), 7.42-7.46 (d, 4H), 7.33-7.28 (d, 4H), 6.98-7.06 (m, 20H), 6.88-6.94 (m, 8H), 6.78-6.84 (d, 4H), 3.73 (s, 12H), 1.27 (s, 18H)

### (E5) SYNTHESIS EXAMPLE 8

### Compound ID369

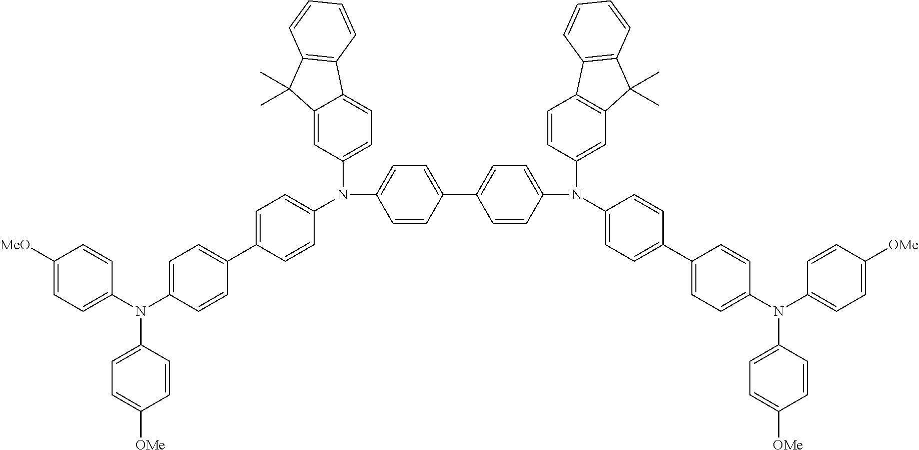

¹H NMR (400 MHz, THF-d8): δ 7.60-7.70 (t, 4H), 7.57-7.54 (d, 4H), 7.48-7.51 (d, 4H), 7.39-7.44 (t, 6H), 7.32-7.33 (d, 2H), 7.14-7.27 (m, 12H), 7.00-7.10 (m, 10H), 6.90-6.96 (m, 4H), 6.80-6.87 (m, 8H), 3.75 (s, 12H), 1.42 (s, 12H)

### (E6) SYNTHESIS EXAMPLE 9

### Compound ID446

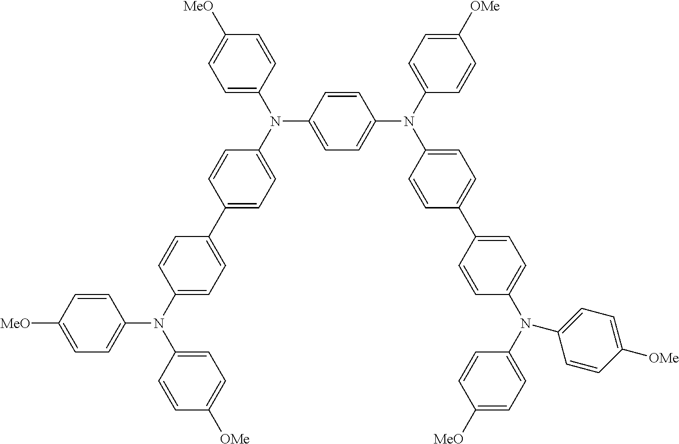

¹H NMR (400 MHz, dmso-d₆): δ 7.39-7.44 (m, 8H), 7.00-7.07 (m, 13H), 6.89-6.94 (m, 19H), 6.79-6.81 (d, 4H), 3.73 (s, 18H)

### (E7) SYNTHESIS EXAMPLE 10

### Compound ID450

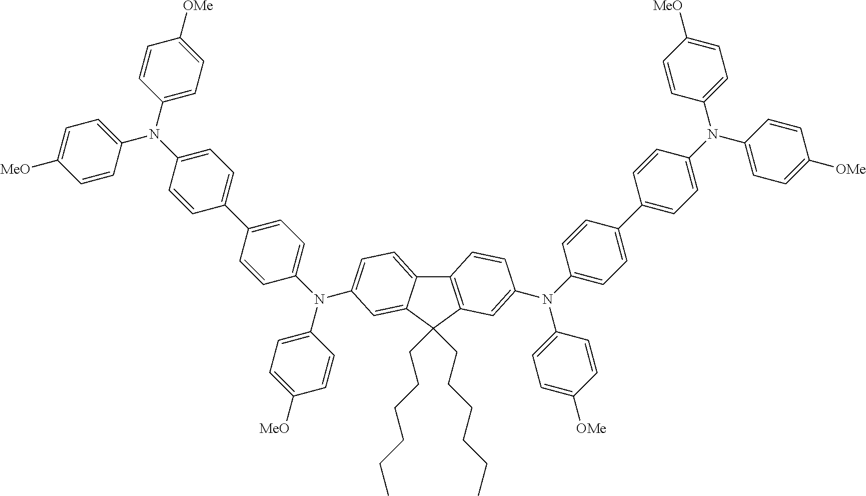

¹H NMR (400 MHz, dmso-d₆): δ 7.55-7.57 (d, 2H), 7.39-7.45 (m, 8H), 6.99-7.04 (m, 15H), 6.85-6.93 (m, 19H), 6.78-6.80 (d, 4H), 3.72 (s, 18H), 1.68-1.71 (m, 6H), 1.07 (m, 6H), 0.98-0.99 (m, 8H), 0.58 (m, 6H)

### (E8) SYNTHESIS EXAMPLE 11

### Compound ID452

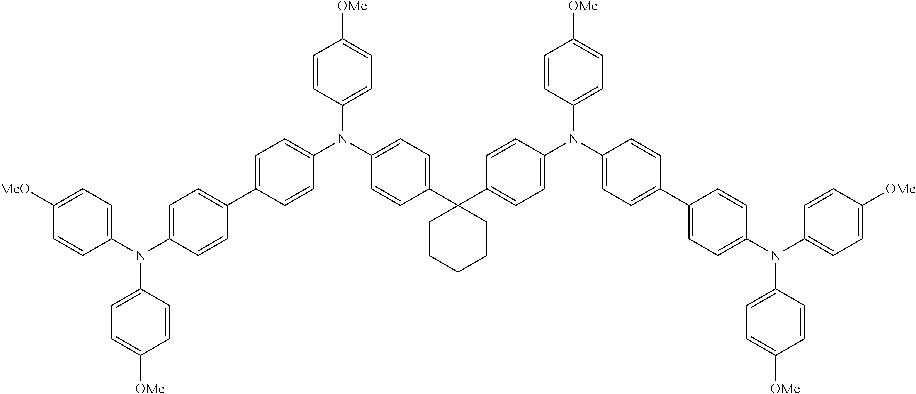

¹H NMR (400 MHz, DMSO-d6): δ 7.38-7.44 (m, 8H), 7.16-7.19 (d, 4H), 6.99-7.03 (m, 12H), 6.85-6.92 (m, 20H), 6.77-6.79 (d, 4H), 3.74 (s, 18H), 2.00-2.25 (m, 4H), 1.25-1.50 (m, 6H)

### (E9) SYNTHESIS EXAMPLE 12

### Compound ID480

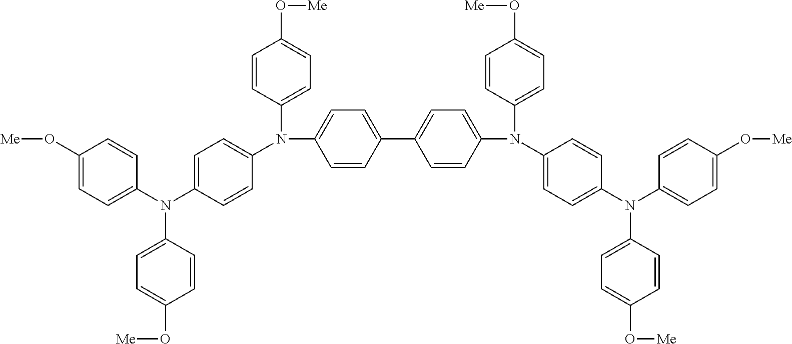

¹H NMR (400 MHz, DMSO-d6): δ 7.40-7.42 (d, 4H), 7.02-7.05 (d, 4H), 6.96-6.99 (m, 28H), 6.74-6.77 (d, 4H), 3.73 (s, 6H), 3.71 (s, 12H)

### (E10) SYNTHESIS EXAMPLE 13

### Compound ID518

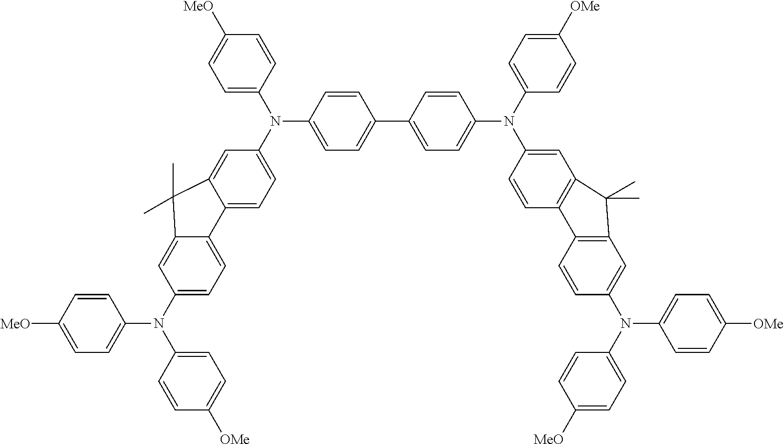

¹H NMR (400 MHz, DMSO-d6): 7.46-7.51 (m, 8H), 7.10-7.12 (d, 2H), 7.05-7.08 (d, 4H), 6.97-7.00 (d, 8H), 6.86-6.95 (m, 20H), 6.69-6.72 (m, 2H), 3.74 (s, 6H), 3.72 (s, 12H), 1.24 (t, 12H)

### (E11) SYNTHESIS EXAMPLE 14

### Compound ID519

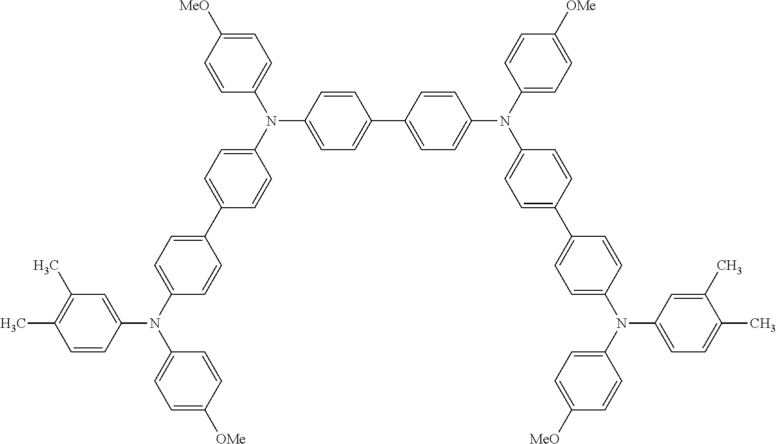

¹H NMR (400 MHz, DMSO-d6): 7.44-7.53 (m, 12H), 6.84-7.11 (m, 32H), 6.74-6.77 (d, 2H), 3.76 (s, 6H), 3.74 (s, 6H), 2.17 (s, 6H), 2.13 (s, 6H)

### (E12) SYNTHESIS EXAMPLE 15

### Compound ID521

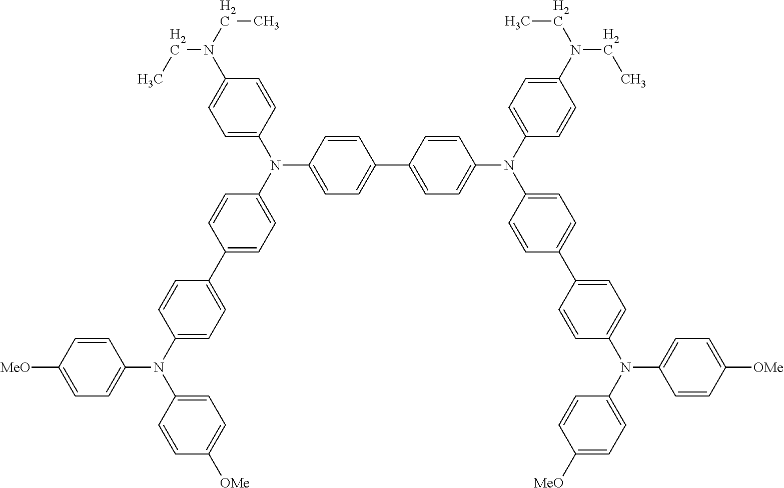

¹H NMR (400 MHz, THF-d₆): 7.36-7.42 (m, 12H), 6.99-7.07 (m, 20H), 6.90-6.92 (d, 4H), 6.81-6.84 (m, 8H), 6.66-6.69 (d, 4H), 3.74 (s, 12H), 3.36-3.38 (q, 8H), 1.41-1.17 (t, 12H)

### (E13) SYNTHESIS EXAMPLE 16

### Compound ID522

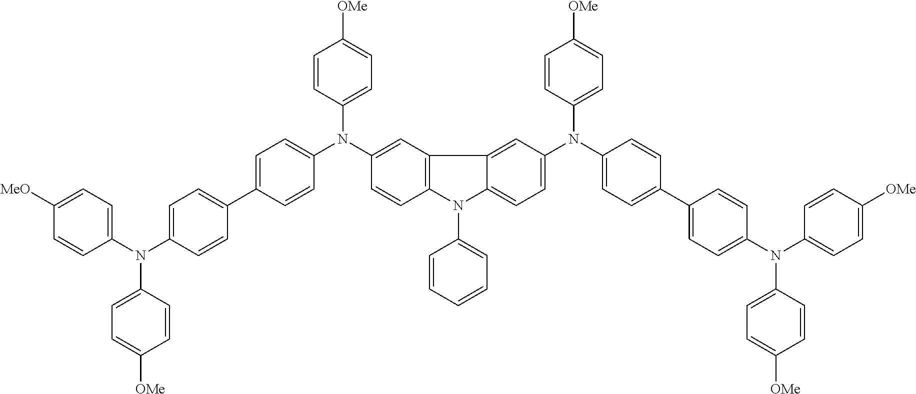

¹H NMR (400 MHz, DMSO-d₆): 7.65 (s, 2H), 7.52-7.56 (t, 2H), 7.44-7.47 (t, 1H), 7.37-7.39 (d, 2H), 7.20-7.22 (m, 10H), 7.05-7.08 (dd, 2H), 6.86-6.94 (m, 8H), 6.79-6.80-6.86 (m, 12H), 6.68-6.73, (dd, 8H), 6.60-6.62 (d, 4H), 3.68 (s, 12H), 3.62 (s, 6H)

### (E14) SYNTHESIS EXAMPLE 17

### Compound ID523

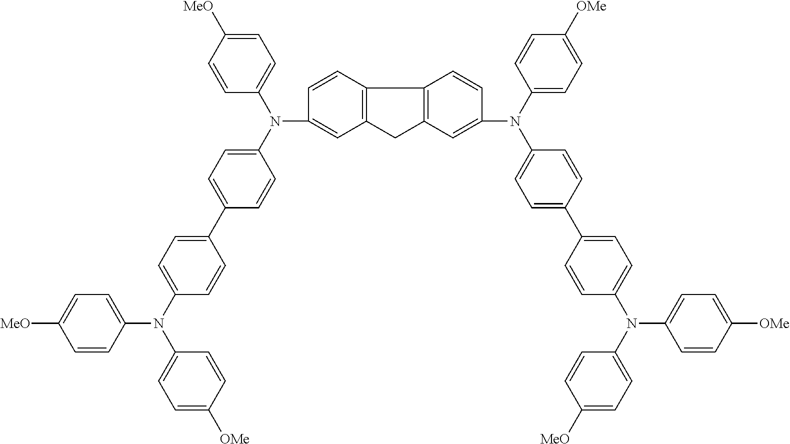

¹H NMR (400 MHz, THF-d₈): 7.54-7.56 (d, 2H), 7.35-7.40 (dd, 8H), 7.18 (s, 2H), 7.00-7.08 (m, 18H), 6.90-6.92 (d, 4H), 6.81-6.86 (m, 12H), 3.75 (s, 6H), 3.74 (s, 12H), 3.69 (s, 2H)

### (E15) SYNTHESIS EXAMPLE 18

### Compound ID565

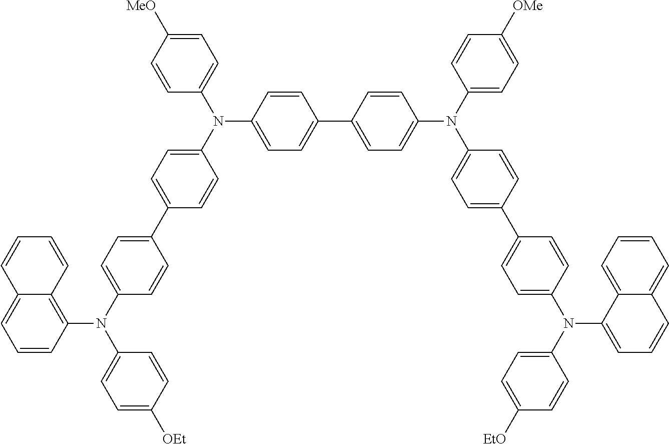

¹H NMR (400 MHz, THF-d8): 7.97-8.00 (d, 2H), 7.86-7.89 (d, 2H), 7.73-7.76 (d, 2H), 7.28-7.47 (m, 20H), 7.03-7.08 (m, 16H), 6.78-6.90 (m, 12H), 3.93-3.99 (q, 4H), 3.77 (s, 6H), 1.32-1.36 (s, 6H)

### (E16) SYNTHESIS EXAMPLE 19

### Compound ID568

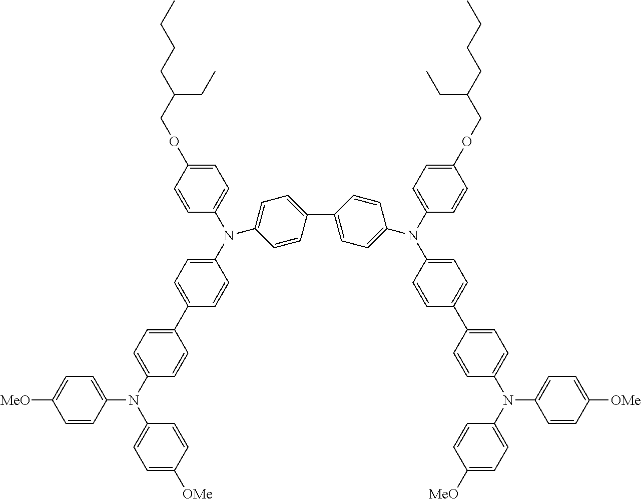

¹H NMR (400 MHz, DMSO-d6): 7.41-7.51 (m, 12H), 6.78-7.06 (m, 36H), 3.82-3.84 (d, 4H), 3.79 (s, 12H), 1.60-1.80 (m, 2H), 0.60-1.60 (m, 28H

### (E17) SYNTHESIS EXAMPLE 20

### Compound ID569

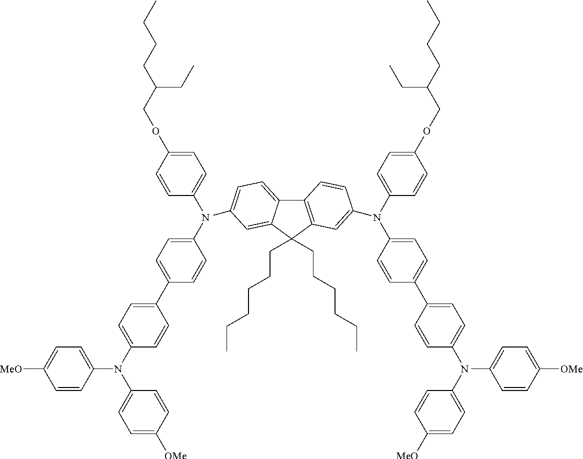

¹H NMR (400 MHz, DMSO-d6): 7.40-7.70 (m, 10H), 6.80-7.20 (m, 36H), 3.92-3.93 (d, 4H), 2.81 (s, 12H), 0.60-1.90 (m, 56H)

### (E18) SYNTHESIS EXAMPLE 21

### Compound ID572

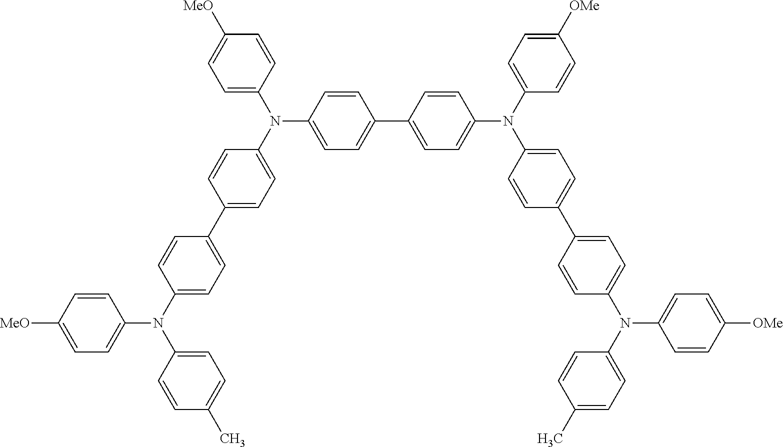

¹H NMR (400 MHz, THF-d8): 7.39-7.47 (m, 12H), 7.03-7.11 (m, 20H), 6.39-6.99 (m, 8H), 6.83-6.90 (m, 8H), 3.78 (s, 6H), 3.76 (s, 6H), 2.27 (s, 6H)

### (E19) SYNTHESIS EXAMPLE 22

### Compound ID573

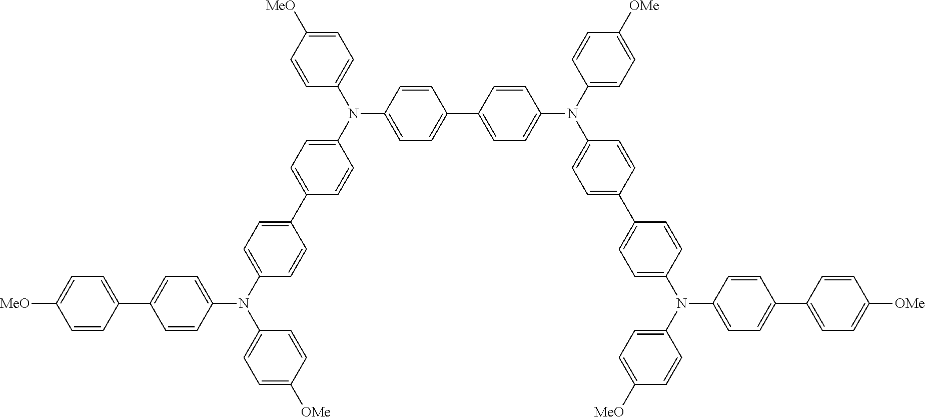

¹H NMR (400 MHz, THF-d8): 7.43-7.51 (m, 20H), 7.05-7.12 (m, 24H), 6.87-6.95 (m, 12H), 3.79 (s, 6H), 3.78 (s, 12H)

### (E20) SYNTHESIS EXAMPLE 23

### Compound ID575

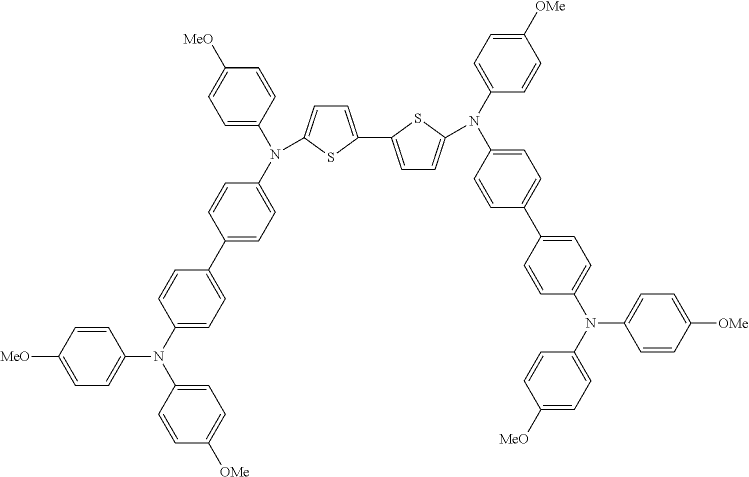

¹H NMR (400 MHz, DMSO-d6): 7.35-7.55 (m, 8H), 7.15-7.45 (m, 4H), 6.85-7.10 (m, 26H), 6.75-6.85 (d, 4H), 6.50-6.60 (d, 2H), 3.76 (s, 6H), 3.74 (s, 12H)

### (E21) SYNTHESIS EXAMPLE 24

### Compound ID629

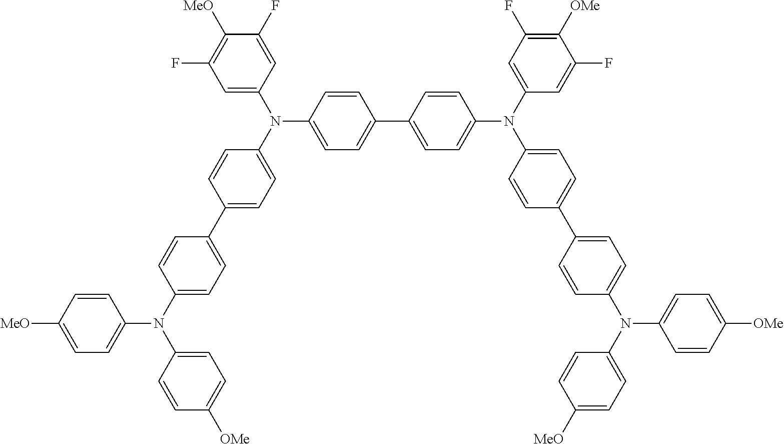

¹H NMR (400 MHz, THF-d₈): 7.50-7.56 (dd, 8H), 7.38-7.41 (dd, 4H), 7.12-7.16 (d, 8H), 7.02-7.04 (dd, 8H), 6.91-6.93 (d, 4H), 6.82-6.84 (dd, 8H), 6.65-6.68 (d, 4H) 3.87 (s, 6H), 3.74 (s, 12H)

### (E22) SYNTHESIS EXAMPLE 25

### Compound ID631

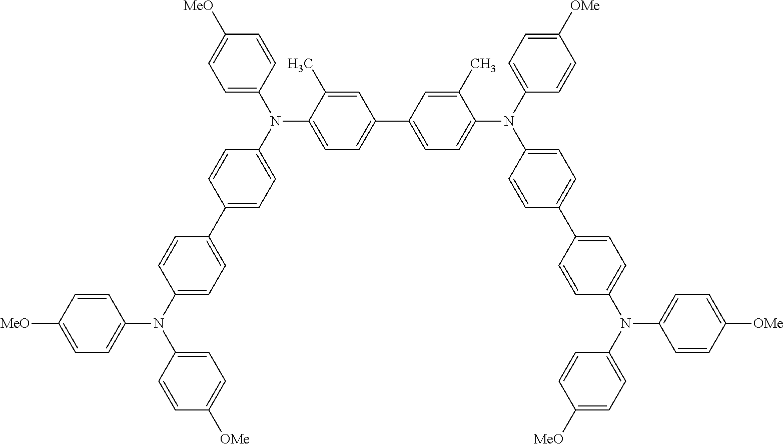

¹H NMR (400 MHz, THF-d₆): 7.52 (d, 2H), 7.43-7.47 (dd, 2H), 7.34-7.38 (m, 8H), 7.12-7.14 (d, 2H), 6.99-7.03 (m, 12H), 6.81-6.92 (m, 20H), 3.74 (s, 18H), 2.10 (s, 6H)

### (F) SYNTHESIS OF COMPOUNDS OF THE FORMULA IV

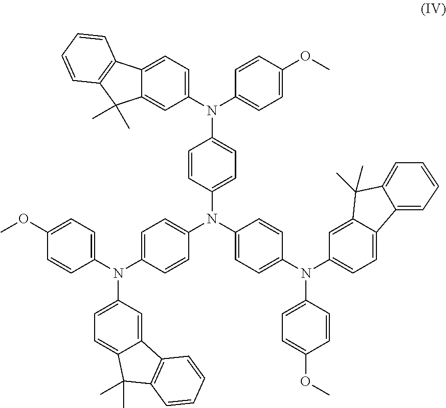

(a) Coupling of p-Anisidine and 2-bromo-9,9-dimethyl-9H-fluorene

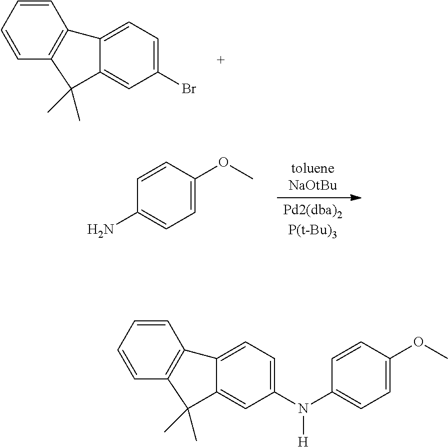

To 0.24 ml (0.08 mmol) of P(t-Bu)₃ (d=0.68 g/ml) and 0.1 g of Pd₂(dba)₂[=(tris(dibenzylideneacetone)dipalladium(0)] (0.1 mmol) were added 10 ml to 15 ml of toluene (anhydrous, 99.8%), and the mixture was stirred at room temperature for 10 min. 1.44 g (15 mmol) of sodium tert-butoxide (97.0%) were added and the mixture was stirred at room temperature for a further 15 min. Subsequently, 2.73 g (11 mmol) of 2-bromo-9,9-dimethyl-9H-fluorene were added and the reaction mixture was stirred for a further 15 min. Finally, 1.23 g (10 mmol) of p-anisidine were added and the mixture was stirred at 90° C. for 4 h.

The reaction mixture was admixed with water and the product was precipitated from hexane. The aqueous phase was additionally extracted with ethyl acetate. The organic phase and the precipitated solid which had been filtered off were combined and purified by column chromatography on an SiO₂ phase (10:1 hexane:ethyl acetate).

1.5 g (yield: 47.6%) of a yellow solid were obtained.

¹HNMR (300 MHz, C6D6): 6.7-7.6 (m, 11H), 5.00 (s, 1H,), 3.35 (s, 3H), 1.37 (s, 6H)

(b) Coupling of the Product from (a) with tris(4-bromophenyl)amine

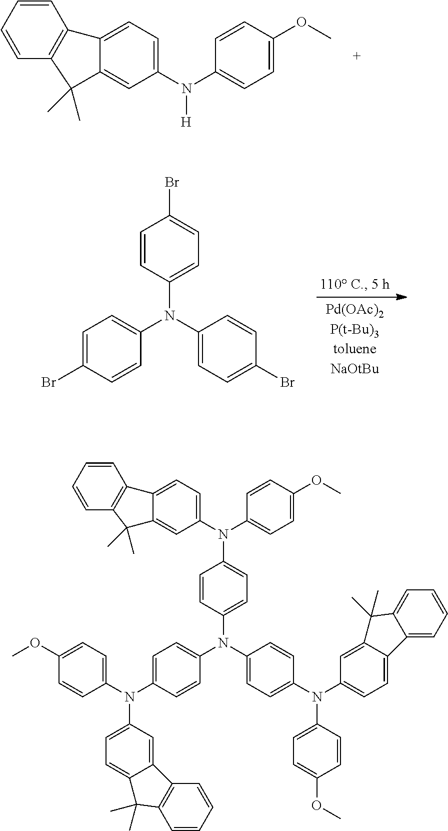

To 0.2 ml (0.07 mmol) of P(t-Bu)₃ (D=0.68 g/ml) and 0.02 g (0.1 mmol) of palladium acetate were added 25 ml of toluene (anhydrous), and the mixture was stirred at room temperature for 10 min. 0.4 g (1.2 mmol) of sodium tert-butoxide (97.0%) was added and the mixture was stirred at room temperature for a further 15 min. Subsequently, 0.63 g (1.3 mmol) of tris(4-bromophenyl)amine was added and the reaction mixture was stirred for a further 15 min. Finally, 1.3 g (1.4 mmol) of the product from step (a) were added and the mixture was stirred at 90° C. for 5 h.

The reaction mixture was admixed with ice-cold water and extracted with ethyl acetate. The product was precipitated from a mixture of hexane/ethyl acetate and purified by column chromatography on SiO₂ phase (9:1→5:1 hexane:ethyl acetate gradient).

0.7 g (yield: 45%) of a yellow product was obtained.

¹HNMR (300 MHz, C6D6): 6.6-7.6 (m, 45H), 3.28 (s, 9H), 1.26 (s, 18H)

### (G) SYNTHESIS OF COMPOUNDS ID504

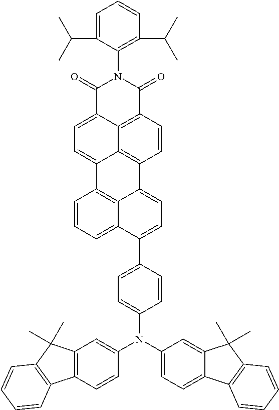

The preparation proceeded from (4-bromophenyl)bis(9,9-dimethyl-9H-fluoren-2-yl) (see Chemical Communications, 2004, 68-69), which was first reacted with 4,4,5,5,4′,4′,5′,5′-octamethyl-[2,2′]bi[[1,3,2]dioxaborolanyl] (step a). This was followed by coupling with 9Br-DIPP-PDCl (step b). This was followed by hydrolysis to give the anhydride (step c) and subsequent reaction with glycine to give the final compound (step d).

Step a:

A mixture of 30 g (54 mmol) of (4-bromophenyl)bis(9,9-dimethyl-9H-fluoren-2-yl), 41 g (162 mmol) of 4,4,5,5,4′,4′,5′,5′-octamethyl-[2,2′]bi[[1,3,2]dioxaborolanyl], 1 g (1.4 mmol) of Pd(dpf)₂Cl₂, 15.9 g (162 mmol) of potassium acetate and 300 ml of dioxane was heated to 80° C. and stirred for 36 h.

After cooling, the solvent was removed and the residue was dried at 50° C. in a vacuum drying cabinet.

Purification was effected by filtration through silica gel with the eluent 1:1 n-hexane:dichloromethane. After the removal of the reactant, the eluent was switched to dichloromethane. The product was isolated as a reddish and tacky residue. This was extracted by stirring with methanol at RT for 0.5 h. The light-colored precipitate was filtered off. After drying at 45° C. in a vacuum drying cabinet, 24 g of a light-colored solid were obtained, which corresponds to a yield of 74%.

Analytical Data

¹H NMR (500 MHz, CD₂Cl₂, 25° C.): δ=7.66-7.61 (m, 6H); 7.41-7.4 (m, 2H); 7.33-7.25 (m, 6H); 7.13-7.12 (m, 2H); 7.09-7.07 (m, 2H); 1.40 (s, 12H); 1.32 (s, 12H)

Step b:

17.8 g (32 mmol) of 9Br-DIPP-PDCl and 19 ml (95 mmol) of 5 molar NaOH were introduced into 500 ml of dioxane. This mixture was degassed with argon for 30 min. Then 570 mg (1.1 mmol) of Pd[P(tBu)₃]₂ and 23 g (38 mmol) of stage a were added and the mixture was stirred at 85° C. under argon for 17 h.

Purification was effected by column chromatography with the eluent 4:1 dichloromethane:toluene.

22.4 g of a violet solid were obtained, which corresponds to a yield of 74%.

Analytical Data:

¹H NMR (500 MHz, CH2Cl2, 25° C.): δ=8.59-8.56 (m, 2H); 8.46-8.38 (m, 4H); 8.21-8.19 (d, 1H); 7.69-7.60 (m, 6H); 7.52-7.25 (m, 17H); 2.79-2.77 (m, 2H); 1.44 (s, 12H); 1.17-1.15 (d, 12H)

Step c:

22.4 g (23 mmol) of step b and 73 g (1.3 mol) of KOH were introduced into 200 ml of 2-methyl-2-butanol and the mixture was stirred at reflux for 17 h.

After cooling, the reaction mixture was added to 1 l of ice-water+50 ml of concentrated acetic acid. The orange-brown solid was filtered through a frit and washed with water.

The solid was dissolved in dichloromethane and extracted with demineralized water. 10 ml of concentrated acetic acid were added to the organic phase, which was stirred at RT. The solvent was removed from the solution. The residue was extracted by stirring with methanol at RT for 30 min, filtered with suction through a frit and dried at 55° C. in a vacuum drying cabinet.

This afforded 17.5 g of a violet solid, which corresponds to a yield of 94%.

The product was used unpurified in the next step.

Step d:

17.5 g (22 mmol) of stage c, 16.4 g (220 mmol) of glycine and 4 g (22 mmol) of zinc acetate were introduced into 350 ml of N-methylpyrrolidone and the mixture was stirred at 130° C. for 12 h.

After cooling, the reaction mixture was added to 1 l of demineralized water. The precipitate was filtered through a frit, washed with water and dried at 70° C. in a vacuum drying cabinet.

Purification was effected by means of column chromatography with the eluent 3:1 dichloromethane:ethanol+2% triethylamine. The isolated product was extracted by stirring at 60° C. with 50% acetic acid. The solid was filtered off with suction through a frit, washed with water and dried at 80° C. in a vacuum drying cabinet.

7.9 g of a violet solid were obtained, which corresponds to a yield of 42%.

Analytical Data:

¹H NMR (500 MHz, THF, 25° C.): δ=8.37-8.34 (m, 2H); 8.25-8.18 (m, 4H); 8.12-8.10 (d, 1H); 7.74-7.70 (m, 4H); 7.59-7.53 (m, 4H); 7.45-7.43 (m, 4H); 7.39-7.37 (m, 2H); 7.32-7.22 (m, 6H); 4.82 (s, 2H); 1.46 (s, 12H)

### (H) SYNTHESIS OF COMPOUNDS ID662

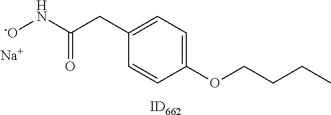

ID662 was prepared by reacting the corresponding commercially available hydroxamic acid [2-(4-butoxyphenyl)-N-hydroxyacetamide] with sodium hydroxide.

Reference numerals

| | |
|---|---|
| 110 | Photovoltaic element |
| 112 | Dye solar cell |
| 114 | Substrate |
| 116 | First electrode |
| 118 | Blocking layer |
| 120 | n-Semiconductive material |
| 122 | Dye |
| 124 | Carrier element |
| 126 | p-Semiconductor |
| 128 | Longpass filter |
| 130 | Electromagnetic radiation |
| 132 | Second electrode |
| 134 | Layer structure |
| 136 | Encapsulation |
| 138 | Fermi level |
| 140 | HOMO |
| 142 | LUMO |
| 210 | Transmission of longpass filter with λ_{LP} = 385 nm |
| 212 | Transmission of longpass filter with λ_{LP} = 420 nm |
| 214 | Transmission of longpass filter with λ_{LP} = 435 nm |
| 216 | Transmission of longpass filter with λ_{LP} = 450 nm |
| 218 | Lifetime of example 1 (without longpass filter) |
| 220 | Lifetime of example 2 (λ_{LP} = 385 nm) |
| 222 | Lifetime of example 3 (λ_{LP} = 420 nm) |
| 224 | Lifetime of example 5 (λ_{LP} = 450 nm) |
| 910 | Absorbance without UV absorber |
| 912 | Absorbance with Carboprotect Xymara |
| 914 | Absorbance with Carboprotect Xymara and Tinuvin 400 |
| 1010 | Lifetime without UV absorber |
| 1012 | Lifetime with Carboprotect Xymara |
| 1014 | Lifetime with Carboprotect Xymara and Tinuvin 400 |

1. A photovoltaic element for conversion of electromagnetic radiation to electrical energy, comprising at least one first electrode, at least one n-semiconductive metal oxide, further comprising at least one dye for absorption of at least a portion of the electromagnetic radiation, further comprising at least one organic hole conductor material and at least one second electrode, said organic hole conductor material in said photovoltaic element having an absorption spectrum for the electromagnetic radiation having an absorption maximum in an ultraviolet or blue spectral region and then, toward higher wavelengths, an absorption edge declining with the wavelength of the electromagnetic radiation and having a characteristic wavelength λ_{HTL}, a decadic absorbance of the hole conductor material at a wavelength λ_{HTL} within the declining absorption edge being 0.3, said photovoltaic element further having at least one longpass filter, said longpass filter having a transmission edge rising with the wavelength of the electromagnetic radiation and having a characteristic wavelength λ_{LP}, a transmission of the longpass filter at λ_{LP} being 50% of a maximum transmission of the longpass filter, where λ_{HTL}−30 nm≦λ_{LP}≦λ_{HTL}+30 nm.

2. The photovoltaic element according to claim 1, wherein λ_{HTL}≦440 nm.

3. The photovoltaic element according to claim 1, wherein wherein the absorption spectrum of the organic hole conductor material at a wavelength of λ_{HTL}+30 nm has declined to a decadic absorbance of less than 0.2 and for wavelengths of λ_{HTL}+30 nm to 800 nm has a decadic absorbance of less than 0.2.

4. The photovoltaic element according to claim 1, wherein the longpass filter has an edge steepness S_{LP} of the rising transmission edge, where S_{LP} is ≦1.2 eV.

5. The photovoltaic element according to claim 1, wherein the photovoltaic element has a transparent substrate, the longpass filter having been applied to the transparent substrate.

6. The photovoltaic element according to claim 5, wherein the first electrode or the second electrode have been applied to a first side of the substrate, the longpass filter having been applied to a second side of the substrate opposing the first side.

7. The photovoltaic element according to claim 1, wherein the longpass filter in at least one transmission region takes up a transmission of at least 75%.

8. The photovoltaic element according to claim 1, wherein the longpass filter in at least one absorption region takes up a decadic absorbance of at least 3.

9. The photovoltaic element according to claim 1, wherein the organic hole conductor material is or comprises an arylamine compound and/or a spiro compound,
especially a Spiro compound with a structure of the following formula: 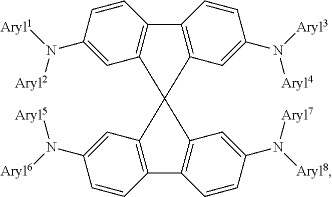
where the Aryl¹, Aryl², Aryl³, Aryl⁴, Aryl⁵, Aryl⁶, Aryl⁷ and Aryl⁸ radicals are each independently selected from substituted aryl radicals and heteroaryl radicals, especially from substituted phenyl radicals, where the aryl radicals and heteroaryl radicals, preferably the phenyl radicals, are preferably each independently substituted by one or more substituents selected from the group consisting of —O-alkyl, —OH, —F, —Cl, 'Br and —I, where alkyl is preferably methyl, ethyl, propyl or isopropyl, where the phenyl radicals are more preferably each independently substituted by one or more substituents selected from the group consisting of —O-Me, —OH, —F, —Cl, —Br and —I,
preferably a spiro compound of the following formula: 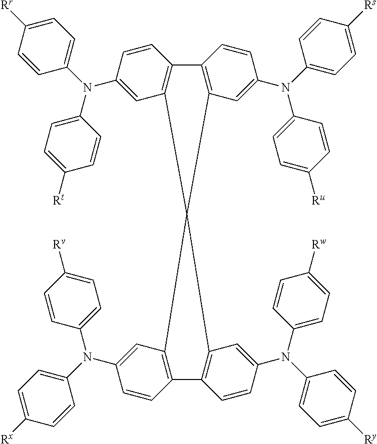
where R^{r}, R^{s}, R^{t}, R^{u}, R^{v}, R^{w}, R^{x} and R^{y} are each independently selected from the group consisting of —O-alkyl, —OH, —F, —Cl, —Br and —I, where alkyl is preferably methyl, ethyl, propyl or isopropyl, where R^{r}, R^{s}, R^{t}, R^{u}, R^{v}, R^{w}, R^{x} and R^{y} are preferably each independently selected from the group consisting of —O-Me, —OH, —F, —Cl, —Br and —I,
and more preferably spiro-MeOTAD:

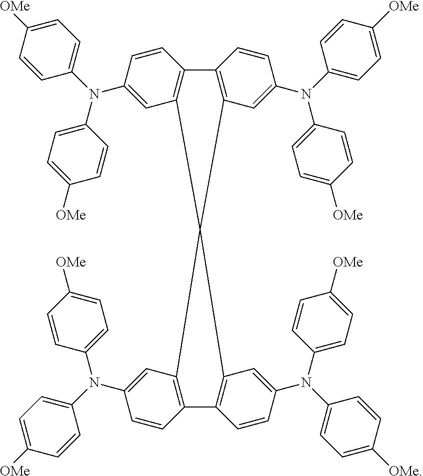

10. The photovoltaic element according to claim 1, wherein the organic hole conductor material is or comprises a compound with the following structural formula: 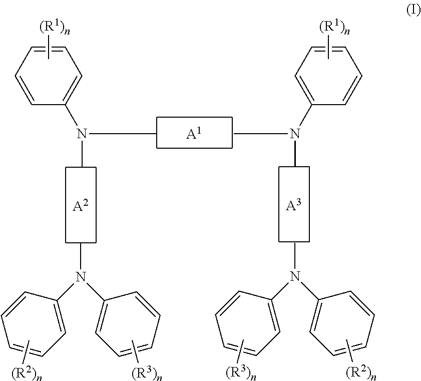
where
A¹, A², A³ are each independently optionally substituted aryl groups or heteroaryl groups,
R¹, R², R³ are each independently selected from the group consisting of the substituents —R, —OR, —NR₂, -A⁴-OR and -A⁴-NR₂,
where R is selected from the group consisting of alkyl, aryl and heteroaryl,
and
where A⁴ is an aryl group or heteroaryl group, and
where n at each instance in formula I is independently a value of 0, 1, 2 or 3,
with the proviso that the sum of the individual values n is at least 2 and at least two of the R¹, R² and R³ radicals are —OR and/or —NR₂.

11. The photovoltaic element according to claim 1, wherein the longpass filter comprises at least one inorganic filter material, especially a metal oxide and more preferably an inorganic filter material selected from the group consisting of SiO₂, TiO₂, ZrO₂ and Ta₂O₅.

12. The photovoltaic element according to claim 1, wherein the longpass filter is producible by means of a sol-gel process.

13. The photovoltaic element according to claim 1, wherein the longpass filter comprises at least one organic filter dye, especially at least one rylene dye.

14. The photovoltaic element according to claim 1, wherein the longpass filter is producible by applying a solution comprising at least one filter material and at least one solvent to a substrate, and then the solvent is removed.

15. The photovoltaic element according to claim 1, wherein the dye has an absorption with a decadic absorbance of at least 0.1 at at least one wavelength in a spectral range above λ_{HTL}.

16. The photovoltaic element according to claim 1, wherein the longpass filter comprises at least one transparent organic matrix material and at least one absorber material introduced into the matrix material.

17. The photovoltaic element according to claim 16, wherein the matrix material comprises at least one varnish.

18. The photovoltaic element according to claim 17, wherein the varnish is a polyacrylate-polyester varnish.

19. The photovoltaic element according to claim 17, wherein the varnish is applied by applying a coating composition, and wherein the coating composition comprises at least one polyester resin (A), at least one polyacrylate resin (B) and preferably at least one crosslinking agent, said crosslinking agent being selected from the group consisting of polyisocyanates, amide- and amine-formaldehyde resins, phenol resins, aldehyde resins and ketone resins, said crosslinking agent preferably being a polyisocyanate.

20. The photovoltaic element according to claim 16, wherein the absorber material comprises at least one organic absorber material.

21. The photovoltaic element according to claim 20, wherein the organic absorber material is selected from compounds comprising a benzotriazole group or a triazine group.

22. The photovoltaic element according to claim 1, wherein the longpass filter comprises at least two absorber materials introduced, especially mixed, into the matrix material, one absorber material being an absorber material comprising a triazine group, preferably an absorber material having the following structure 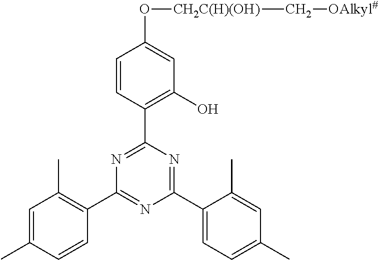
where alkyl^{#} is preferably a linear alkyl group, especially a linear alkyl group having 12 or 13 carbon atoms, and the other absorber material being preferably a compound of the following structure: 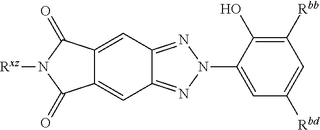
where R^{bb} and R^{bd} are each independently selected from the group consisting of H, -alkyl, —OH, -alkylaryl, -alkylheteryl, -cycloalkyl, cycloheteroalkyl, alkenyl, aryl and —SO₃H,
and where R^{xz} is selected from the group consisting of H, alkyl, aryl, heteroaryl, alkylaryl, alkylheteroryl, alkenyl and alkynyl.

23. A process for producing a photovoltaic element for conversion of electromagnetic radiation to electrical energy, by providing at least one first electrode, at least one n-semiconductive metal oxide, at least one dye for absorption of at least a portion of the electromagnetic radiation, at least one organic hole conductor material and at least one second electrode, the organic hole conductor material being selected such that it, in the photovoltaic element, has an absorption spectrum for the electromagnetic radiation having an absorption maximum in an ultraviolet or blue spectral region and then, toward higher wavelengths, having an absorption edge declining with the wavelength of the electromagnetic radiation and having a characteristic wavelength λ_{HTL}, a decadic absorbance of the hole conductor material at the wavelength λ_{HTL} within the declining absorption edge being 0.3, and by further providing at least one longpass filter, said longpass filter having a transmission edge rising with the wavelength of the electromagnetic radiation and having a characteristic wavelength λ_{LP}, a transmission of the longpass filter at λ_{LP} being 50% of a maximum transmission of the longpass filter, where λ_{HTL}−30 nm≦λ_{LP}≦λ_{HTL}+30 nm.

24. A process for selecting a longpass filter for use in a photovoltaic element for conversion of electromagnetic radiation to electrical energy, said photovoltaic element having at least one first electrode, at least one n-semiconductive metal oxide, at least one dye for absorption of at least a portion of the electromagnetic radiation, at least one organic hole conductor material and at least one second electrode, said process comprising the following steps:
determining an absorption spectrum of the organic hole conductor material in the photovoltaic element,
evaluating the absorption spectrum and determining a characteristic wavelength λ_{HTL}, the characteristic wavelength being within a declining absorption edge in which an absorption of the organic hole conductor material in the photovoltaic element declines proceeding from an absorption maximum in an ultraviolet or blue spectral range, a decadic absorbance of the hole conductor material at the characteristic wavelength λ_{HTL} being 0.3,
selecting the longpass filter such that the longpass filter has a transmission edge rising with the wavelength of the electromagnetic radiation and having a characteristic wavelength λ_{LP}, a transmission of the longpass filter at λ_{LP} being 50% of a maximum transmission of the longpass filter, where λ_{HTL}−30 nm≦λ_{LP}≦λ_{HTL}+30 nm.

25. The process according to claim 23, wherein the longpass filter is produced by introducing at least one absorber material into at least one transparent organic matrix material.

26. The process according to claim 24, wherein the longpass filter is produced by introducing at least one absorber material into at least one transparent organic matrix material.

27. A use of a varnish for protection of a photovoltaic element for conversion of electromagnetic radiation from damage by ultraviolet radiation, said varnish comprising at least one organic matrix material and at least one absorber material introduced into the matrix material.

28. The use according to claim 27, said varnish comprising at least two absorber materials introduced into the matrix material.
